(19) United States
(12) Patent Application Publication
(10) Pub. No.: US 2025/0089242 A1
(43) Pub. Date: Mar. 13, 2025

(54) MEMORY DEVICE AND MANUFACTURING METHOD THEREOF

(71) Applicant: SEOUL NATIONAL UNIVERSITY R&DB FOUNDATION, Seoul (KR)

(72) Inventor: Cheol Seong Hwang, Seoul (KR)

(21) Appl. No.: 18/576,312

(22) PCT Filed: Nov. 10, 2023
(86) PCT No.: PCT/KR2023/018026

§ 371 Date: Jan. 3, 2024

(30) Foreign Application Priority Data
Mar. 15, 2023 (KR) 10-2023-0034162
May 25, 2023 (KR) 10-2023-0067652

(51) Int. Cl. H10B 12/00

(52) U.S. Cl. CPC H10B 12/485; H10B 12/0335; H10B 12/315; H10B 12/482; H10B 12/488

(57) ABSTRACT

The present disclosure discloses a manufacturing method of a memory device including forming a structure including an epitaxial material plug extending in a vertical direction on a substrate, an epitaxial channel material layer extending in a horizontal direction from a side surface of the epitaxial material plug, and a gate insulating material layer formed on at least a surface portion of the epitaxial channel material layer.

### TECHNICAL FIELD

The present invention relates to semiconductor/electronic devices and manufacturing methods thereof, and more particularly, to memory devices and manufacturing methods thereof.

### BACKGROUND ART

There is a continuous need to increase the performance of semiconductor devices and the degree of integration of semiconductor devices. Arranging unit cells of semiconductor devices two-dimensionally, that is, in a planar manner, is reaching its limit in increasing the degree of integration of semiconductor devices. Accordingly, the attempts are being made to develop technologies that greatly increase the degree of integration of semiconductor devices by three-dimensionally integrating the unit cells of the semiconductor devices. In this regard, the attempts to increase the integration degree of memory devices such as NAND devices or DRAM devices are being attempted in various forms. In addition, research and development are continuously being conducted to improve the performance and operating characteristics of memory devices.

In the manufacturing 3D memory devices, for example, a stacked structure in which Si/SiGe structures are repeatedly stacked hundreds of times is used, but this method has the problems such as very low productivity, high production costs, and high process difficulty. In particular, in forming the stacked structure, there is a disadvantage that the epitaxial process time is long, and the epitaxial process difficulty is high. Additionally, in the case of the existing method, it may be difficult to secure uniformity of the channel thickness, and in some cases, a problem may arise that the Si layer is structurally difficult to withstand when the SiGe layer is removed.

### DISCLOSURE OF THE INVENTION

### Technical Problem

The technological object to be achieved by the present invention is to provide a memory device and a manufacturing method thereof which may increase the degree of integration and secure excellent performance, while also facilitating easy processing and reducing manufacturing costs.

In addition, the technological object to be achieved by the present invention is to provide a method of manufacturing a memory device and a memory device manufactured by this method which may improve performance such as mobility by using a single crystal channel material, may improve channel thickness uniformity, and may improve on-current characteristics.

The object to be solved by the present invention is not limited to the objects mentioned above, and other objects not mentioned will be understood by those skilled in the art from the description below.

### Technical Solution

According to one embodiment of the present invention, there is provided a manufacturing method of a memory device comprising: forming a stack including a first insulating layer, a first sacrificial layer, and a second insulating layer sequentially stacked on a substrate; forming a patterned stack having at least one pattern portion having a first sacrificial layer pattern obtained from the first sacrificial layer by pattering the stack, wherein the pattern portion has a shape extending in a first direction, and empty spaces are provided on both sides of the pattern portion along a second direction perpendicular to the first direction; forming a structure including the patterned stack and an insulating material by filling the empty spaces on both sides of the at least one pattern portion with the insulating material; forming a first vertical hole penetrating through the first sacrificial layer pattern of the pattern portion in the structure; forming an epitaxial material plug filling the first vertical hole from the substrate by using an epitaxial growth method; forming a first etched portion spaced apart from the epitaxial material plug in the structure; forming a horizontal hole extending in the first direction by removing the first sacrificial layer pattern exposed by the first etched portion; forming an epitaxial channel material layer filling the horizontal hole from a side surface of the epitaxial material plug by using an epitaxial growth method; forming an empty region around the epitaxial material plug and the epitaxial channel material layer by removing the first and second insulating layers and the insulating material from the structure; forming a gate insulating material layer on surface portions of the epitaxial material plug and the epitaxial channel material layer; forming a filling insulating layer filling the empty region on the gate insulating material layer; forming a second vertical hole in a region corresponding to the first vertical hole in the structure where the gate insulating material layer and the filling insulating layer are formed; exposing the gate insulating material layer by removing the filling insulating layer from a transistor formation region around the second vertical hole of the structure; defining a transistor including a word line by forming the word line surrounding an exposed portion of the gate insulating material layer in the transistor formation region; forming a bit line connected to one end of the epitaxial channel material layer in a region corresponding to the second vertical hole in the transistor formation region; and removing the epitaxial channel material layer and the gate insulating material layer from a capacitor formation region adjacent to the transistor formation region of the structure, and forming a capacitor connected to the other end of the epitaxial channel material layer of the transistor.

The first insulating layer, the second insulating layer, and the insulating material may include a silicon nitride, and the first sacrificial layer may include a silicon oxide.

The epitaxial material plug, and the epitaxial channel material layer may include a single crystal semiconductor.

The epitaxial material plug, and the epitaxial channel material layer may include any one selected from a single crystal Si, a single crystal Ge, and a single crystal SiGe.

The defining the transistor by forming the word line may include: forming a word line material layer surrounding the exposed portion of the gate insulating material layer in the transistor formation region; forming a through hole by etching a region corresponding to the second vertical hole in the word line material layer; recessing a portion of the word line material layer exposed through the through hole so that the one end of the epitaxial channel material layer may protrude toward the through hole rather than the word line material layer; and forming a body insulating layer filling the through hole.

The above method may include forming a first recess exposing the word line material layer by removing the filling insulating layer from the capacitor formation region; and recessing a portion of the word line material layer exposed by the first recess.

The forming the bit line may include forming a third vertical hole in a region of the body insulating layer corresponding to the second vertical hole; and forming the bit line in the third vertical hole.

After the forming the bit line, the above method may include forming a second etched portion spaced apart from the bit line in the capacitor formation region; and forming a first recess exposing the gate insulating material layer by removing the filling insulating layer exposed by the second etched portion in the capacitor formation region.

After the forming the first recess in the capacitor formation region, the above method may further include forming an insertion insulating layer surrounding an exposed portion of the gate insulating material layer in the capacitor formation region; forming a mold insulating layer on the insertion insulating layer filling the first recess and the second etched portion; forming a third etched portion in a region of the mold insulating layer corresponding to the second etched portion; and forming a second recess by etching the epitaxial channel material layer, the gate insulating material layer, and the insertion insulating layer exposed by the third etched portion.

The forming the capacitor may include forming an electrode member connected to the other end of the epitaxial channel material layer on an inner surface of the second recess; forming a dielectric layer on the electrode member; forming a plate electrode on the dielectric layer.

After forming the electrode member, the above method may further include exposing an outer surface of the electrode member by etching the mold insulating layer, and after etching the mold insulating layer, the dielectric layer and the plate electrode may be sequentially formed.

The stack may further include a second sacrificial layer and a third insulating layer sequentially stacked on the second insulating layer, and the stack may have a vertically symmetrical structure with respect to the second insulating layer.

The second insulating layer may have a thickness larger than that of each of the first insulating layer, the third insulating layer, the first sacrificial layer, and the second sacrificial layer.

The transistor may be a first transistor, the capacitor may be a first capacitor, and the memory device may be formed to further include a second transistor disposed on the first transistor and a second capacitor disposed on the first capacitor.

According to another embodiment of the present invention, there is provided a manufacturing method of a memory device comprising: forming a structure including an epitaxial material plug extending in a vertical direction on a substrate, an epitaxial channel material layer extending in a horizontal direction from a side surface of the epitaxial material plug, a gate insulating material layer formed on at least a surface portion of the epitaxial channel material layer, and a filling insulating layer formed on the gate insulating material layer and filling a space surrounding the epitaxial material plug and the epitaxial channel material layer; forming a vertical hole (hereinafter, referred to as a second vertical hole) by removing the epitaxial material plug from the structure; exposing the gate insulating material layer by removing the filling insulating layer from a transistor formation region around the second vertical hole of the structure; forming a word line surrounding an exposed portion of the gate insulating material layer in the transistor formation region to define a transistor including the word line; forming a bit line connected to one end of the epitaxial channel material layer in a region corresponding to the second vertical hole in the transistor formation region; and removing the epitaxial channel material layer and the gate insulating material layer from a capacitor formation region adjacent to the transistor formation region of the structure, and forming a capacitor connected to the other end of the epitaxial channel material layer of the transistor.

According to one embodiment of the present invention, there is provided a memory device comprising: a plurality of memory cells stacked in a vertical direction, and wherein each of the plurality of memory cells includes a transistor and a capacitor electrically connected to the transistor in a lateral direction, the transistor includes an epitaxial channel material layer, a word line surrounding the epitaxial channel material layer, and a gate insulating layer disposed therebetween, the capacitor includes an electrode member electrically connected to the transistor, a dielectric layer disposed on a surface of the electrode member, and a plate electrode disposed on a surface of the dielectric layer, a bit line connected to a plurality of transistors of the plurality of memory cells and extending in a vertical direction is provided, and the transistor has a GAA (gate-all-around) structure.

For example, the epitaxial channel material layer may include any one selected from a single crystal Si, a single crystal Ge, and a single crystal SiGe.

A body insulating layer surrounding at least a portion of an outer surface of the bit line may be further provided between the bit line and the word line, and a gap filling insulating layer which is a separate material layer from the body insulating layer may be provided between two mutually adjacent word lines of the plurality of transistors.

When observed from above, the body insulating layer may have a structure in which a plurality of annular-shaped units are connected in series, and the bit line may be disposed inside each of the plurality of annular-shaped units.

An insertion insulating layer may be further provided surrounding a portion of the gate insulating layer adjacent to the electrode member and extending to cover a side surface of the word line, and the insertion insulating layer may be a separate a material layer from the body insulating layer and the gap filling insulating layer.

The body insulating layer may be in contact with a first side surface of the gap filling insulating layer, and the insertion insulating layer may be in contact with a second side surface of the gap filling insulating layer.

According to another embodiment of the present invention, there is provided a manufacturing method of a memory device comprising: forming a stack including a first insulating layer, a first sacrificial layer, and a second insulating layer sequentially stacked on a substrate; forming a first etched portion penetrating through a region including at least one bit line formation planned region in the stack; forming an epitaxial material plug filling the first etched portion from the substrate by using an epitaxial growth method; forming a second etched portion spaced apart from the epitaxial material plug in the stack; forming a horizontal space by removing the first sacrificial layer exposed by the second etched portion; forming an epitaxial channel material layer filling the horizontal space from a side surface of the epitaxial material plug by using an epitaxial growth method; forming a patterned stack including at least one pattern portion having an epitaxial channel pattern obtained from the epitaxial channel material layer and an epitaxial plug pattern obtained from the epitaxial material plug by patterning the stack on which the epitaxial channel material layer is formed; removing the first and second insulating layers from the patterned stack; forming a gate insulating material layer on surface portions of the epitaxial plug pattern and the epitaxial channel pattern; forming a structure including the epitaxial plug pattern, the epitaxial channel pattern, the gate insulating material layer, and an filling insulating layer by forming the filling insulating layer filling a space surrounding the epitaxial plug pattern and the epitaxial channel pattern on the gate insulating material layer; forming a first vertical hole exposing the epitaxial channel pattern in a region corresponding to the bit line formation planned region; exposing the gate insulating material layer by removing the filling insulating layer from a transistor formation region around the first vertical hole of the structure; defining a transistor including a word line by forming the word line surrounding an exposed portion of the gate insulating material layer in the transistor formation region; forming a bit line connected to one end of the epitaxial channel pattern in a region corresponding to the first vertical hole in the transistor formation region; and removing the epitaxial channel pattern and the gate insulating material layer from a capacitor formation region adjacent to the transistor formation region of the structure, and forming a capacitor connected to the other end of the epitaxial channel pattern of the transistor.

The first insulating layer and the second insulating layer may include a silicon nitride, and the first sacrificial layer may include a silicon oxide.

The first etched portion may have a trench shape which commonly penetrates through a plurality of the bit line formation planned regions.

The epitaxial material plug, and the epitaxial channel material layer may include a single crystal semiconductor.

The epitaxial material plug, and the epitaxial channel material layer may include any one selected from a single crystal Si, a single crystal Ge, and a single crystal SiGe.

The defining the transistor by forming the word line may include: forming a word line material layer surrounding the exposed portion of the gate insulating material layer in the transistor formation region; forming a through hole by etching a region corresponding to the first vertical hole in the word line material layer; recessing a portion of the word line material layer exposed through the through hole so that the one end of the epitaxial channel pattern may protrude toward the through hole rather than the word line material layer; and forming a body insulating layer filling the through hole.

Forming a first recess exposing the word line material layer by removing the filling insulating layer from the capacitor formation region; and recessing a portion of the word line material layer exposed by the first recess may be further included.

The forming the bit line may include forming a second vertical hole in a region of the body insulating layer corresponding to the first vertical hole; and forming the bit line in the second vertical hole.

After forming the bit line, forming a third etched portion spaced apart from the bit line in the capacitor formation region; and forming a first recess exposing the gate insulating material layer by removing the filling insulating layer exposed by the third etched portion in the capacitor formation region may further included.

After forming the first recess in the capacitor formation region, forming an insertion insulating layer surrounding an exposed portion of the gate insulating material layer in the capacitor formation region; forming a mold insulating layer filling the first recess and the third etched portion on the insertion insulating layer; forming a fourth etched portion in a region of the mold insulating layer corresponding to the third etched portion; and forming a second recess by etching the epitaxial channel pattern, the gate insulating material layer, and the insertion insulating layer exposed by the fourth etched portion may further included.

The forming the capacitor may include forming an electrode member connected to the other end of the epitaxial channel pattern on an inner surface of the second recess; forming a dielectric layer on the electrode member; and forming a plate electrode on the dielectric layer.

After forming the electrode member, the method may include exposing an outer surface of the electrode member by etching the mold insulating layer, and after etching the mold insulating layer, the dielectric layer and the plate electrode may be sequentially formed.

The stack may further include a second sacrificial layer and a third insulating layer sequentially stacked on the second insulating layer, and the stack may have a vertically symmetrical structure with respect to the second insulating layer.

The second insulating layer may have a thickness larger than that of each of the first insulating layer, the third insulating layer, the first sacrificial layer, and the second sacrificial layer.

The transistor may be a first transistor, the capacitor may be a first capacitor, and the memory device may be formed to further include a second transistor disposed on the first transistor and a second capacitor disposed on the first capacitor.

According to another embodiment of the present invention, there is provided a manufacturing method of a memory device comprising: forming a structure including an epitaxial plug pattern extending in a vertical direction on a substrate, an epitaxial channel pattern extending in a horizontal direction from a side surface of the epitaxial plug pattern, a gate insulating material layer formed on at least a surface portion of the epitaxial channel pattern, and a filling insulating layer formed on the gate insulating material layer to fill a space surrounding the epitaxial plug pattern and the epitaxial channel pattern; removing the epitaxial plug pattern and forming a first vertical hole exposing the epitaxial channel pattern by etching a bit line formation planned region in the structure; exposing the gate insulating material layer by removing the filling insulating layer from a transistor formation region around the first vertical hole of the structure; forming a word line surrounding an exposed portion of the gate insulating material layer in the transistor formation region to define a transistor including the word line; forming a bit line connected to one end of the epitaxial channel pattern in a region corresponding to the first vertical hole in the transistor formation region; and removing the epitaxial channel pattern and the gate insulating material layer from a capacitor formation region adjacent to the transistor formation region of the structure, and forming a capacitor connected to the other end of the epitaxial channel pattern of the transistor.

In the structure, the epitaxial plug pattern and the epitaxial channel pattern may have the same width.

According to another embodiment of the present invention, there is provided a memory device comprising: a plurality of memory cells stacked in a vertical direction, and wherein each of the plurality of memory cells includes a transistor and a capacitor electrically connected to the transistor in a lateral direction, the transistor includes an epitaxial channel pattern, a word line surrounding the epitaxial channel pattern, and a gate insulating layer disposed therebetween, the epitaxial channel pattern includes a single crystal semiconductor, the capacitor includes an electrode member electrically connected to the transistor, a dielectric layer disposed on a surface of the electrode member, and a plate electrode disposed on a surface of the dielectric layer, and a bit line connected to a plurality of transistors of the plurality of memory cells and extending in a vertical direction, and the transistor has a GAA (gate-all-around) structure.

For example, the epitaxial channel pattern may include anyone selected from a single crystal Si, a single crystal Ge, and a single crystal SiGe.

A body insulating layer may be provided between the bit line and the word line to surround at least a portion of an outer surface of the bit line, and a gap filling insulating layer may be provided between two mutually adjacent word lines of the plurality of transistors.

When observed from above, the body insulating layer may have a structure in which a plurality of annular-shaped units are connected in series, and the bit line may be disposed inside each of the plurality of annular-shaped units.

An insertion insulating layer may be further provided surrounding a portion of the gate insulating layer adjacent to the electrode member and extending to cover a side surface of the word line, and the insertion insulating layer may be a separate material layer from the body insulating layer and the gap filling insulating layer.

The body insulating layer may be in contact with a first side surface of the gap filling insulating layer, and the insertion insulating layer may be in contact with a second side surface of the gap filling insulating layer.

### Advantageous Effects

According to the embodiments of the present invention described above, it is possible to implement a memory device (stack-type memory device) and a manufacturing method thereof which may increase the degree of integration and secure excellent performance, while also facilitating easy processing and reducing manufacturing costs. In addition, according to the embodiments of the present invention, it is possible to implement a memory device (stack-type memory device) and a manufacturing method thereof which may improve performance such as mobility by using a single crystal channel material, may improve channel thickness uniformity, and may improve on-current characteristics.

According to one embodiment of the present invention, an epitaxial channel layer is formed by using a selective epitaxial growth (SEG) method using a stack of an insulating layer and a sacrificial layer. Thus, as compared to the existing method using a Si/SiGe stacked structure, it is possible to manufacture a memory device in which process difficulties may be reduced, manufacturing costs may be reduced, and performances are improved.

According to one embodiment of the present invention, since an epitaxial channel layer is formed by using a selective epitaxial growth (SEG) method using a stack of an insulating layer and a sacrificial layer, it is possible to manufacture a memory device with improved performance in which process difficulties may be reduced and the manufacturing costs may be reduced as compared to the existing method using a Si/SiGe stacked structure. According to one embodiment, in manufacturing a memory device, after forming a stack in which an insulating layer and a sacrificial layer are stacked, an epitaxial material plug may be formed by using a selective epitaxial growth (SEG) method, for example, through a trench-shaped etched portion, an epitaxial channel material layer may be formed by using a SEG method from the epitaxial material plug in a space where the sacrificial layer was removed, a cell patterning may be proceeded, and then a process for forming a word line and a capacitor may be performed. In this case, it may be advantageous in manufacturing a memory device in which reduces process difficulties and provides excellent performance. In particular, when forming an epitaxial material plug by using the SEG method through a trench-shaped etched portion, the difficulties of the epitaxial process may be reduced as compared to a case that epitaxial growth is performed through a narrow hole.

According to one example, the memory device may be configured to include a horizontal stack-type DRAM device.

However, the effects of the present invention are not limited to the above effects and may be expanded in various ways without departing from the technological spirit and scope of the present invention.

### BRIEF DESCRIPTION OF THE DRAWINGS

FIGS. 1A, 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A and 32A are cross-sectional diagrams for explaining an example of a manufacturing method of a memory device according to an embodiment of the present invention.

FIGS. 1B, 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B and 32B are diagrams for explaining an example of a manufacturing method of a memory device according to an embodiment of the present invention.

FIGS. 1C, 2C, 3C, 4C, and 5C are cross-sectional diagrams for explaining an example of a manufacturing method of a memory device according to an embodiment of the present invention.

FIG. 32A and FIG. 32B are diagrams for explaining a memory device according to an embodiment of the present invention.

FIGS. 33A, 34A, 35A, 36A, 37A, 38A, 39A, 40A, 41A, 42A, 43A, 44A, 45A, 46A, 47A, 48A, 49A, 50A, 51A, 52A, 53A, 54A, 55A, 56A, 57A, 58A, 59A, 60A, 61A, 62A and 63A are cross-sectional diagrams for explaining an example of a manufacturing method of a memory device according to an embodiment of the present invention.

FIGS. 33B, 34B, 35B, 36B, 37B, 38B, 39B, 40B, 41B, 42B, 43B, 44B, 45B, 46B, 47B, 48B, 49B, 50B, 51B, 52B, 53B, 54B, 55B, 56B, 57B, 58B, 59B, 60B, 61B, 62B and 63B are diagrams for explaining an example of a manufacturing method of a memory device according to an embodiment of the present invention.

FIGS. 33C, 34C, 35C, 36C, 37C, 38C, 39C, 40C, 41C, 42C, 43C and 44C are cross-sectional diagrams for explaining an example of a manufacturing method of a memory device according to an embodiment of the present invention.

FIG. 63A and FIG. 63B are diagrams for explaining a memory device according to an embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, clement, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the description of this specification, the descriptions such as “first” and “second”, “upper or top”, and “lower or bottom” are intended to distinguish members, and not used to limit the members themselves or mean a specific order, but rather a relative positional relationship among them, and does not limit specific cases where the other members are directly contacted with the described configuring members or another member is introduced into the interface between them. The same interpretation may be applied to other expressions which describe relationships between the configuring components.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and substance tolerances, and exact or absolute figures provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring elements throughout the detailed description.

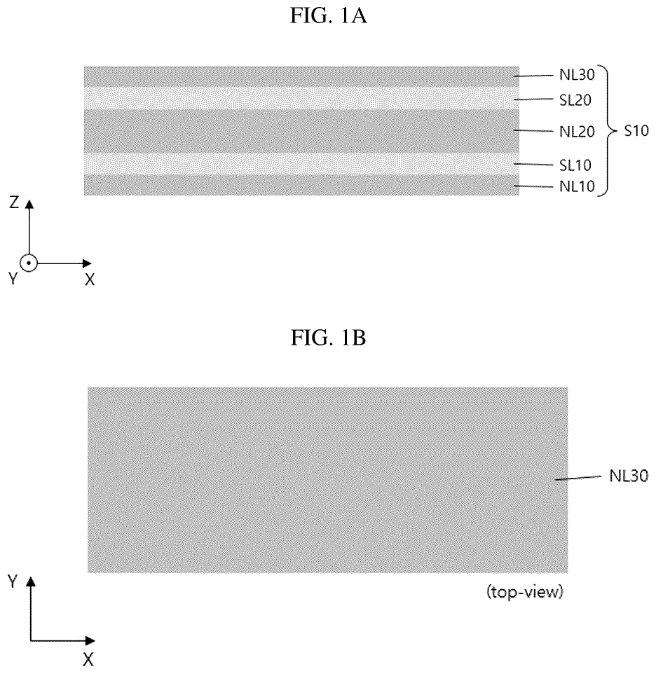

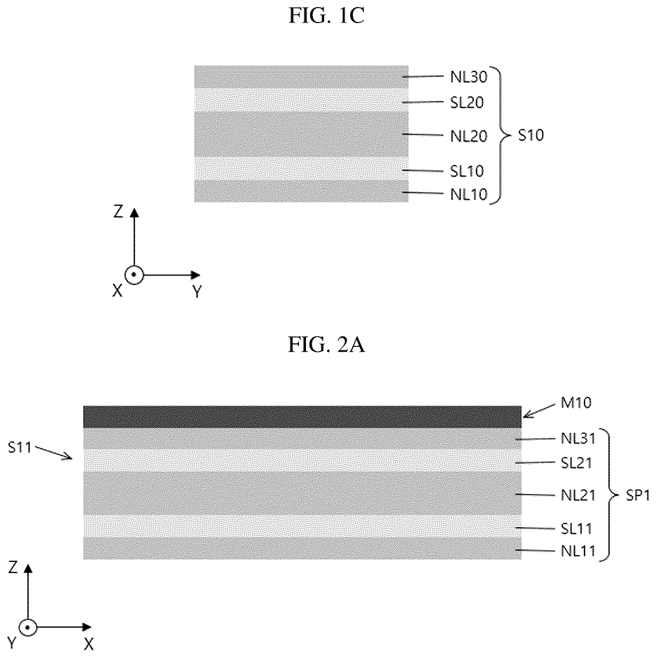

FIG. 1A to FIG. 32B are diagrams for explaining an example of a manufacturing method of a memory device (stack-type memory device) according to an embodiment of the present invention.

The same numbers in FIGS. 1A to FIG. 32B (e.g., FIG. 1 in FIG. 1A, FIG. 1B, and FIG. 1C) refer to the same steps. FIGS. 1A, 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A and 32A are cross-sectional diagrams cut along the X-Z plane. FIGS. 1B, 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B and 32B are plan diagrams observed from above (i.e., a top-view) or cross-sectional diagrams cut along the X-Y plane (i.e. Z-cut view). FIGS. 1C, 2C, 3C, 4C, and 5C are cross-sectional diagrams cut along the Y-Z plane.

Referring to FIG. 1A to FIG. 1C, a stack S10 may be formed on a predetermined substrate (not shown). The material of the substrate may be selected from a variety of materials. The substrate may be formed by including a semiconductor material or an insulating material. The substrate may include a semiconductor wafer. The substrate may also include a bulk silicon substrate, a silicon-on-insulator (SOI) substrate, a germanium substrate, or a germanium-on-insulator (GOI), a silicon-germanium substrate, or a substrate formed by an epitaxial growth process. The substrate may include a single crystal semiconductor material. For example, the substrate may include any one selected from a single crystal silicon (Si), a single crystal germanium (Ge), and a single crystal silicon-germanium (SiGe).

The stack S10 may be formed on the substrate. The stack S10 may include a first insulating layer NL10, and a first sacrificial layer SL10 and a second insulating layer NL20 which are sequentially stacked on the first insulating layer NL10. As a non-limiting example, the first insulating layer NL10 and the second insulating layer NL20 may include a silicon nitride (e.g., SiNₓ) or may be formed of a silicon nitride (e.g., SiNₓ). As a non-limiting example, the first sacrificial layer SL10 may include a silicon oxide (e.g., SiO₂) or may be formed of a silicon oxide (e.g., SiO₂). The first insulating layer NL10 and the first sacrificial layer SL10 may have an etching selectivity, and similarly, the second insulating layer NL20 and the first sacrificial layer SL10 may have an etching selectivity. The first insulating layer NL10, first sacrificial layer SL10, and second insulating layer NL20 may be formed through a deposition process.

Furthermore, according to one embodiment, the stack S10 may further include a second sacrificial layer SL20 and a third insulating layer NL30 sequentially stacked on the second insulating layer NL20. In this case, the stack S10 may have a vertically symmetrical structure with respect to the second insulating layer NL20. The second sacrificial layer SL20 may be formed of the same material as the first sacrificial layer SL10, and the third insulating layer NL30 may be formed of the same material as the first insulating layer NL10 and/or the second insulating layer NL20. The second sacrificial layer SL20 and the third insulating layer NL30 may be formed through a deposition process.

The second insulating layer NL20 may have a thickness larger than that of each of the first insulating layer NL10, the third insulating layer NL30, the first sacrificial layer SL10, and the second sacrificial layer SL20. For example, the second insulating layer NL20 may have a thickness which is about 1.5 times to about 2.5 times larger than a thickness of each of the first insulating layer NL10, the third insulating layer NL30, the first sacrificial layer SL10, and the second sacrificial layer SL20. It is possible to secure a gap between upper and lower cells to be formed later by forming the second insulating layer NL20 relatively thick. The first insulating layer NL10 and the third insulating layer NL30 may have the same thickness or substantially the same thickness. The first sacrificial layer SL10 and the second sacrificial layer SL20 may have the same thickness or substantially the same thickness. The first insulating layer NL10, the third insulating layer NL30, the first sacrificial layer SL10, and the second sacrificial layer SL20 may have the same thickness or substantially the same thickness.

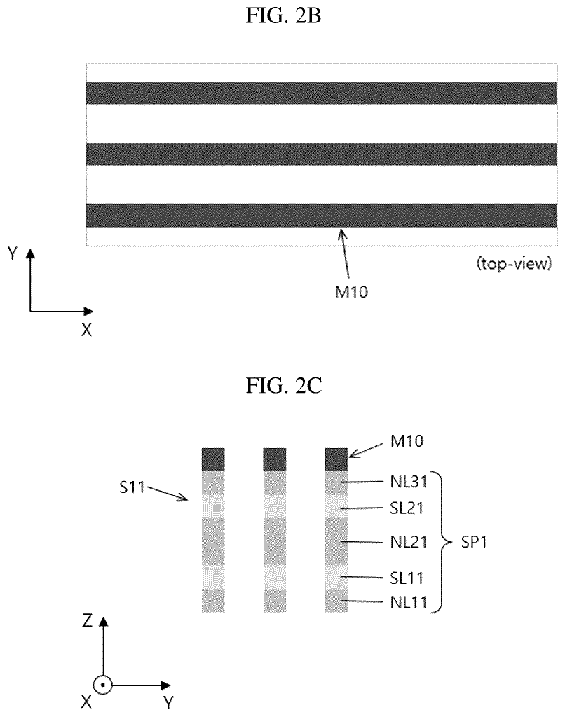

Referring to FIG. 2A to FIG. 2C, a patterned stack S11 having at least one pattern portion SP1 may be formed by patterning the stack (S10 in FIG. 1A). The pattern portion SP1 may have a shape extending in a first direction, for example, the X-axis direction, and empty spaces may be provided on both sides of the pattern portion SP1 along a second direction perpendicular to the first direction, for example, the Y-axis direction. The plurality of pattern portions SP1 may be spaced apart in the Y-axis direction and arranged side by side in the X-axis direction. In this step, remaining regions except for the region extending from a channel region to be formed later may be removed by patterning.

The pattern portion SP1 may include a patterned first insulating layer NL11, a patterned first sacrificial layer SL11, a patterned second insulating layer NL21, a patterned second sacrificial layer SL21, and a patterned third insulating layer NL31. Here, the patterned first sacrificial layer SL11 may be referred to as the first sacrificial layer pattern SL11 obtained from the first sacrificial layer (SL10 in FIG. 1A). Also, the patterned second sacrificial layer SL21 may be referred to as the second sacrificial layer pattern SL21 obtained from the second sacrificial layer (SL20 in FIG. 1A). The plurality of first sacrificial layer patterns SL11 may be spaced apart from each other in the Y-axis direction and extend parallel to each other in the X-axis direction. Similarly, the plurality of second sacrificial layer patterns SL21 may be spaced apart from each other in the Y-axis direction and extend side by side in the X-axis direction. Each of the first sacrificial layer patterns SL11 and the second sacrificial layer patterns SL21 may have a line shape.

A first mask pattern M10 disposed on the stack (S10 in FIG. 1A) may be used for the patterning process of FIGS. 2A to 2C. The first mask pattern M10 may have a predetermined pattern structure. The first mask pattern M10 may be, for example, a photoresist pattern. The first mask pattern M10 may be removed after the patterning process.

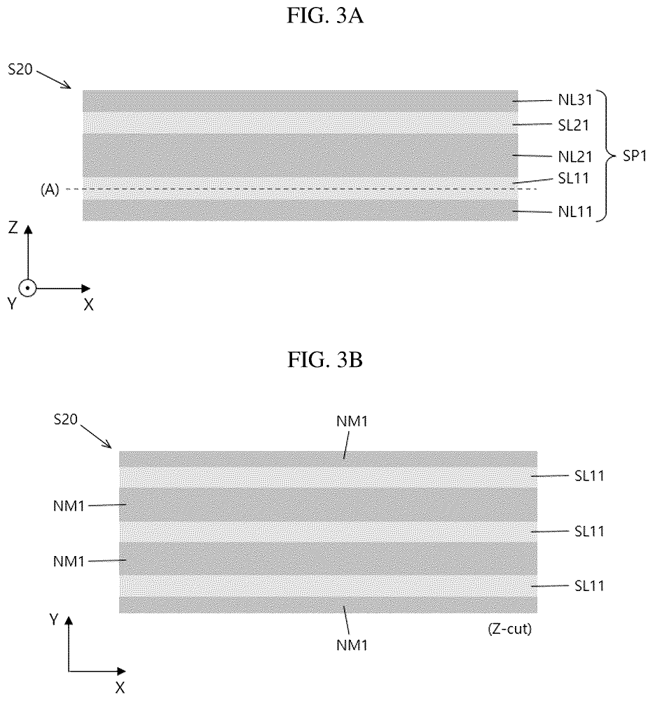

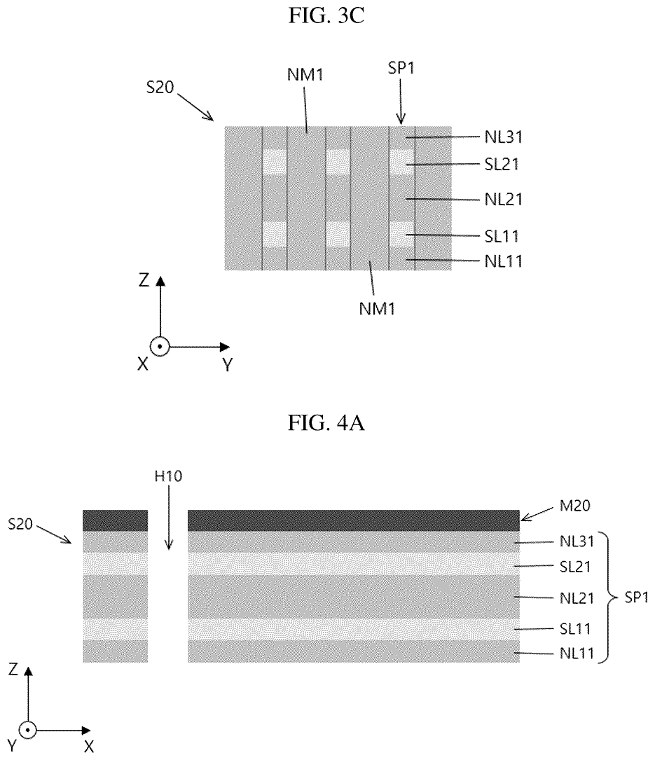

Referring to FIG. 3A to FIG. 3C, a structure S20 including the patterned stack (S11 in FIG. 2A) and an insulating material NM1 may be formed by filling the empty spaces on both sides of at least one pattern portion SP1 with the insulating material NM1. Here, FIG. 3B may be a cross-sectional diagram taken along line (A) of FIG. 3A.

The insulating material NM1 may be referred to as an ‘insulating material layer’ or an ‘insulating material layer pattern’, and may have the same (or substantially the same) height as the pattern portion SP1. The insulating material NM1 may be formed of the same material as the first to third insulating layers NL11, NL21, and NL31. For example, the insulating material NM1 may include a silicon nitride (e.g., SiNx) or may be formed of a silicon nitride (e.g., SiNx). Accordingly, a plurality of first sacrificial layer patterns SL11 and a plurality of second sacrificial layer patterns SL21 formed of a second material may be disposed in a matrix material layer formed of a first material, and the second material may have an etching selectivity with respect to the first material.

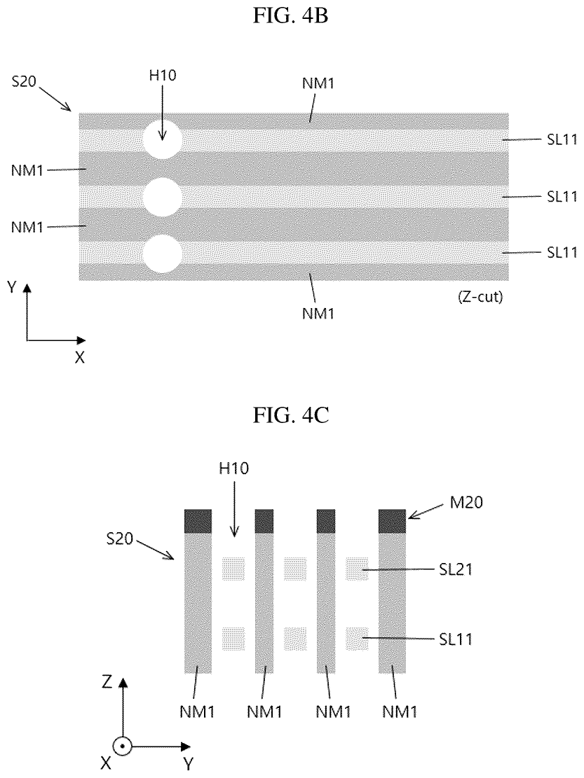

Referring to FIG. 4A to FIG. 4C, a first vertical hole H10 penetrating through the first sacrificial layer pattern SL11 of the pattern portion SP1 may be formed in the structure S20. The first vertical hole H10 may be formed to penetrate through the second sacrificial layer pattern SL21 and the first sacrificial layer pattern SL11. The first vertical hole H10 may be formed to penetrate from the third insulating layer NL31 to the first insulating layer NL11 of the pattern portion SP1 in a predetermined region of the structure S20. The first vertical hole H10 may correspond to a region where a bit line will be formed later. The first vertical hole H10 may be formed in a region of the structure S20 where a transistor will be formed, that is, a transistor formation region (transistor formation planned region). A plurality of first vertical holes H10 may be formed to be spaced apart from each other in the Y-axis direction. As the first vertical hole H10 is formed, the side surfaces of the first sacrificial layer pattern SL11 and the second sacrificial layer pattern SL21 may be exposed.

A second mask pattern M20 may be used to form the first vertical hole H10. The second mask pattern M20 may have a predetermined opening pattern. The second mask pattern M20 may be, for example, a photoresist pattern. After forming the first vertical hole H10, the second mask pattern M20 may be removed.

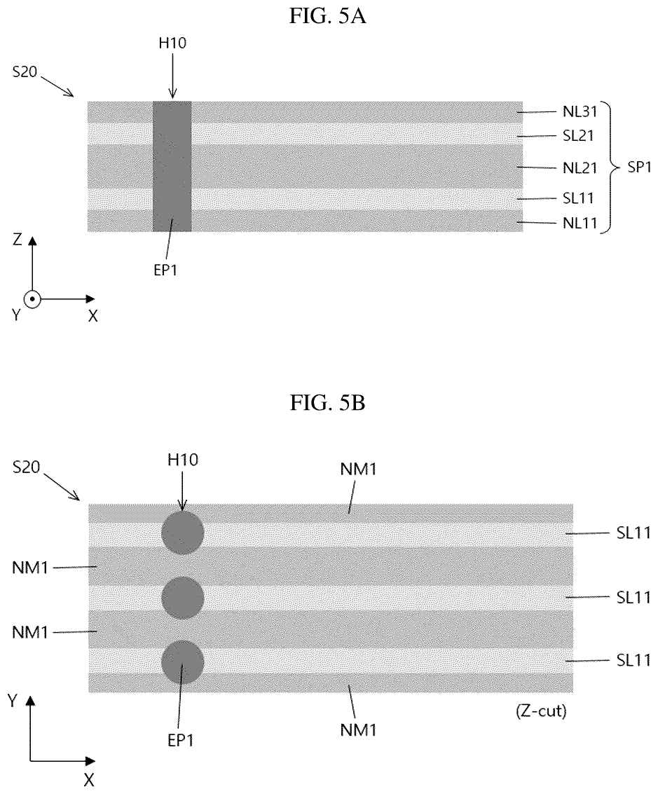

Referring to FIG. 5A to FIG. 5C, an epitaxial material plug EP1 filling the first vertical hole H10 may be formed from the substrate (not shown) by using an epitaxial growth method. The epitaxial material plug EP1 that fills the first vertical hole H10 may be formed from an upper surface portion of the substrate exposed by the first vertical hole H10 by using an epitaxial growth process. Therefore, the epitaxial growth method may be referred to as a selective epitaxial growth (SEG) method.

The epitaxial material plug EP1 may include a single crystal semiconductor. For example, the epitaxial material plug EP1 may include a single crystal Si. The epitaxial material plug EP1 may be made of a single crystal Si. However, the material of the epitaxial material plug EP1 is not limited to a single crystal Si. In some cases, the epitaxial material plug EP1 may include other material such as a single-crystal Ge or a single-crystal SiGe, or may be composed of the other material.

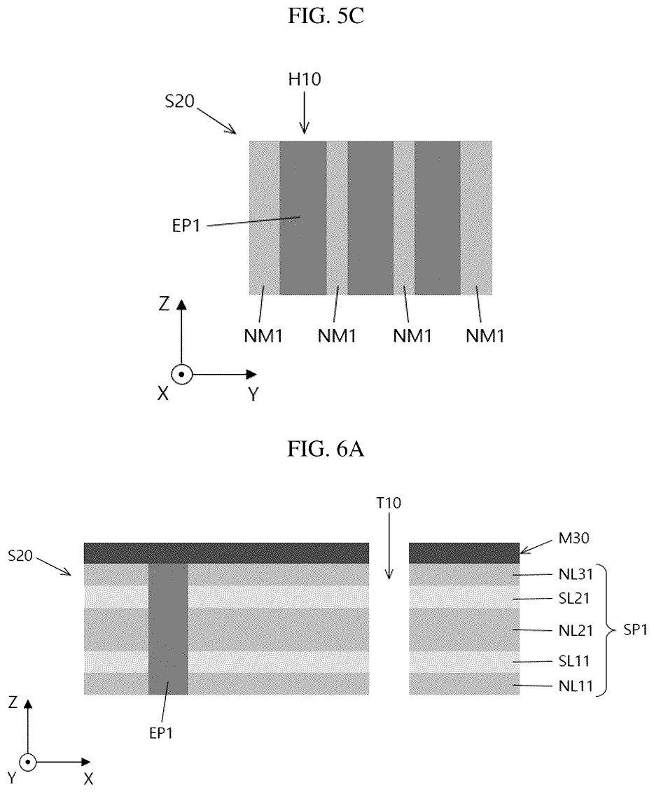

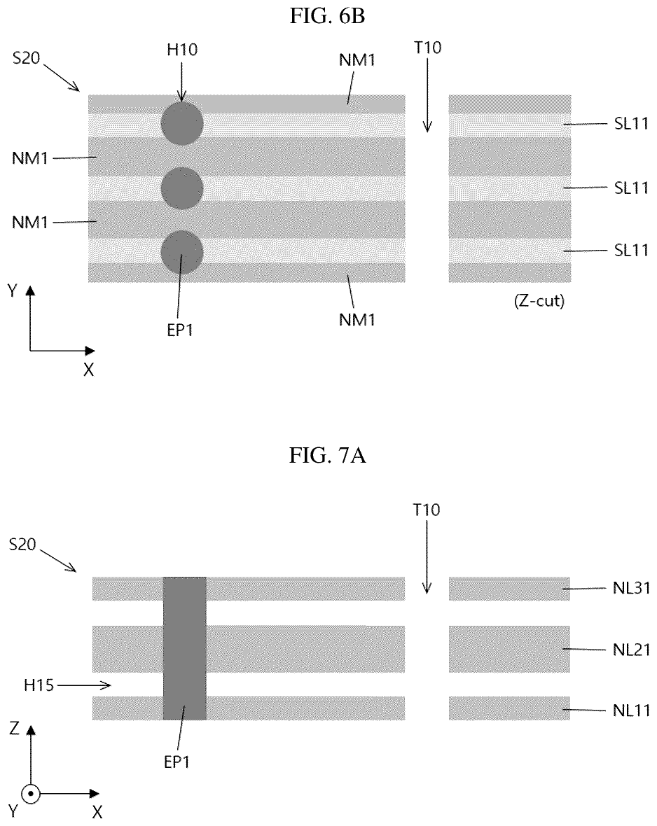

Referring to FIG. 6A and FIG. 6B, a first etched portion T10 spaced apart from the epitaxial material plug EP1 may be formed in the structure S20. The first etched portion T10 may be formed in a capacitor formation region adjacent to the transistor formation region in the structure S20. The first etched portion T10 may have a trench shape. Accordingly, the first etched portion T10 may be referred to as a first trench. The first etched portion T10 may be formed to penetrate from the third insulating layer NL31 to the first insulating layer NL11 and may have a shape extending in the Y-axis direction. The first etched portion T10 may have a line pattern shape.

A third mask pattern M30 may be used to form the first etched portion T10. The third mask pattern M30 may have a predetermined opening area. The third mask pattern M30 may be, for example, a photoresist pattern. After forming the first etched portion T10, the third mask pattern M30 may be removed.

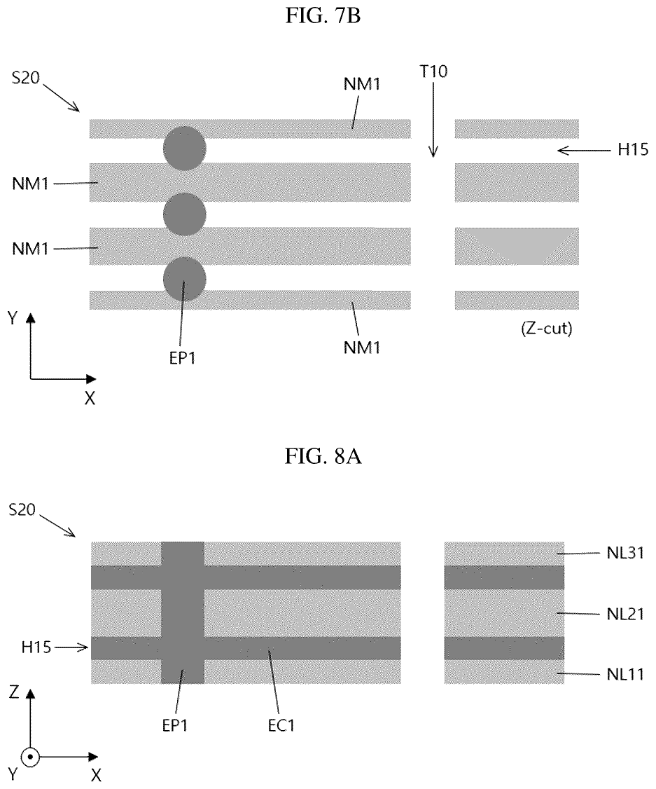

Referring to FIG. 7A and FIG. 7B, a horizontal hole H15 extending in the first direction, for example, the X-axis direction may be formed by removing the first sacrificial layer pattern (SL11 in FIG. 6A) and the second sacrificial layer pattern (SL21 in FIG. 6A) exposed by the first etched portion T10. The first sacrificial layer pattern (SL11 in FIG. 6A) and the second sacrificial layer pattern (SL21 in FIG. 6A) may be selectively removed by using a wet etching process using a wet etchant having etching selectivity for the first sacrificial layer pattern (SL11 in FIG. 6A) and the second sacrificial layer pattern (SL21 in FIG. 6A). The horizontal hole H15 formed by removing the first sacrificial layer pattern (SL11 in FIG. 6A) may be referred to as a first horizontal hole, and the horizontal hole H15 formed by removing the second sacrificial layer pattern (SL21 in FIG. 6A) may be referred to as a second horizontal hole. The horizontal hole H15 may have a line shape extending in the X-axis direction.

According to one embodiment, the entire first sacrificial layer pattern (SL11 in FIG. 6A) may be removed in the step for forming the horizontal hole H15. Furthermore, in the step for forming the horizontal hole H15, the entire second sacrificial layer pattern (SL21 in FIG. 6A) may be removed. Accordingly, the horizontal hole H15 may be formed to extend not only to the region where a transistor will be formed (i.e., the transistor formation region) but also to the region where a capacitor will be formed (i.e., the capacitor formation region). In this step, when the entire first sacrificial layer pattern (SL11 in FIG. 6A) and the entire second sacrificial layer pattern (SL21 in FIG. 6A) are removed, an effect that a process may be simplified may be obtained in connection with this removal.

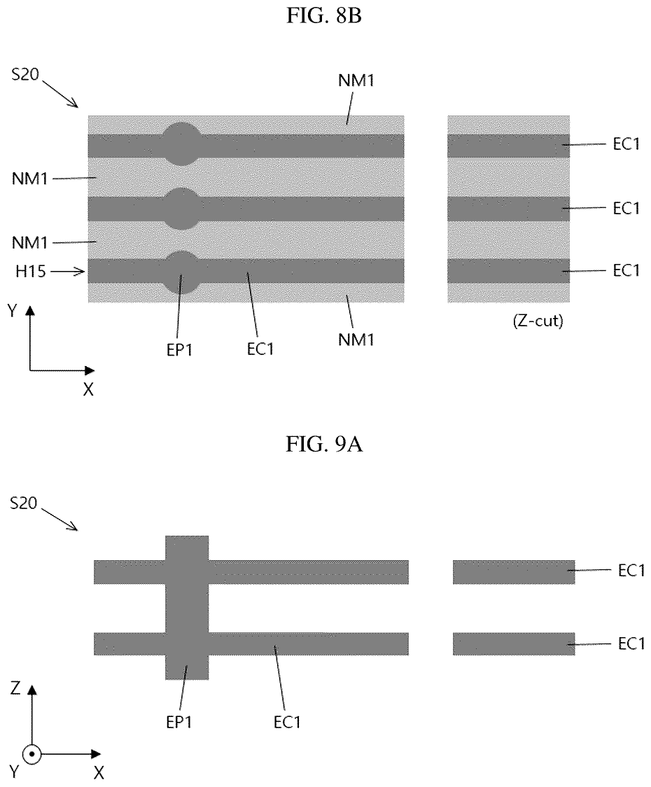

Referring to FIG. 8A and FIG. 8B, an epitaxial channel material layer EC1 filling the horizontal hole H15 may be formed from the side surface of the epitaxial material plug EP1 by using an epitaxial growth method. The epitaxial channel material layer EC1 filling the horizontal hole H15 may be formed from a side surface portion of the epitaxial material plug EP1 exposed by the horizontal hole H15 by using an epitaxial growth process. Therefore, the epitaxial growth method may be referred to as a selective epitaxial growth (SEG) method.

The epitaxial channel material layer EC1 may include a single crystal semiconductor. For example, the epitaxial channel material layer EC1 may include single crystal Si. The epitaxial channel material layer EC1 may be composed of single crystal Si. However, the material of the epitaxial channel material layer EC1 is not limited to single crystal Si. In some cases, the epitaxial channel material layer EC1 may include other material such as a single-crystal Ge or a single-crystal SiGe, or may be composed of the other material. Since the epitaxial channel material layer EC1 may be composed of a single crystal material, a transistor formed by applying the epitaxial channel material layer EC1 may have excellent performance such as high mobility. Furthermore, when forming the epitaxial channel material layer EC1 as in the embodiment of the present invention, the epitaxial channel material layers EC1 may have excellent thickness uniformity.

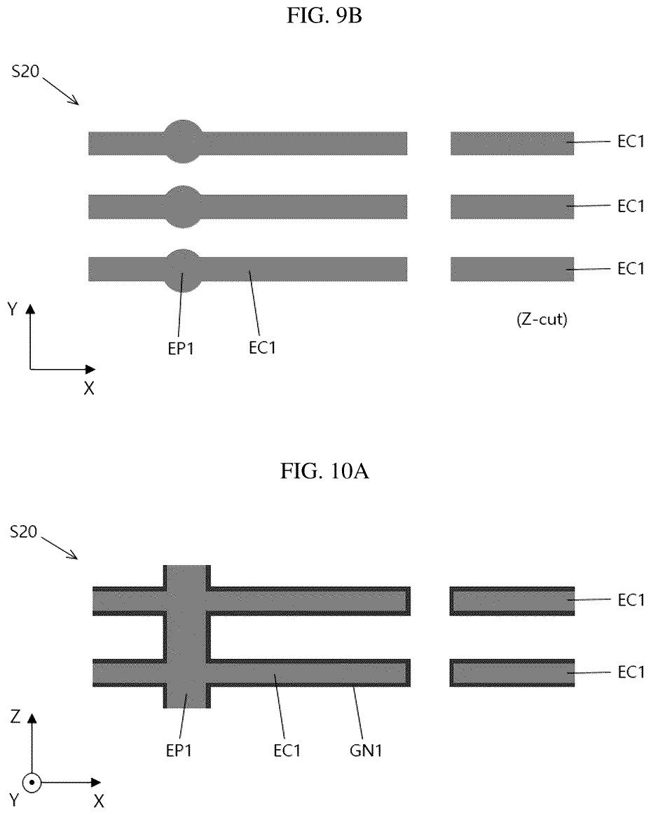

Referring to FIG. 9A and FIG. 9B, an empty region may be formed around the epitaxial material plug EP1 and the epitaxial channel material layer EC1 by removing the first to the third insulating layers (NL11, NL21, and NL31 in FIG. 8A) and the insulating material (NM1 in FIG. 8B) from the structure S20. Since the first to the third insulating layers (NL11, NL21, and NL31 in FIG. 8A) and the insulating material (NM1 in FIG. 8B) may be the same material, they may be easily removed by using an etching method having etching selectivity.

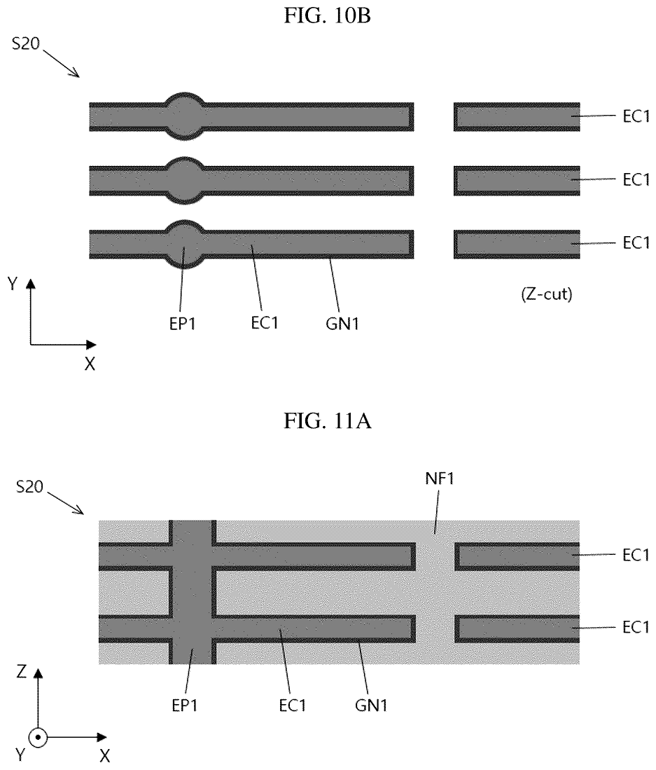

Referring to FIG. 10A and FIG. 10B, a gate insulating material layer GN1 may be formed on surface portions of the epitaxial material plug EP1 and the epitaxial channel material layer EC1. According to one embodiment, the gate insulating material layer GN1 may be formed by using a thermal oxidation process on surface portions of the epitaxial material plug EP1 and the epitaxial channel material layer EC1. In this case, the gate insulating material layer GN1 may be an oxide layer. For example, the gate insulating material layer GN1 may be a silicon oxide layer.

However, the formation method and constituting material of the gate insulating material layer GN1 are not limited to the above and may vary in various ways. For example, the gate insulating material layer GN1 may also be formed by using an atomic layer deposition (ALD) process. In this case, the gate insulating material layer GN1 may be formed to include at least any one selected from a silicon oxide, a silicon nitride, a silicon oxynitride, and a high-k material. Here, the high-k material may be a material with a higher dielectric constant than that of a silicon nitride.

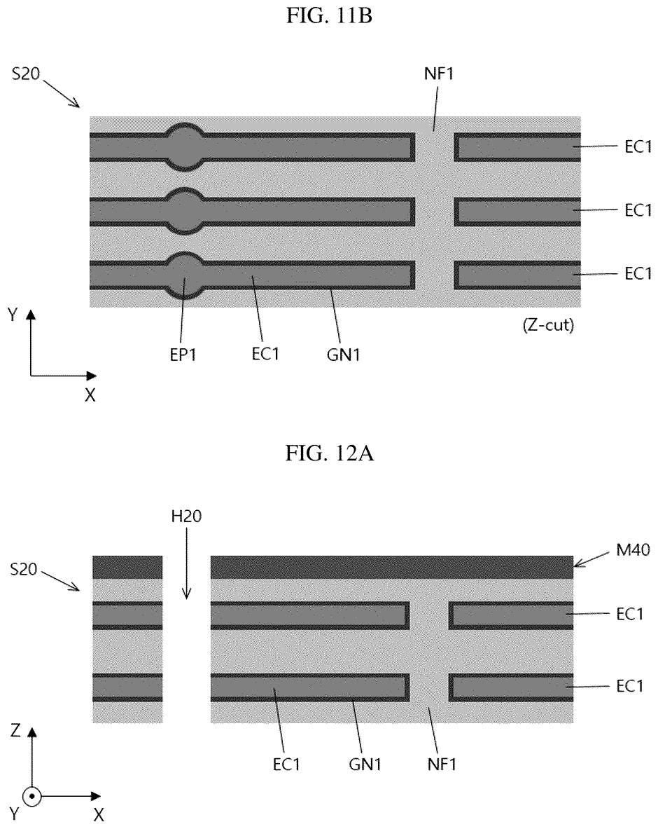

Referring to FIG. 11A and FIG. 11B, a filling insulating layer NF1 may be formed on the gate insulating material layer GN1 to fill the empty region. That is, the filling insulating layer NF1 which fills the empty region around the epitaxial material plug EP1 and the epitaxial channel material layer EC1 may be formed on the gate insulating material layer GN1. As a non-limiting example, the filling insulating layer NF1 may include a silicon nitride (e.g., SiNₓ) or may be formed of a silicon nitride (e.g., SiNₓ). The filling insulating layer NF1 may be formed of a material other than silicon nitride. When forming the filling insulating layer NF1, after depositing an insulator for the filling insulating layer NF1, a planarization process may be further performed on its upper surface and surrounding area.

In this step, the structure S20 may include the epitaxial material plug EP1, the epitaxial channel material layer EC1, the gate insulating material layer GN1, and the filling insulating layer NF1. The structure S20 may include an epitaxial material plug EP1 extending in a vertical direction on the substrate (not shown), an epitaxial channel material layer EC1 extending in a horizontal direction from a side surface of the epitaxial material plug EP1, the gate insulating material layer GN1 formed on at least a surface portion of the epitaxial channel material layer EC1, and the filling insulating layer NF1 formed on the gate insulating material layer GN1 and filling a space surrounding the epitaxial material plug EP1 and the epitaxial channel material layer EC1. Here, the gate insulating material layer GN1 may be formed on surface portions of the epitaxial material plug EP1 and the epitaxial channel material layer EC1.

The method of preparing the structure S20 as shown in FIG. 11A and FIG. 11B may vary. In other words, the process described with reference to FIG. 1A to FIG. 11B may be modified in various ways.

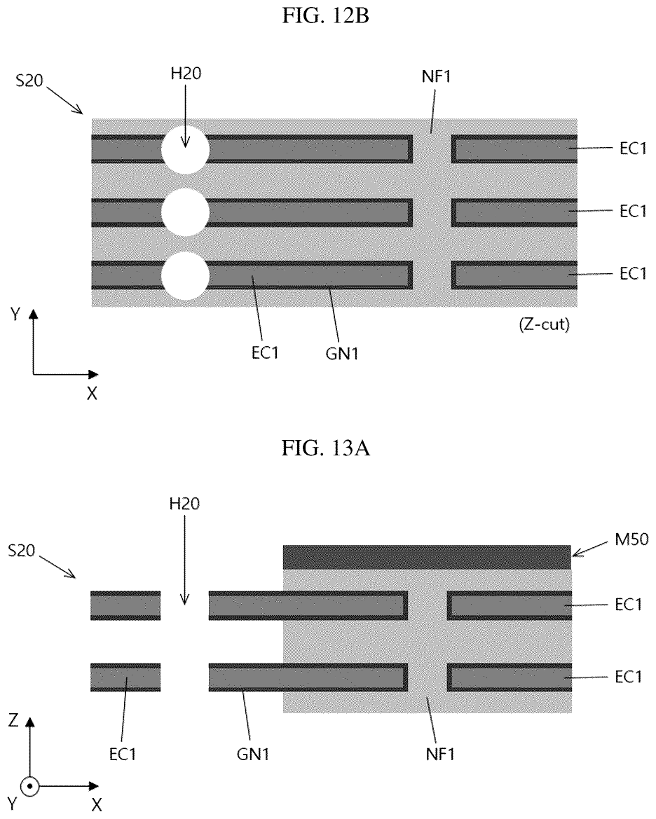

Referring to FIG. 12A and FIG. 12B, in the structure S20 in which the gate insulating material layer GN1 and the filling insulating layer NF1 are formed, a second vertical hole H20 may be formed in a region corresponding to the first vertical hole (H10 in FIG. 4A). The second vertical hole H20 be formed to penetrate through the filling insulating layer NF1 in the vertical direction. For reference, the expression ‘corresponding’ in this specification may mean the same thing, but may be a general concept that broadly encompasses substantially the same or similar things. This may be applied equally throughout this specification.

A fourth mask pattern M40 may be used to form the second vertical hole H20. The fourth mask pattern M40 may have a predetermined opening pattern. The fourth mask pattern M40 may be, for example, a photoresist pattern. After forming the second vertical hole H20, the fourth mask pattern M40 may be removed.

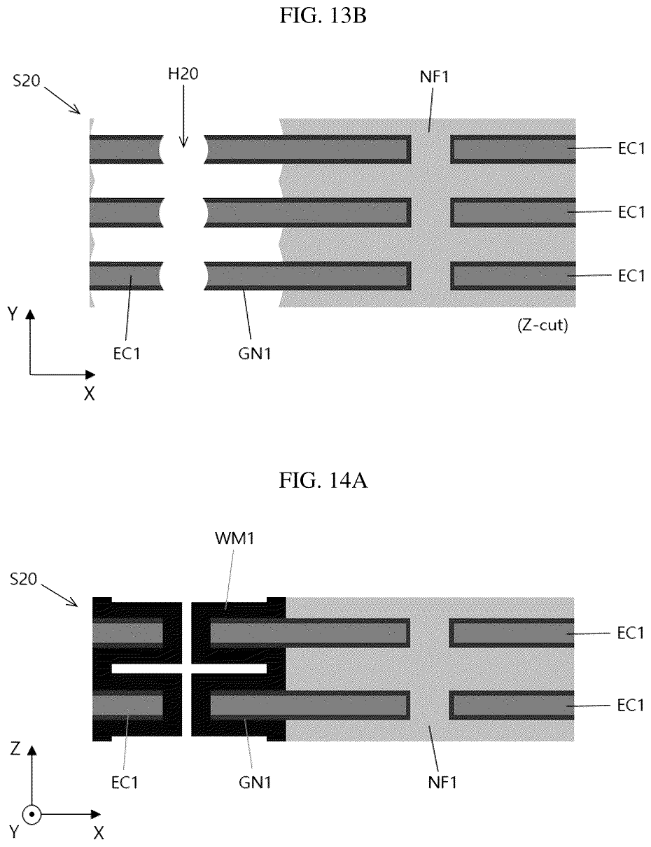

Referring to FIG. 13A and FIG. 13B, the gate insulating material layer GN1 may be exposed by removing the filling insulating layer NF1 from the transistor formation region (transistor formation planned region) around the second vertical hole H20 of the structure S20. At this time, a fifth mask pattern M50 may be formed on a capacitor formation region (capacitor formation planned region) adjacent to the transistor formation region (transistor formation planned region), and the fifth mask pattern M50 may be formed to expose the transistor formation region. The filling insulating layer NF1 may be removed by etching from the transistor formation region by using the fifth mask pattern M50 as an etching mask. Afterwards, the fifth mask pattern M50 may be removed.

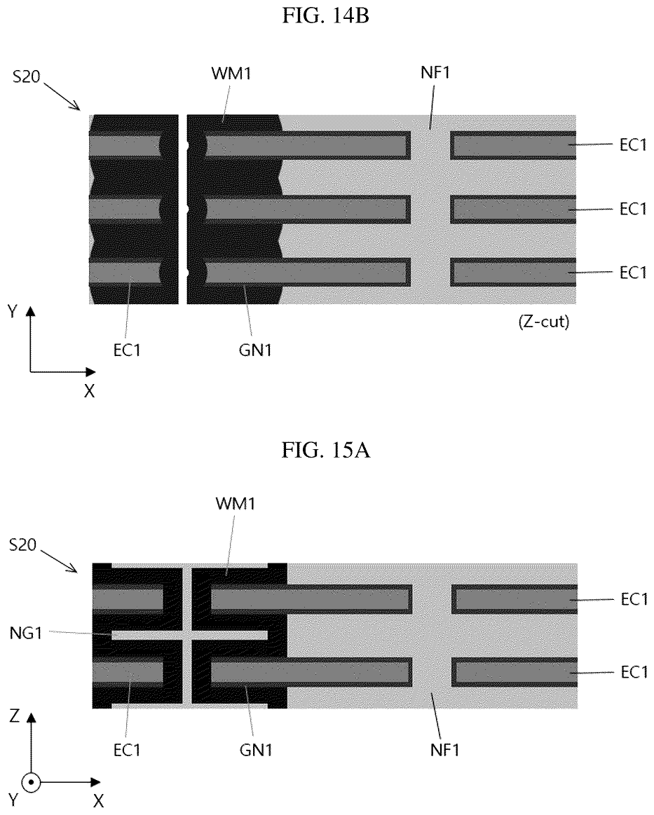

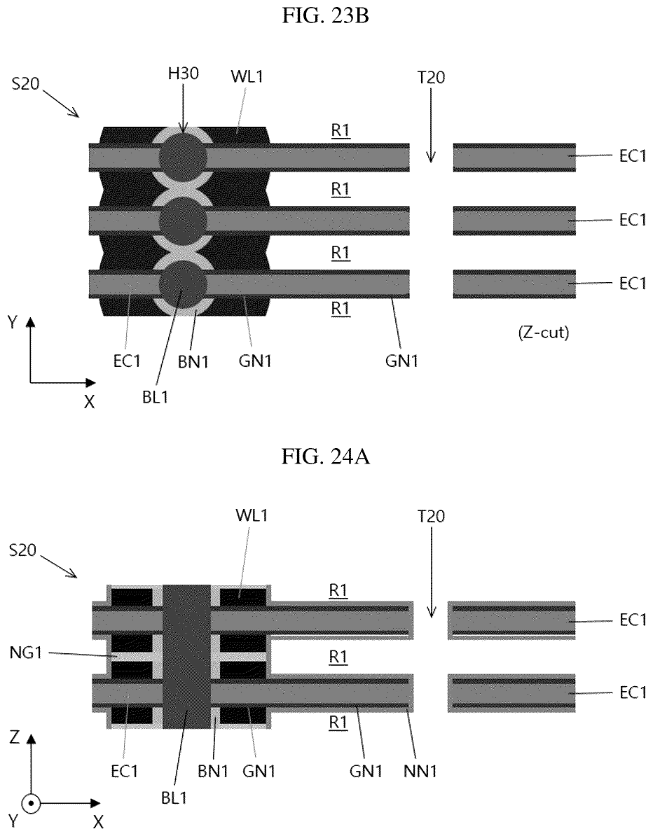

Then, a word line (WL1 in FIG. 23A) surrounding an exposed portion of the gate insulating material layer GN1 in the transistor formation region may be formed by using the method as illustrated in FIG. 14A to FIG. 23B, and thus, a transistor may be defined.

Referring to FIG. 14A and FIG. 14B, a word line material layer WM1 surrounding the exposed portion of the gate insulating material layer GN1 in the transistor formation region may be formed. The word line material layer WM1 may be formed substantially conformally according to the shape of the surface regions exposed in the transistor formation region. The word line material layer WM1 may be formed through, for example, an ALD process. At this time, as shown in FIG. 14A, the gap in the Z-axis direction between the lower and upper epitaxial channel material layers EC1 may be larger than approximately twice the thickness of the word line material layer WM1. Furthermore, the gap in the Z-axis direction between the lower and upper gate insulating material layers GN1 may be larger than about twice the thickness of the word line material layer WM1. Meanwhile, as shown in FIG. 14B, the gap in the Y-axis direction between two epitaxial channel material layers EC1 spaced apart in the Y-axis direction may be smaller than about twice the thickness of the word line material layer WM1. Furthermore, the gap in the Y-axis direction between the two gate insulating material layers GN1 spaced apart in the Y-axis direction may be less than about twice the thickness of the word line material layer WM1.

The word line material layer WM1 may be formed to surround each epitaxial channel material layer EC1 in the transistor formation region. Furthermore, the word line material layer WM1 may have a line shape extending in the Y-axis direction.

Referring to FIG. 15A and FIG. 15B, a gap filling insulating layer NG1 may be formed to fill the empty space of the curved portion (bent portion) of the word line material layer WM1. The gap filling insulating layer NG1 may be formed of an insulating oxide or another insulating material.

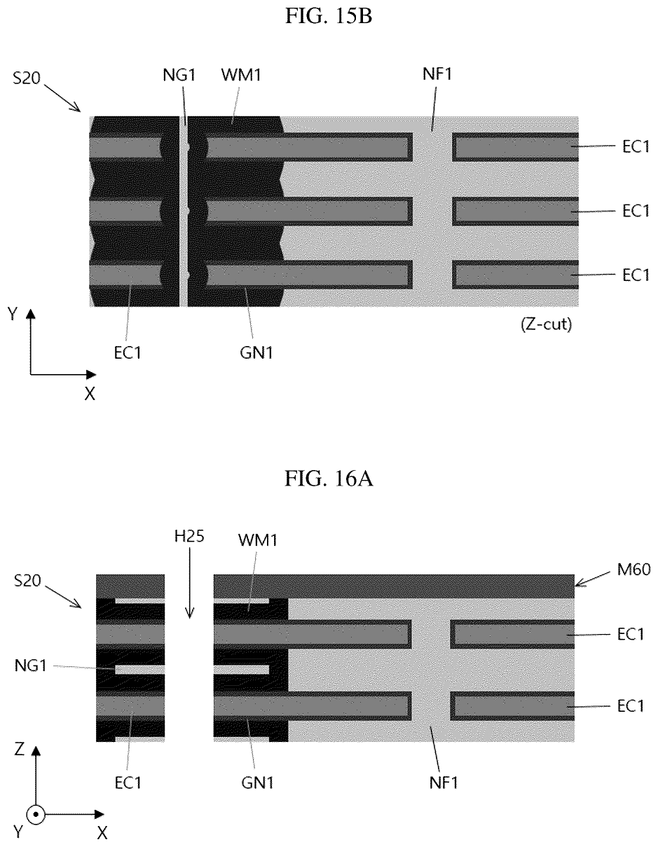

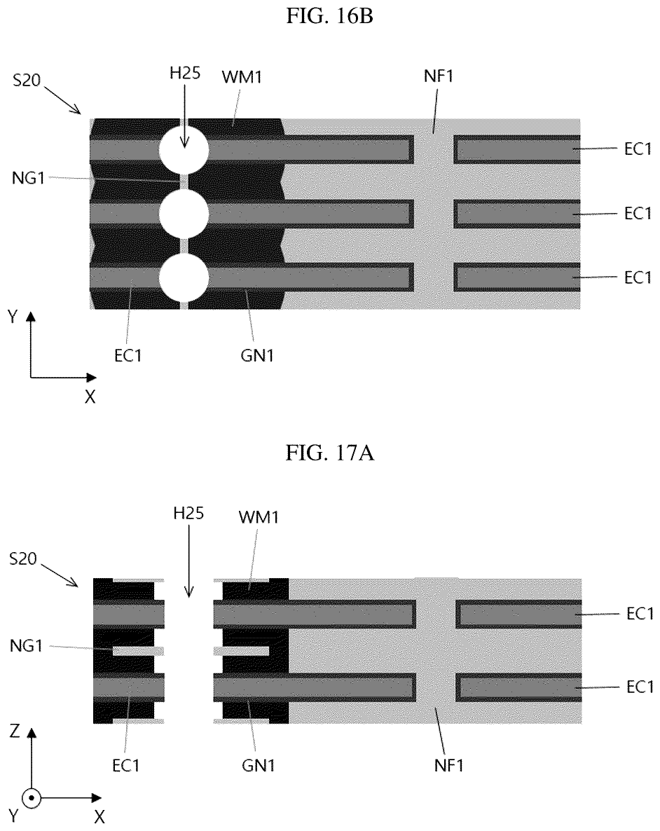

Referring to FIG. 16A and FIG. 16B, a through hole H25 may be formed by etching a region corresponding to the second vertical hole (H20 in FIG. 12A) in the word line material layer WM1. The through hole (H25) may be a vertical hole. A sixth mask pattern M60 may be used to form the through hole H25. The sixth mask pattern M60 may have a predetermined opening pattern. The sixth mask pattern M60 may be, for example, a photoresist pattern. After forming the through hole H25, the sixth mask pattern M60 may be removed.

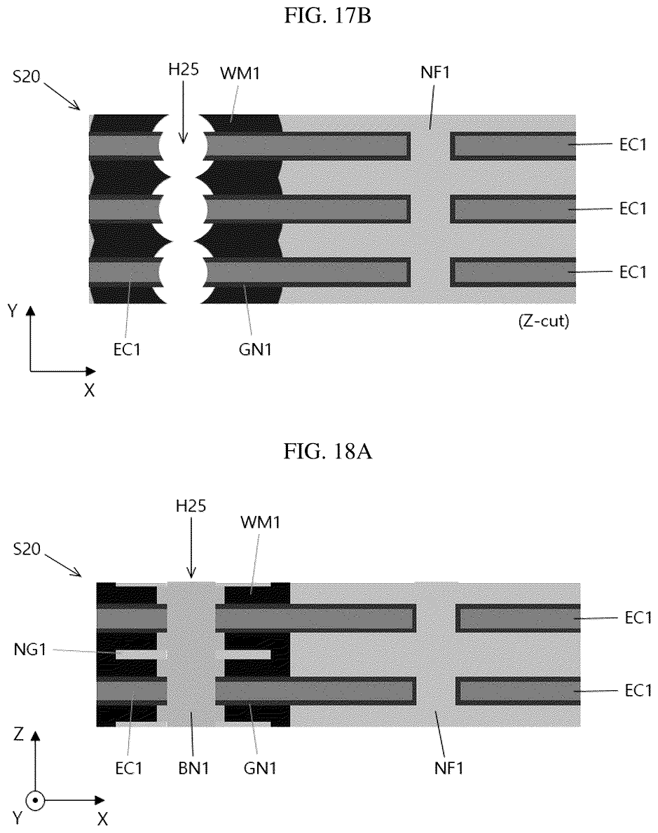

Referring to FIG. 17A and FIG. 17B, a portion of the word line material WM1 exposed through the through hole H25 may be recessed so that one end of the epitaxial channel material layer EC1 may protrude toward the through hole H25 rather than the word line material layer WM1. Therefore, a portion of the word line material layer WM1 may be etched around the through hole H25, and the etched regions (recess regions) may be connected in the Y-axis direction.

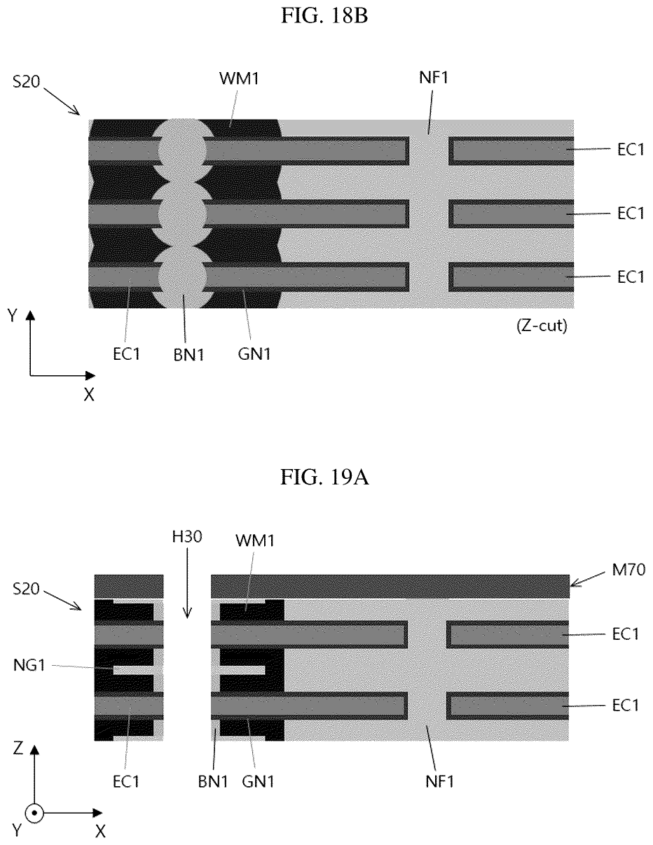

Referring to FIG. 18A and FIG. 18B, a body insulating layer BN1 may be formed to fill the through hole H25 and the etching regions (recess regions) surrounding the through hole H25. The body insulating layer BN1 may be formed of an insulating oxide or another insulating material. The body insulating layer BN1 may be formed of the same material as the gap filling insulating layer NG1 or may be formed of a different material.

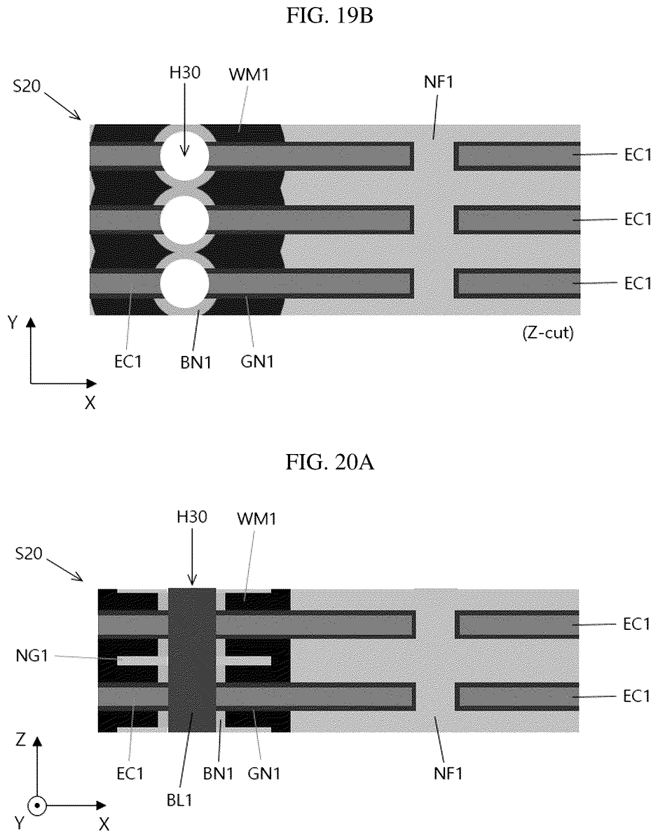

Referring to FIG. 19A and FIG. 19B, a third vertical hole H30 may be formed in a region corresponding to the second vertical hole (H20 in FIG. 12A) of the body insulating layer BN1. A seventh mask pattern M70 may be used to form the third vertical hole H30. The seventh mask pattern M70 may have a predetermined opening pattern. The seventh mask pattern M70 may be, for example, a photoresist pattern. After forming the third vertical hole H30, the seventh mask pattern M70 may be removed.

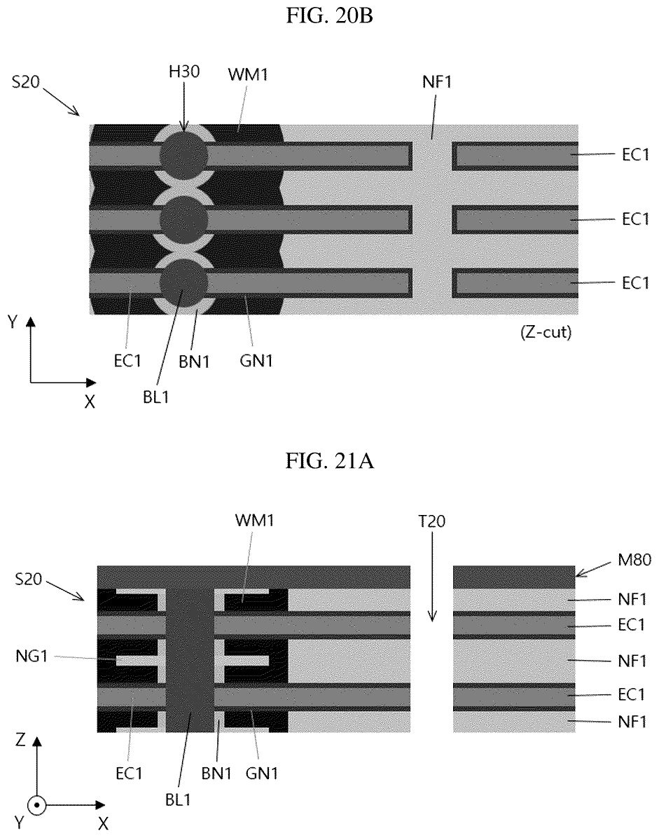

Referring to FIG. 20A and FIG. 20B, a bit line BL1 may be formed in the third vertical hole H30. The bit line BL1 may be connected to (contact) one end of the epitaxial channel material layer EC1. Accordingly, the bit line BL1 may be formed to be connected to (contact) one end of the epitaxial channel material layer EC1 in a region corresponding to the second vertical hole (H20 in FIG. 12A) in the transistor formation region. The bit line BL1 may have a pillar shape penetrating through the structure S20 in the vertical direction. The bit line BL1 may be electrically connected to the one end of the epitaxial channel material layer EC1 in the lateral direction. A plurality of bit lines BL1 connected to a plurality of epitaxial channel material layers EC1 may be formed.

Although not shown, if there is a conductive material of the bit line BL1 deposited above the third vertical hole H30, it may be removed through, for example, an etchback process.

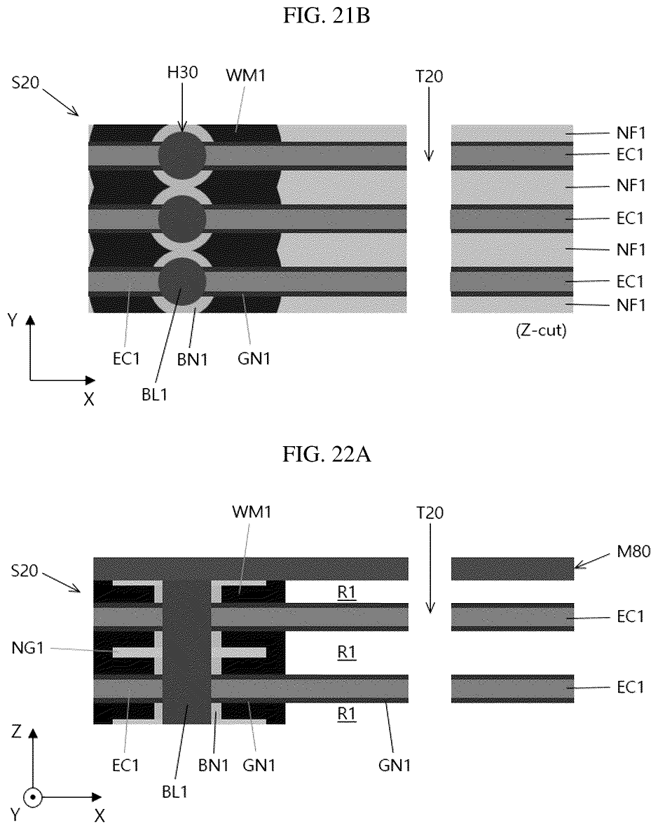

Referring to FIG. 21A and FIG. 21B, a second etched portion T20 spaced apart from the bit line BL1 may be formed in the capacitor formation region of the structure S20. The second etched portion T20 may have a trench shape. Accordingly, the second etched portion T20 may be referred to as a second trench. The second etched portion T20 may be formed to penetrate through the filling insulating layer NF1 and may have a shape extending in the Y-axis direction. The second etched portion T20 may have a line pattern shape. The second etch section T20 may be formed in a region corresponding to the first etched portion (T10 in FIG. 6A).

According to one embodiment, the second etched portion T20 may be formed by etching a portion of the filling insulating layer NF1 and a portion of the gate insulating material layer GN1. An end of the gate insulating material layer GN1 and an end of the epitaxial channel material layer EC1 may be exposed toward the second etched portion T20.

An eighth mask pattern M80 may be used to form the second etched portion T20. The eighth mask pattern M80 may have a predetermined opening region. The eighth mask pattern M80 may be, for example, a photoresist pattern.

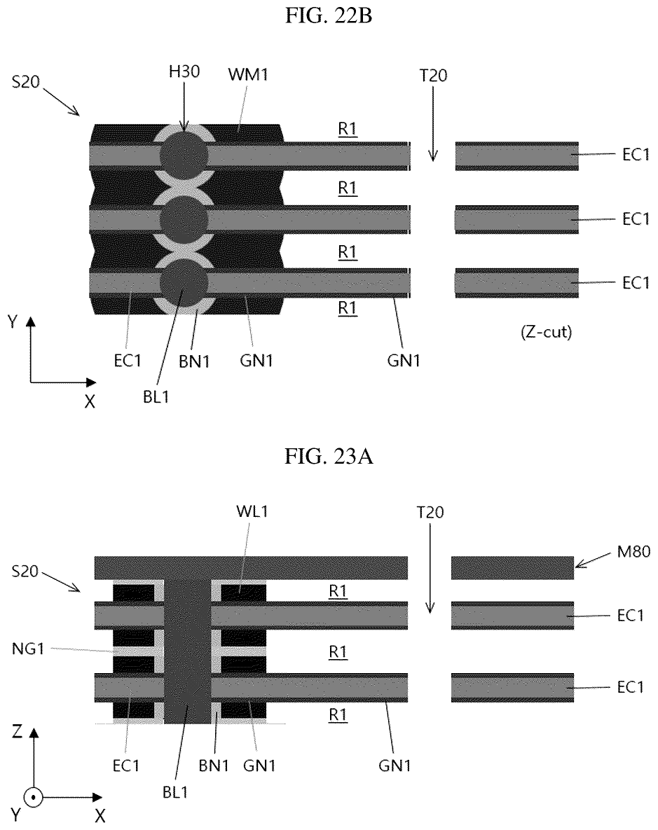

Referring to FIG. 22A and FIG. 22B, a first recess (first recess portion) R1 exposing the gate insulating material layer GN1 and the word line material layer WM1 may be formed by removing (etching) the filling insulating layer (NF1 in FIG. 21A) exposed by the second etched portion T20 in the capacitor formation region.

Referring to FIG. 23A and FIG. 23B, after the first recess R1 is formed in the capacitor formation region, a portion of the word line material layer (WM1 in FIG. 22A) exposed by the first recess R1 may be recessed. In other words, a portion of the word line material layer (WM1 in FIG. 22A) exposed toward the capacitor formation region may be recessed. As a result, the word line material layer portion surrounding the lower epitaxial channel material layer EC1 and the word line material layer portion surrounding the upper epitaxial channel material layer EC1 may be separated from each other. Here, the separated portion of the word line material layer may be referred to as the word line WL1. Afterwards, the eighth mask pattern M80 may be removed. However, the removal timing of the eighth mask pattern M80 may vary.

The word line WL1 may have a structure surrounding the gate insulating material layer GN1. Accordingly, the transistor including the word line WL1 may have a gate-all-around (GAA) structure. In this regard, the transistor may have excellent gate controllability and high on-current characteristics.

Although the method of forming the word line WL1 has been described in detail with reference to FIG. 14A to FIG. 23B, this is merely an example, and the method of forming the word line WL1 may vary depending on the case.

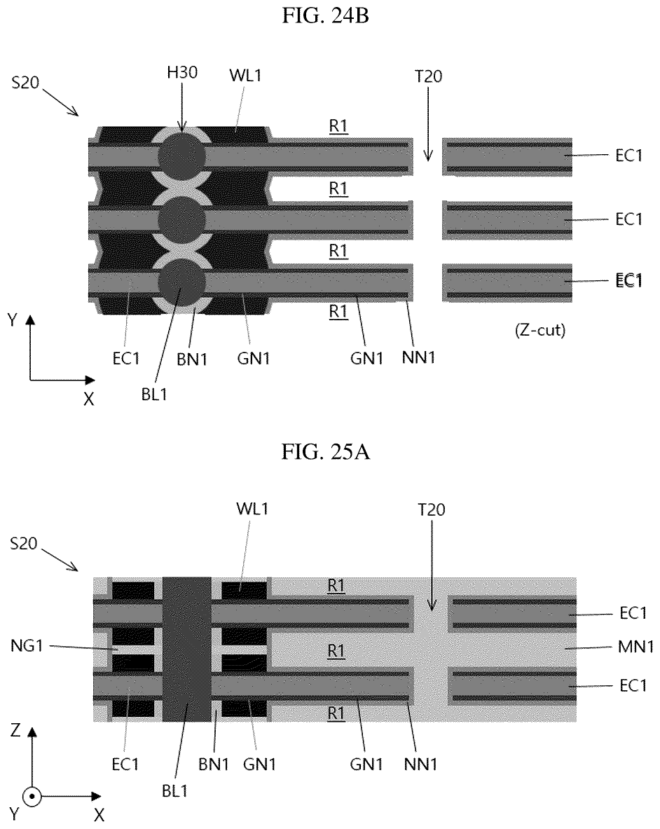

Referring to FIG. 24A and FIG. 24B, after forming the first recess R1 in the capacitor formation region, an insertion insulating layer NN1 surrounding an exposed portion of the gate insulating material layer GN1 in the capacitor formation region may be formed. The insertion insulating layer NN1 may be conformally formed on the surface region exposed to the first recess R1. The insertion insulating layer NN1 may be formed to cover surfaces of the gate insulating material layer GN1, the epitaxial channel material layer EC1, and the word line WL1 exposed in the capacitor formation region. The insertion insulating layer NN1 may be formed through, for example, an ALD process. The thickness of the insertion insulating layer NN1 may be as thin as several tens of nm or less. The insertion insulating layer NN1 may be formed of an insulating oxide or another insulating material.

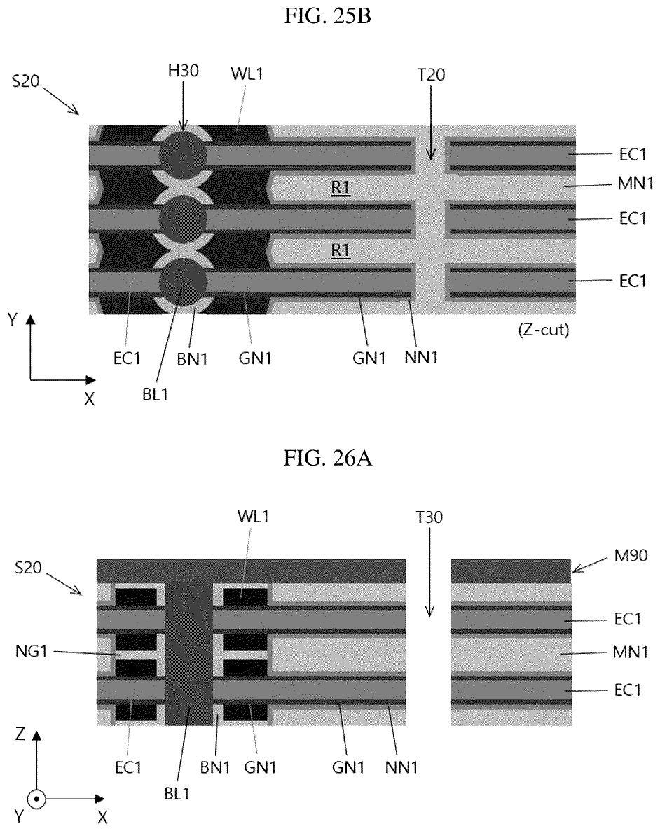

Referring to FIG. 25A and FIG. 25B, a mold insulating layer MN1 filling the first recess R1 may be formed. The mold insulating layer MN1 may be formed to fill the first recess R1 and the second etched portion T20 on the insertion insulating layer NN1. The mold insulating layer MN1 may include, for example, a silicon nitride (e.g., SiNₓ) or may be formed of a silicon nitride (e.g., SiNₓ). When forming the mold insulating layer MN1, after depositing an insulator for the mold insulating layer MN1, a planarization process may be further performed on its upper surface and surrounding area.

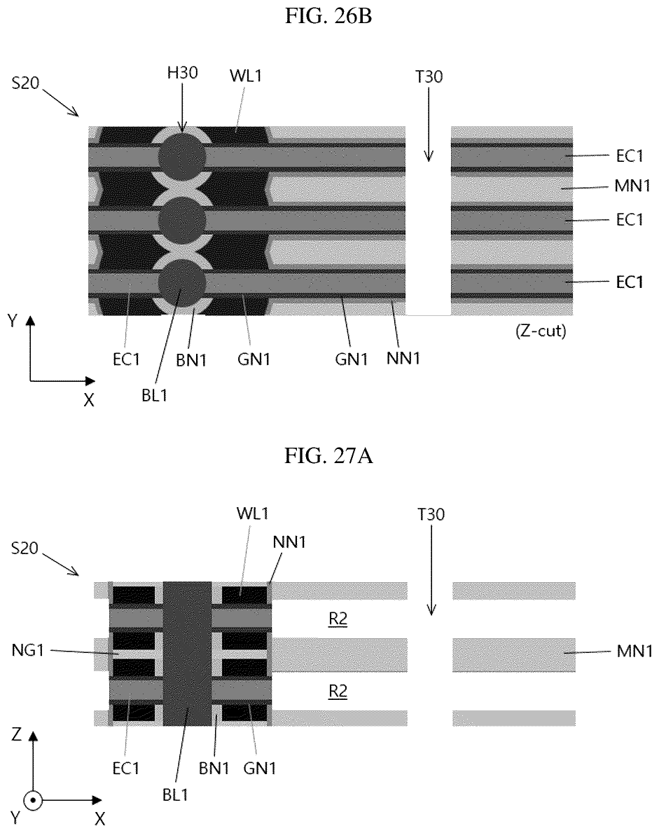

Referring to FIG. 26A and FIG. 26B, a third etched portion T30 may be formed in a region of the mold insulating layer MN1 corresponding to the second etched portion (T20 in FIG. 21A). The third etched portion T30 may be formed by etching a portion of the mold insulating layer MN1 and a portion of the insertion insulating layer NN1. Accordingly, an end of the gate insulating material layer GN1 and an end of the epitaxial channel material layer EC1 may be exposed toward the third etched portion T30. The third etched portion T30 may have a line shape extending in the Y-axis direction. The third etched portion T30 may be referred to as a third trench.

A ninth mask pattern M90 may be used to form the third etched portion T30. The ninth mask pattern M90 may have a predetermined opening area. The ninth mask pattern M90 may be, for example, a photoresist pattern. After forming the third etched portion T30, the ninth mask pattern M90 may be removed.

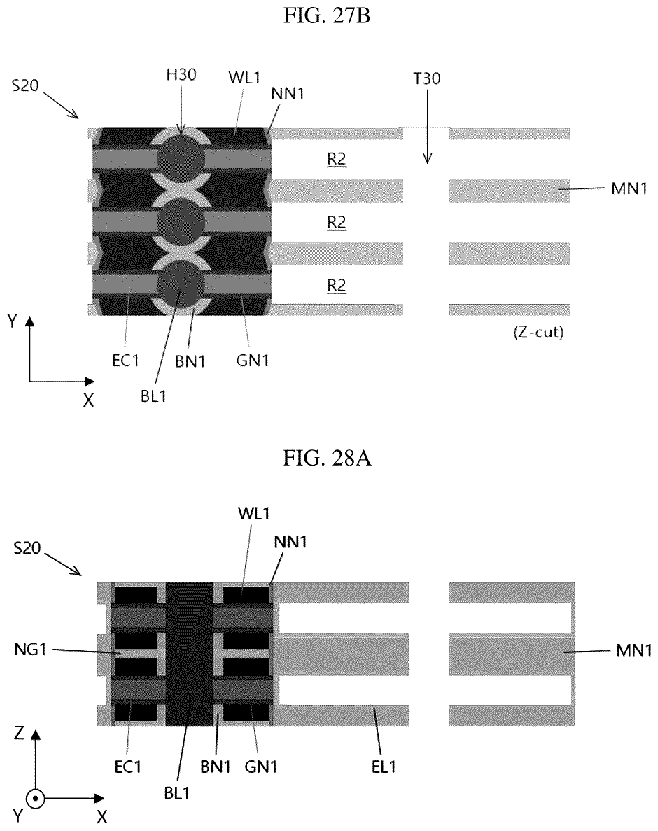

Referring to FIG. 27A and FIG. 27B, a second recess (second recess portion) R2 may be formed by etching the epitaxial channel material layer EC1, the gate insulating material layer GN1, and the insertion insulating layer NN1 exposed by the third etched portion T30. The epitaxial channel material layer EC1, the gate insulating material layer GN1, and the insertion insulating layer NN1 may be etched by injecting a predetermined wet etchant, that is, a wet etching solution through the third etched portion T30. At this time, one or more wet etchants may be used. The second recess R2 may be formed to a region somewhat spaced apart from the word line WL1. The etching range of the epitaxial channel material layer EC1, the gate insulating material layer GN1, and the insertion insulating layer NN1 may be controlled by adjusting the conditions of the etching process.

When the insertion insulating layer NN1 is removed in the step of FIG. 27A after forming the insertion insulating layer NN1 in the previous step of FIG. 24A, the second recess R2 may be formed to have a larger width than that of the remaining gate insulating material layer GN1. Accordingly, the width of the second recess R2 in the Z-axis direction may be larger than the width of the remaining gate insulating material layer GN1 in the Z-axis direction. Furthermore, the width of the second recess R2 in the Y-axis direction may be larger than the width of the remaining gate insulating material layer GN1 in the Y-axis direction. As a result, a process margin for forming a capacitor in a subsequent process may be increased. It may be desirable to form the insertion insulating layer NN1 in order to secure a process margin, and the like. However, the formation of the above-described insertion insulating layer NN1 may be optional and may be omitted in some cases.

Meanwhile, in the step of FIG. 27A, since the epitaxial channel material layer EC1 may be etched and removed by using a wet etching process in the capacitor formation region, this wet etching process may rarely cause etching damage to the epitaxial channel material layer EC1.

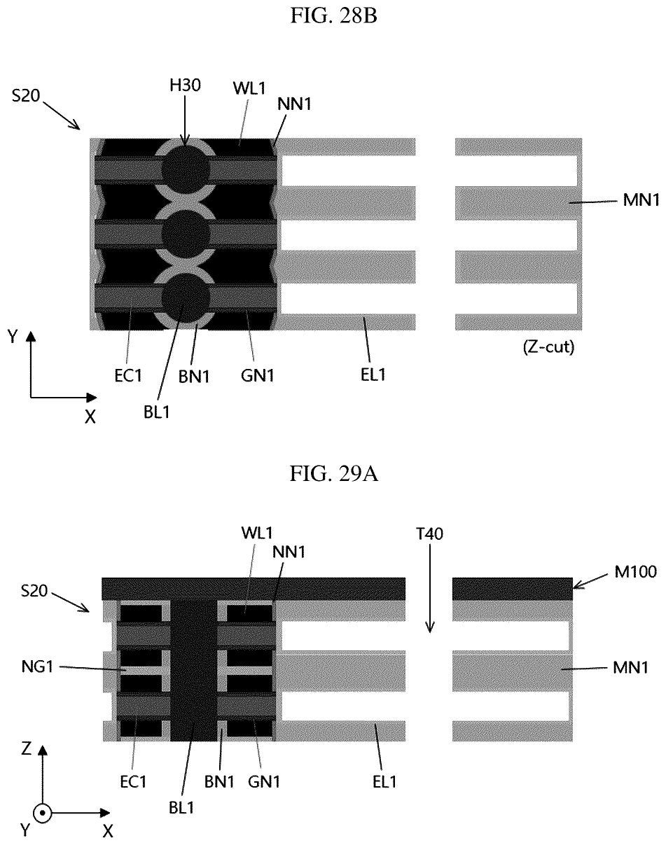

Referring to FIG. 28A and FIG. 28B, an electrode member EL1 connected to the other end of the epitaxial channel material layer EC1 may be formed on an inner surface of the second recess (R2 in FIG. 27A). The electrode member EL1 may be connected to the other end of the epitaxial channel material layer EC1 of the transistor. The electrode member EL1 may be an electrode layer (first electrode layer) for a capacitor. The electrode member EL1 may be conformally formed along the surface shape of the mold insulating layer MN1. The electrode member EL1 may be formed, for example, through an ALD process.

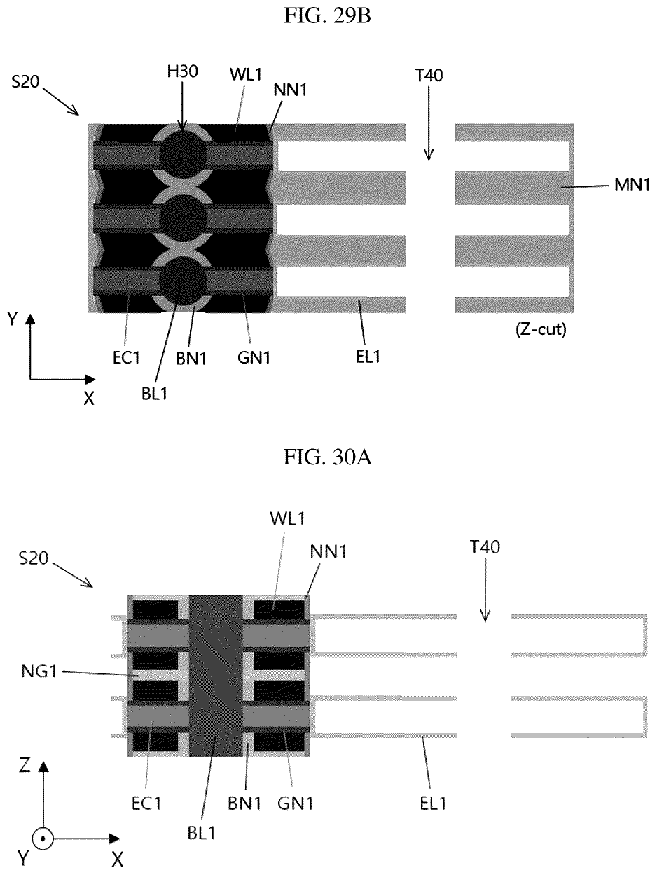

Referring to FIG. 29A and FIG. 29B, a fourth etched portion T40 may be formed in a region corresponding to the third etched portion (T30 in FIG. 26A) in the capacitor formation region. The fourth etched portion T40 may be formed by etching a portion of the electrode member EL1. The fourth etched portion T40 may have a line shape extending in the Y-axis direction. The fourth etched portion T40 may be referred to as a fourth trench. The electrode member EL1 may be separated as an individual capacitor region through this process. In other words, the electrode member EL1 may be separated into a unit cell region.

A tenth mask pattern M100 may be used to form the fourth etched portion T40. The tenth mask pattern M100 may have a predetermined opening region. The tenth mask pattern M100 may be, for example, a photoresist pattern. After forming the fourth etched portion T40, the tenth mask pattern M100 may be removed.

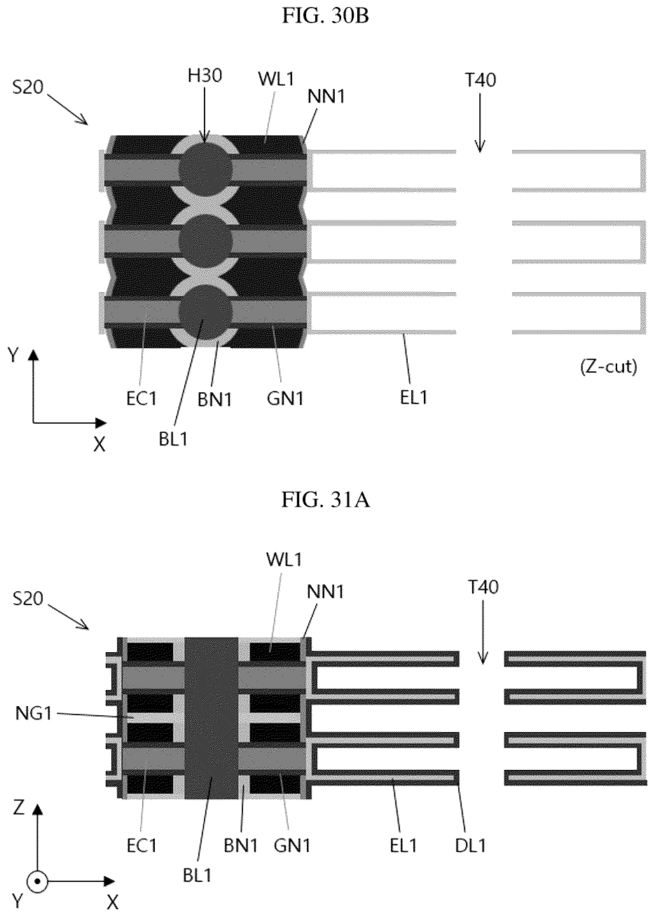

Referring to FIG. 30A and FIG. 30B, an outer surface of the electrode member EL1 may be exposed by etching the mold insulating layer (MN1 in FIG. 29A) after forming the electrode member EL1. In this step, the insertion insulating layer NN1 may be exposed by removing the entire mold insulating layer (MN1 in FIG. 29A). However, if necessary, the etching range of the mold insulating layer (MN1 in FIG. 29A) may be appropriately adjusted. As a method of adjusting the etching range, at least a portion of the tenth mask pattern (M100 in FIG. 29A) may be temporarily maintained, or a separate hard mask (not shown) may be used. If necessary, a portion of the mold insulating layer (MN1 in FIG. 29A) adjacent to the insertion insulating layer NN1 may remain without being etched.

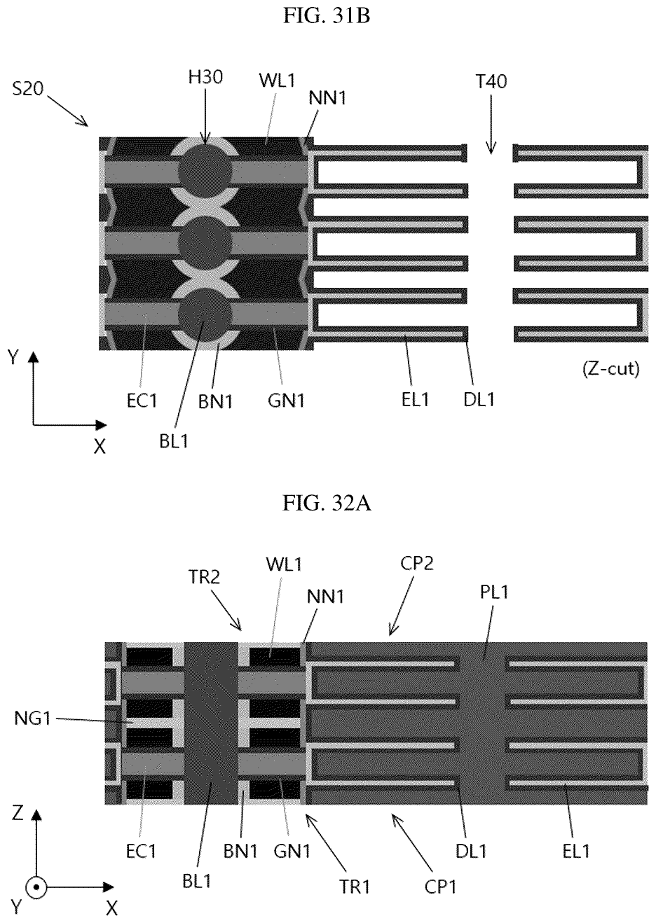

Referring to FIG. 31A and FIG. 31B, a dielectric layer DL1 may be formed on the electrode member EL1 in the capacitor formation region. The dielectric layer DL1 may be a dielectric layer for a capacitor. The dielectric layer DL1 may be formed conformally according to the surface shape of the electrode member EL1. The dielectric layer DL1 may be formed (deposited) through, for example, an ALD process. The dielectric layer DL1 may be formed to include at least any one selected from various dielectric materials. For example, the dielectric layer DL1 may include a high-k material with a higher dielectric constant than that of a silicon nitride. The specific material of the dielectric layer DL1 may vary.

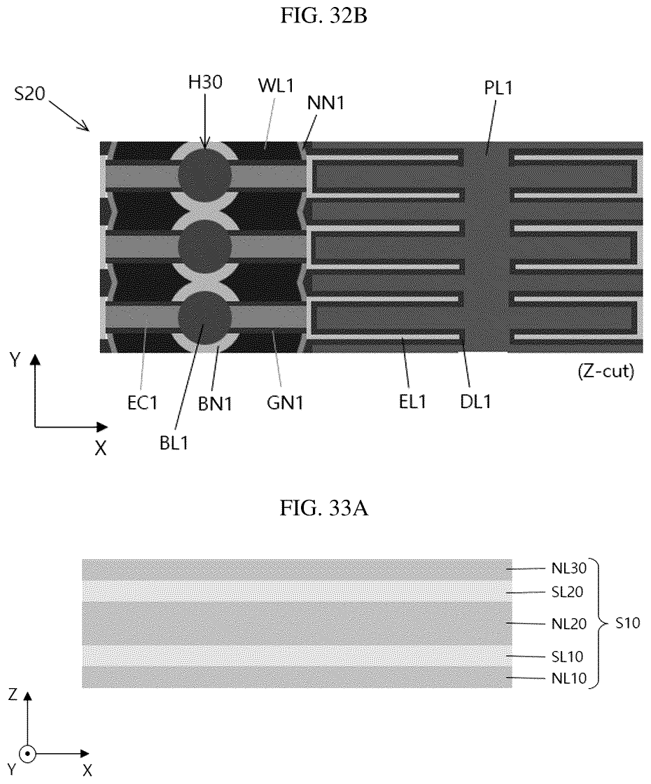

Referring to FIG. 32A and FIG. 32B, a plate electrode PL1 may be formed on the dielectric layer DL1 in the capacitor formation region. The plate electrode PL1 may be an electrode layer (second electrode layer) for a capacitor. The plate electrode PL1 may be formed to fill the fourth etched portion (T40 in FIG. 29A), the inside of the electrode member EL1, and the space between the electrode member EL1. The plate electrode PL1 may be formed to include one or more of various electrode materials used in semiconductor device processing. The plate electrode PL1 may have a type of line shape. Therefore, the plate electrode PL1 may be said to be a plate electrode line. The electrode member EL1, the dielectric layer DL1, and the plate electrode PL1 may form a capacitor.

FIG. 28A to FIG. 32B illustrate and describe the method for forming the capacitor as an example, but in some cases, the method for forming the capacitor and the specific structure of the capacitor may vary.

In the device structure of FIG. 32A, the lower epitaxial channel material layer EC1, the word line WL1 surrounding it, and the gate insulating material layer GN1 between them may constitute a first transistor TR1. In addition, the lower electrode member EL1 electrically connected to the first transistor TR1 on the lateral side of the first transistor TR1, and the dielectric layer DL1 in contact with the lower electrode member EL1 and the plate electrode PL1 may constitute a first capacitor CP1. Furthermore, the first transistor TR1 and the first capacitor CP1 may constitute one memory cell (a lower memory cell). The first transistor TR1 and the first capacitor CP1 may be arranged in a horizontal direction.

In addition, the upper epitaxial channel material layer EC1, the word line WL1 surrounding it, and the gate insulating material layer GN1 between them may constitute a second transistor TR2. In addition, the upper electrode member EL1 electrically connected to the second transistor TR2 on the lateral side of the second transistor TR2 and the dielectric layer DL1 in contact with the upper electrode member EL1 and the plate electrode PL1 may constitute a second capacitor CP2. Furthermore, the second transistor TR2 and the second capacitor CP2 may constitute one memory cell (an upper memory cell). The second transistor TR2 and the second capacitor CP2 may be arranged in a horizontal direction. The second transistor TR2 may be disposed on the first transistor TR1, and the second capacitor CP2 may be disposed on the first capacitor CP1.

Although not shown, the device structures such as those of FIG. 32A and FIG. 32B may be repeatedly arranged in the Z-axis direction, may be repeatedly arranged in the X-axis direction, and may be repeatedly arranged in the Y-axis direction. According to the embodiments of the present invention, it is possible to implement a memory device which may remarkably improve integration degree and have excellent performance and operation characteristics. The memory device may be a gate-all-around (GAA) type stacked memory device having a horizontal arrangement and a stacked structure. Furthermore, the memory device according to an embodiment of the present invention may be a vertical DRAM device or a three-dimensional DRAM device.

Hereinafter, a memory device according to an embodiment of the present invention will be additionally described with reference to FIG. 32A and FIG. 32B.

Referring to FIG. 32A and FIG. 32B, a memory device according to an embodiment of the present invention may include a plurality of memory cells stacked in a vertical direction. Each of the plurality of memory cells may include a transistor and a capacitor electrically connected to the transistor in a lateral direction. The transistor may correspond to TR1 and TR2, and the capacitor may correspond to CP1 and CP2. The transistor may include an epitaxial channel material layer EC1, a word line WL1 surrounding the epitaxial channel material layer EC1, and a gate insulating layer GN1 disposed between them. The capacitor may include an electrode member EL1 electrically connected to the transistor, a dielectric layer DL1 disposed on a surface of the electrode member EL1, and a plate electrode PL1 disposed on a surface of the dielectric layer DL1.

Furthermore, the memory device may include a bit line BL1 connected to a plurality of transistors of the plurality of memory cells. The bit line BL1 may extend in the vertical direction. A body insulating layer BN1 surrounding at least a portion of an outer surface of the bit line BL1 may be disposed between the bit line BL1 and the word line WL1. A gap filling insulating layer NG1 which is a separate material layer from the body insulating layer BN1 may be disposed between two adjacent word lines WL1 of the plurality of transistors.

The epitaxial channel material layer EC1 may include a single crystal semiconductor. For example, the epitaxial channel material layer EC1 may include any one selected from a single crystal Si, a single crystal Ge, and a single crystal SiGe. The transistor may have excellent performance by including the epitaxial channel material layer EC1.

When observed from above, the body insulating layer BN1 may have a structure in which a plurality of annular-shaped units are connected in a row (see FIG. 32B, etc.). The bit line BL1 may be disposed inside each of the plurality of ring-shaped units. Each of the plurality of annular-shaped units may have a ring-shaped cross-sectional structure. For example, each of the plurality of annular-shaped units may have a cross-sectional structure of a circular ring shape or an approximately circular ring shape. Furthermore, the body insulating layer BN1 may have a shape extending in the same direction as the word line WL1 when observed from above. Within the body insulating layer BN1, a plurality of bit lines BL1 may be arranged to be spaced apart from each other in the horizontal direction, that is, the horizontal direction in which the word line WL1 extends.

In an embodiment of the present invention, the transistor may have a gate-all-around (GAA) structure. In this regard, the transistor and the memory device including it may have excellent characteristics.

In addition, the memory device may further include an insertion insulating layer NN1 extending to cover a side surface of the word line WL1 while surrounding a portion (end portion) of the gate insulating layer GN1 adjacent to the electrode member EL1. The insertion insulating layer NN1 may be a separate material layer from the body insulating layer BN1 and the gap filling insulating layer NG1. The insertion insulating layer NN1 may be, for example, an atomic layer deposition (ALD) material layer.

According to one embodiment, the body insulating layer BN1 may be in contact with a first side surface (first end) of the gap filling insulating layer NG1, and the insertion insulating layer NN1 may be in contact with a second side surface (second end) of the gap filling insulating layer NG1. A portion of the insertion insulating layer NN1 may be in contact with the electrode member EL1.

Furthermore, according to one embodiment, the side surface of the insertion insulating layer NN1 may contact the side surface of the dielectric layer DL1. The word line WL1 may contact a first side surface of the insertion insulating layer NN1, and the dielectric layer DL1 may contact a second side surface of the insertion insulating layer NN1. However, it is not limited to this structure and may be modified.

A memory device according to an embodiment of the present invention may have structural features as shown in FIG. 32A and FIG. 32B. For example, the memory device has a stacked structure and includes the epitaxial channel material layer EC1, and may have features in the structures of the body insulating layer BN1, the gap filling insulating layer NG1, the insertion insulating layer NN1 and their peripheral portions, and the transistor and the capacitor.

According to the embodiments of the present invention described above, it is possible to implement a memory device (stack-type memory device) and a manufacturing method which may increase the degree of integration and secure excellent performance, while also facilitating casy processing and reducing manufacturing costs. In addition, according to embodiments of the present invention, it is possible to implement a memory device (stack-type memory device) and a manufacturing method thereof which may improve performance such as mobility by using a single crystal channel material, may improve channel thickness uniformity, and may improve on-current characteristics. In particular, according to one embodiment of the present invention, an epitaxial channel layer is formed by using a stack of an insulating layer and a sacrificial layer and according to a selective epitaxial growth (SEG) method. Thus, when compared to the existing method using a Si/SiGe stacked structure, it is possible to implement a memory device in which the process difficulties may be reduced, a manufacturing cost may be reduced, and performances are improved. Since the embodiment of the present invention uses a selective epitaxial process for a single material, the process may be remarkably facilitated when compared to the existing method of repeatedly performing the epitaxial process for multiple materials (e.g., Si and SiGe).

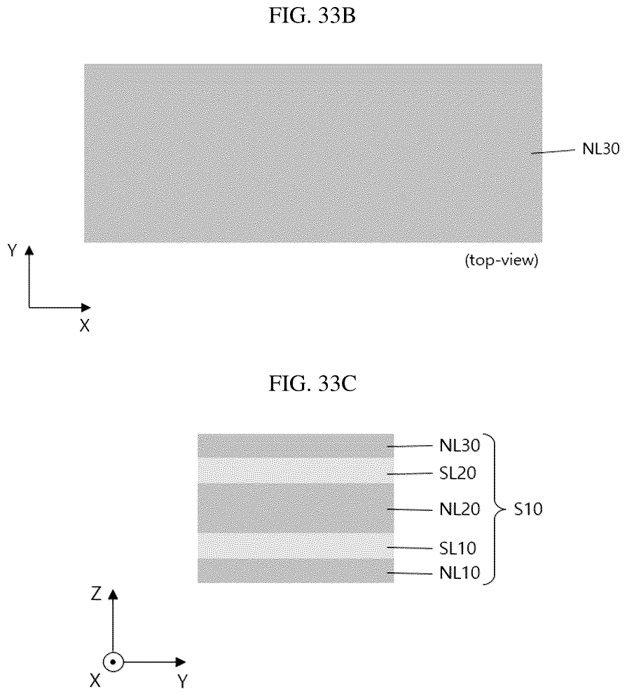

FIG. 33A to FIG. 63B are diagrams for explaining an example of a manufacturing method of a memory device (stack-type memory device) according to an embodiment of the present invention.

The same reference numbers in FIG. 33A to FIG. 63B (e.g., FIG. 33 in FIG. 33A, FIG. 33B, and FIG. 33C) represent the same steps. FIGS. 33A, 34A, 35A, 36A, 37A, 38A, 39A, 40A, 41A, 42A, 43A, 44A, 45A, 46A, 47A, 48A, 49A, 50A, 51A, 52A, 53A, 54A, 55A, 56A, 57A, 58A, 59A, 60A, 61A, 62A, and 63A are cross-sectional diagrams cut along the XZ plane. FIGS. 33B, 34B, 35B, 36B, 37B, 38B, 39B, 40B, 41B, 42B, 43B, 44B, 45B, 46B, 47B, 48B, 49B, 50B, 51B, 52B, 53B, 54B, 55B, 56B, 57B, 58B, 59B, 60B, 61B, 62B, and 63B are top diagrams (i.e. It is either a top-view) or cross-sectional diagrams cut in the X-Y plane (i.e., Z-cut view). FIGS. 33C, 34C, 35C, 36C, 37C, 38C, 39C, 40C, 41C, 42C, 43C, and 44C are cross-sectional diagrams cut along the Y-Z plane.

Referring to FIG. 33A to FIG. 33C, a stack S10 may be formed on a predetermined substrate (not shown). The material of the substrate may be selected from a variety of materials. The substrate may include a semiconductor material. The substrate may include a semiconductor wafer. The substrate may include a bulk silicon substrate, a silicon-on-insulator (SOI) substrate, a germanium substrate, or a germanium-on-insulator (GOI), a silicon-germanium substrate, or a substrate formed through an epitaxial growth process. The substrate may include a single crystal semiconductor material. For example, the substrate may include any one selected from a single crystal silicon (Si), a single crystal germanium (Ge), and a single crystal silicon-germanium (SiGe).

The stack S10 may be formed on the substrate. The stack S10 may include a first insulating layer NL10, and a first sacrificial layer SL10 and a second insulating layer NL20 which are sequentially stacked on the first insulating layer NL10. As a non-limiting example, the first insulating layer NL10 and the second insulating layer NL20 may include a silicon nitride (e.g., SiNₓ) or may be formed of silicon nitride (e.g., SiNₓ). As a non-limiting example, the first sacrificial layer SL10 may include a silicon oxide (e.g., SiO₂) or may be formed of a silicon oxide (e.g., SiO₂). The first insulating layer NL10 and the first sacrificial layer SL10 may have an etching selectivity, and similarly, the second insulating layer NL20 and the first sacrificial layer SL10 may have an etching selectivity. The first insulating layer NL10, the first sacrificial layer SL10, and the second insulating layer NL20 may be formed through a deposition process.

Furthermore, according to one embodiment, the stack S10 may further include a second sacrificial layer SL20 and a third insulating layer NL30 sequentially stacked on the second insulating layer NL20. In this case, the stack S10 may have a vertically symmetrical structure with respect to the second insulating layer NL20. The second sacrificial layer SL20 may be formed of the same material as the first sacrificial layer SL10, and the third insulating layer NL30 may be formed of the same material as the first insulating layer NL10 and/or the second insulating layer NL20. The second sacrificial layer SL20 and the third insulating layer NL30 may be formed through a deposition process.

The second insulating layer NL20 may have a thickness larger than that of each of the first insulating layer NL10, the third insulating layer NL30, the first sacrificial layer SL10, and the second sacrificial layer SL20. For example, the second insulating layer NL20 may have a thickness which is about 1.5 times to about 2.5 times larger than a thickness of each of the first insulating layer NL10, the third insulating layer NL30, the first sacrificial layer SL10, and the second sacrificial layer SL20. It is possible to secure a gap between upper and lower cells to be formed later by forming the second insulating layer NL20 relatively thick. The first insulating layer NL10 and the third insulating layer NL30 may have the same thickness or substantially the same thickness. The first sacrificial layer SL10 and the second sacrificial layer SL20 may have the same thickness or substantially the same thickness. The first insulating layer NL10, the third insulating layer NL30, the first sacrificial layer SL10, and the second sacrificial layer SL20 may have the same thickness or substantially the same thickness.

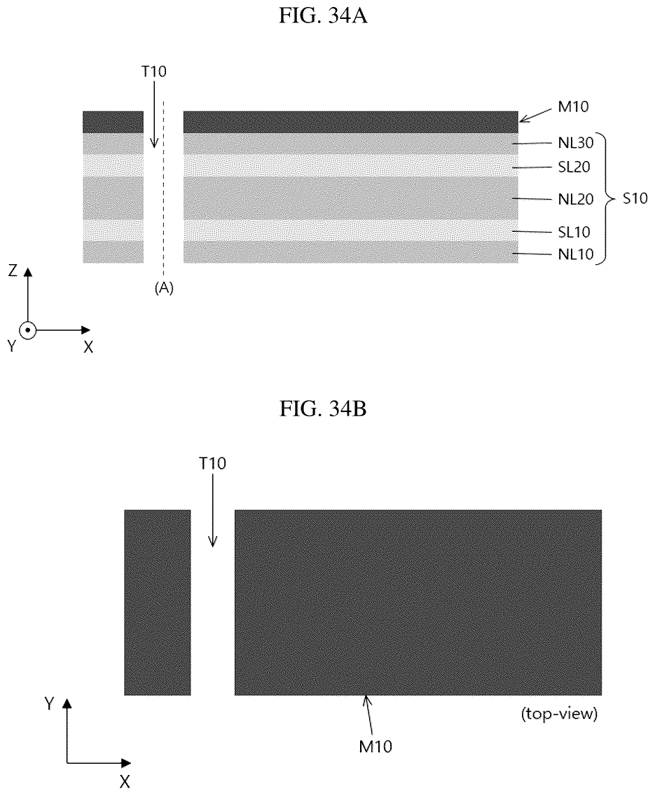

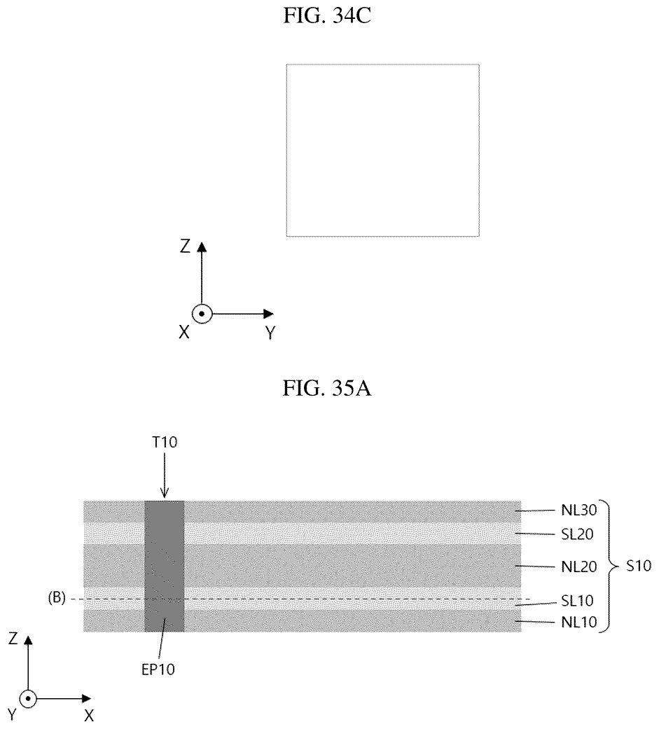

Referring to FIG. 34A to FIG. 34C, a first etched portion T10 penetrating through a region including at least one bit line formation planned region may be formed in the stack S10. The first etched portion T10 may be formed to penetrate through the at least one-bit line formation planned region and a region adjacent thereto. The first etched portion T10 may be formed to commonly penetrate through a plurality of the bit line formation planned regions. The first etched portion T10 may have a trench shape which commonly penetrates through the plurality of bit line formation planned regions. Accordingly, the first etched portion T10 may be referred to as a first trench. The first etched portion T10 may be formed to penetrate from the third insulating layer NL30 to the first insulating layer NL10 and, for example, may have a shape extending in the Y-axis direction. The first etched portion T10 may have a line pattern shape. The first etching portion T10 may be formed in a region where a transistor is to be formed, that is, a transistor formation region (transistor formation planned region). Here, FIG. 34C may be a cross-sectional view taken along line (A) of FIG. 34A.

A first mask pattern M10 may be used to form the first etched portion T10. The first mask pattern M10 may have a predetermined opening region. The first mask pattern M10 may be, for example, a photoresist pattern. After forming the first etched portion T10, the first mask pattern M10 may be removed.

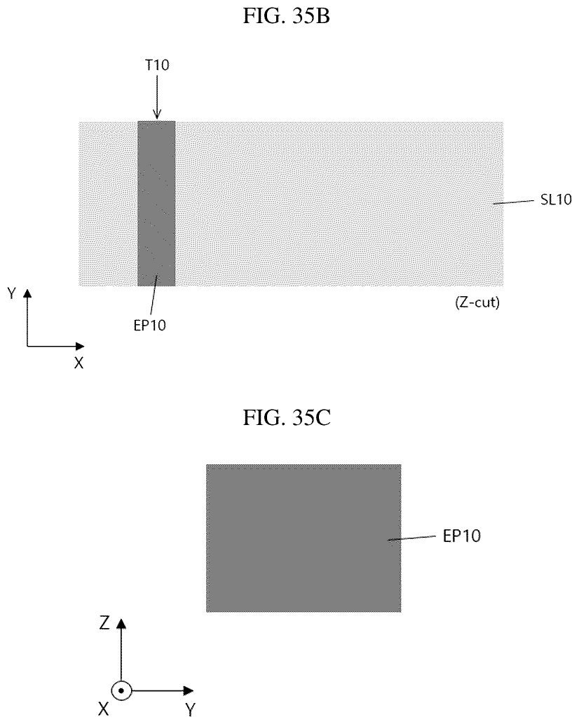

Referring to FIG. 35A to FIG. 35C, an epitaxial material plug EP10 filling the first etched portion T10 may be formed from the substrate (not shown) by using an epitaxial growth method. The epitaxial material plug EP10 filling the first etch section T10 may be formed from an upper surface of the substrate exposed by the first etch section T10 by using an epitaxial growth process. Therefore, the epitaxial growth method may be referred to as a selective epitaxial growth (SEG) method. Here, FIG. 35B may be a cross-sectional diagram taken along line (B) of FIG. 35A.

The epitaxial material plug EP10 may include a single crystal semiconductor. For example, the epitaxial material plug EP10 may include single crystal Si. The epitaxial material plug EP10 may be composed of single crystal Si. However, the material of the epitaxial material plug EP10 is not limited to single crystal Si. In some cases, the epitaxial material plug EP10 may include other material such as single-crystal Ge or single-crystal SiGe, or may be composed of the other material. For example, the epitaxial material plug EP10 may have a vertical plate shape extending in the Y-axis direction.

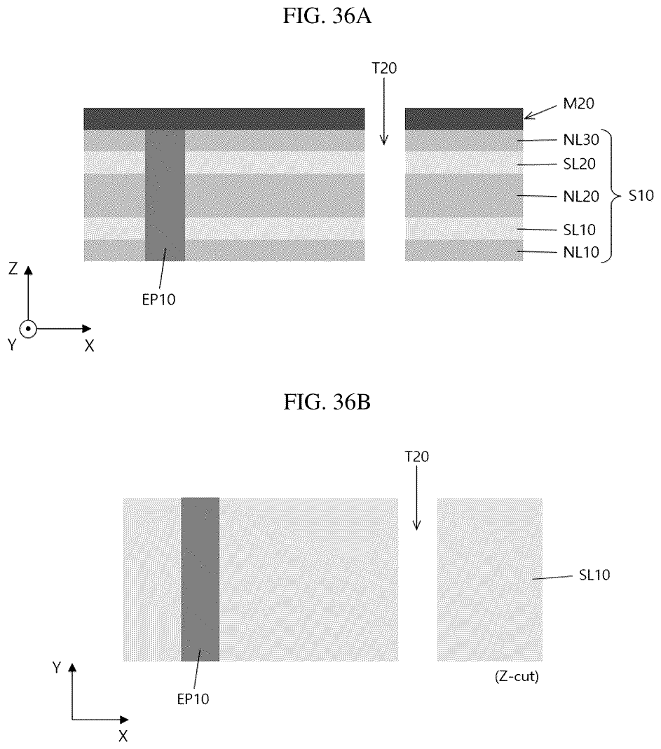

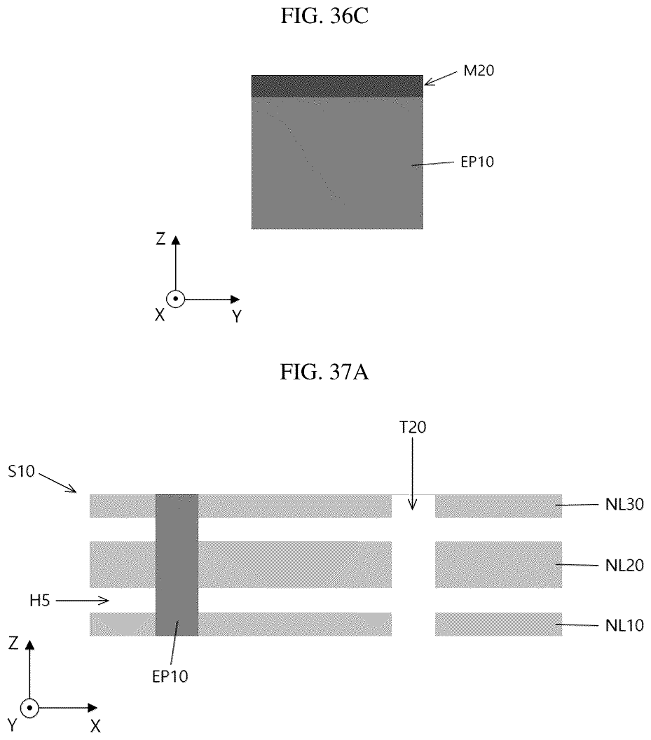

Referring to FIG. 36A to FIG. 36C, a second etched portion T20 spaced apart from the epitaxial material plug EP10 may be formed in the stack S10. The second etched portion T20 may be formed in a capacitor formation region (capacitor formation planned region) adjacent to the transistor formation region in the stack S10. The second etched portion T20 may have a trench shape. Accordingly, the second etched portion T20 may be referred to as a second trench. The second etched portion T20 may be formed to penetrate from the third insulating layer NL30 to the first insulating layer NL10 and, for example, may have a shape extending in the Y-axis direction. The second etched portion T20 may have a line pattern shape.

A second mask pattern M20 may be used to form the second etched portion T20. The second mask pattern M20 may have a predetermined opening region. The second mask pattern M20 may be, for example, a photoresist pattern. After forming the second etched portion T20, the second mask pattern M20 may be removed.

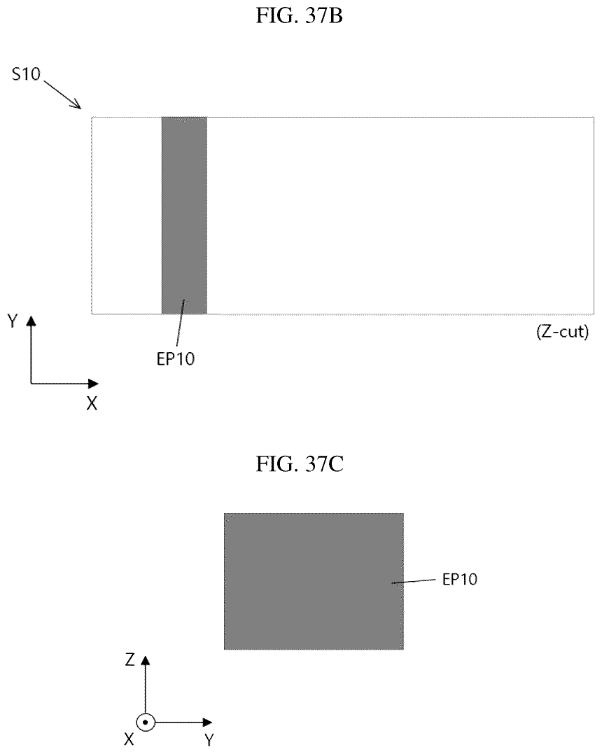

Referring to FIG. 37A to FIG. 37C, a horizontal space H5 may be formed by removing the first sacrificial layer (SL10 in FIG. 36A) and the second sacrificial layer (SL20 in FIG. 36A) exposed by the second etched portion T20. The horizontal space H5 may extend parallel to the XY plane. The first sacrificial layer (SL10 in FIG. 36A) and the second sacrificial layer (SL20 in FIG. 36A) may be selectively removed by using a wet etching process using a wet etchant having etching selectivity for the first sacrificial layer (SL10 in FIG. 36A) and the second sacrificial layer (SL20 in FIG. 36A). The horizontal space H5 formed by removal of the first sacrificial layer (SL10 in FIG. 36A) may be referred to as a first horizontal space, and the horizontal space H5 formed by removal of the second sacrificial layer (SL20 in FIG. 36A) may be referred to as a second horizontal space.

According to one embodiment, in the step for forming the horizontal space H5, the entire first sacrificial layer (SL10 in FIG. 36A) may be removed. Furthermore, in the step for forming the horizontal space H5, the entire second sacrificial layer (SL20 in FIG. 36A) may be removed. Accordingly, the horizontal space H5 may be formed to extend not only to the region where a transistor is to be formed (i.e., the transistor formation region) but also to the region where a capacitor is to be formed (i.e., the capacitor formation region). In this step, when the entire first sacrificial layer (SL10 in FIG. 36A) and the entire second sacrificial layer (SL20 in FIG. 36A) are removed, an effect that the process may be simplified may be obtained.

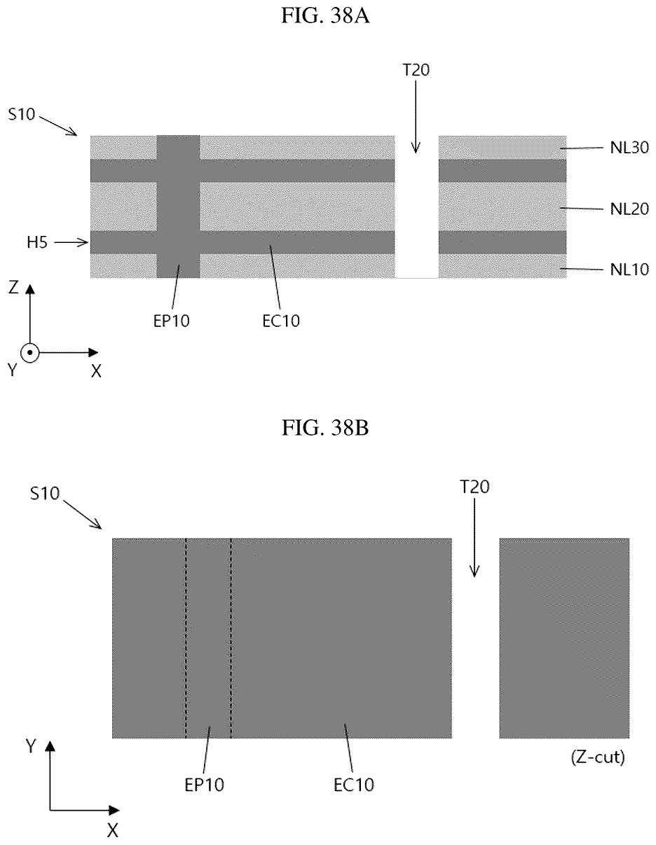

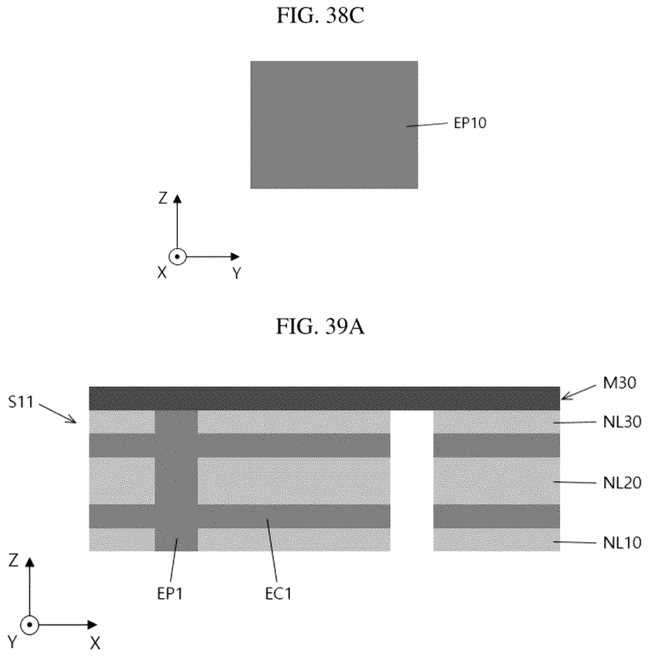

Referring to FIG. 38A to FIG. 38C, an epitaxial channel material layer EC10 filling the horizontal space H5 may be formed from the side surface of the epitaxial material plug EP10 by using an epitaxial growth method. The epitaxial channel material layer EC10 filling the horizontal space H5 may be formed from the side surface of the epitaxial material plug EP10 exposed by the horizontal space H5 by using an epitaxial growth process. Therefore, the epitaxial growth method may be referred to as a selective epitaxial growth (SEG) method. The epitaxial channel material layer EC10 may have a plate (horizontal plate) shape parallel to the XY plane.

The epitaxial channel material layer (EC10) may include a single crystal semiconductor. For example, the epitaxial channel material layer EC10 may include single crystal Si. The epitaxial channel material layer EC10 may be composed of single crystal Si. However, the material of the epitaxial channel material layer EC10 is not limited to single crystal Si. In some cases, the epitaxial channel material layer EC10 may include other material such as single-crystal Ge or single-crystal SiGe, or may be composed of the other material. Since the epitaxial channel material layer EC10 may be composed of a single crystal material, a transistor formed by applying the epitaxial channel material layer EC10 may have excellent performance such as high mobility. Furthermore, when forming the epitaxial channel material layer EC10 as in the embodiment of the present invention, the epitaxial channel material layers EC10 may have excellent thickness uniformity.

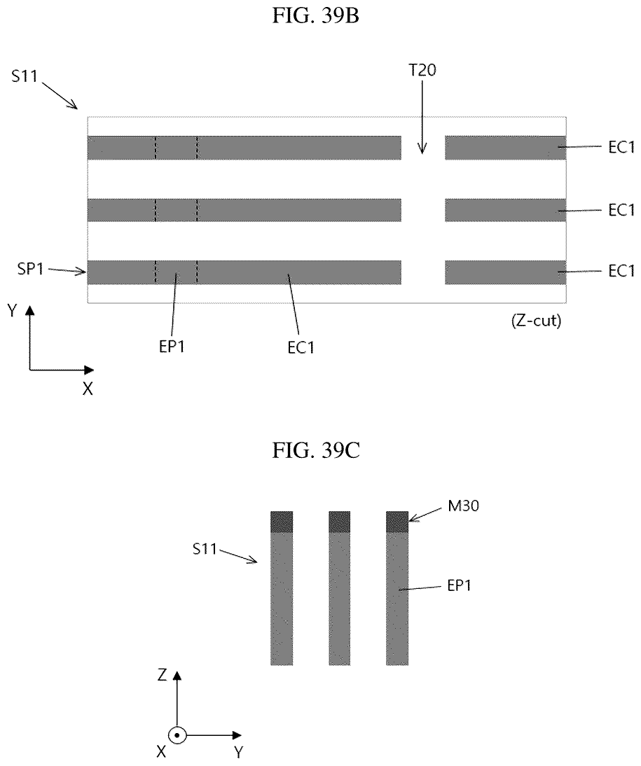

Referring to FIG. 39A to FIG. 39C, a patterned stack S11 having at least one pattern portion SP1 including an epitaxial channel pattern EC1 obtained from the epitaxial channel material layer (EC10 in FIG. 38A), and an epitaxial plug pattern EP1 obtained from the epitaxial material plug (EP10 in FIG. 38A) may be formed by patterning the stack (S10 in FIG. 38A) on which the epitaxial channel material layer (EC10 in FIG. 38A) is formed. The epitaxial channel pattern EC1 may be referred to as an ‘epitaxial channel pattern portion’, and the epitaxial plug pattern EP1 may be referred to as an ‘epitaxial plug pattern portion’.

The pattern portion SP1 may have a shape extending in a first direction, for example, X-axis direction and empty spaces may be provided on both sides of the pattern portion SP1 along a second direction perpendicular to the first direction, for example, the Y-axis direction. The plurality of pattern portions SP1 may be spaced apart in the Y-axis direction and arranged side by side in the X-axis direction. In each pattern part SP1, the epitaxial channel pattern EC1 and the epitaxial plug pattern EP1 may have the same width (a width in the Y-axis direction). The epitaxial channel pattern EC1 may have a line shape and may have a broken/cut (disconnected) shape by the second etched portion T20. At this stage, the epitaxial channel pattern EC1 including a channel region to be used as an actual channel later may be defined. Therefore, this step may be understood to be a cell patterning step.

For the patterning process of FIG. 39A to FIG. 39C, a third mask pattern M30 disposed on the stack (S10 in FIG. 38A) may be used. The third mask pattern M30 may have a predetermined pattern structure. The third mask pattern M30 may be, for example, a photoresist pattern. After the patterning process, the third mask pattern M30 may be removed.

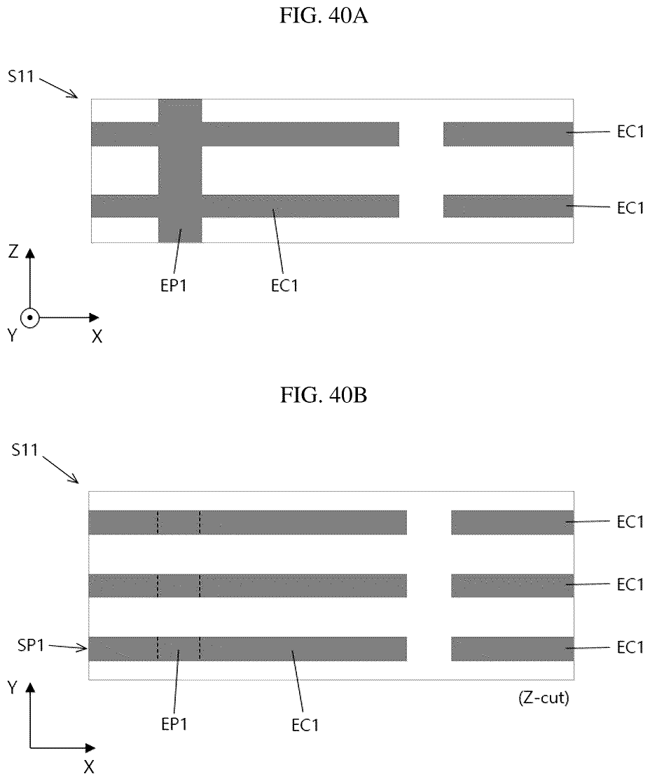

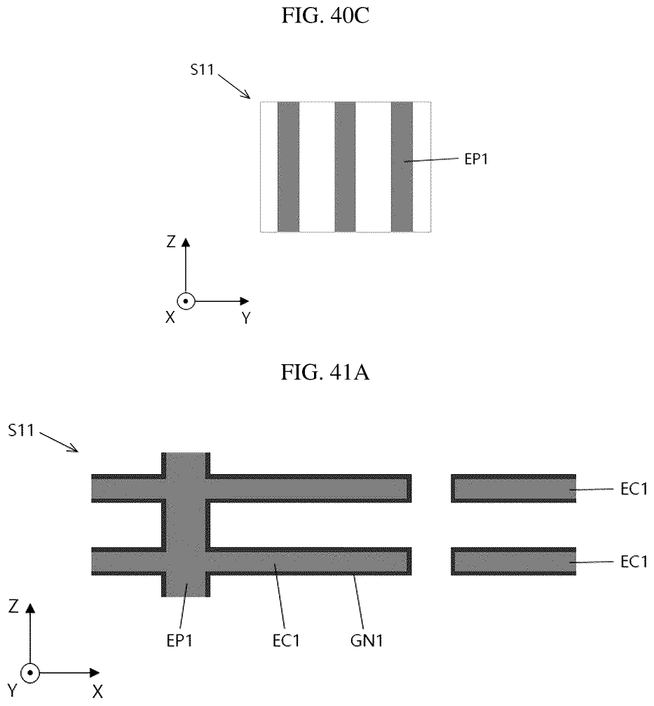

Referring to FIG. 40A to FIG. 40C, an empty region may be formed around the epitaxial plug pattern EP1 and the epitaxial channel pattern EC1 by removing the first to the third insulating layers (NL10, NL20, NL30 in FIG. 39A) from the patterned stack S11. Since the first to third insulating layers (NL10, NL20, and NL30 in FIG. 39A) may be made of the same material, they may be easily removed by using an etching method with etching selectivity.

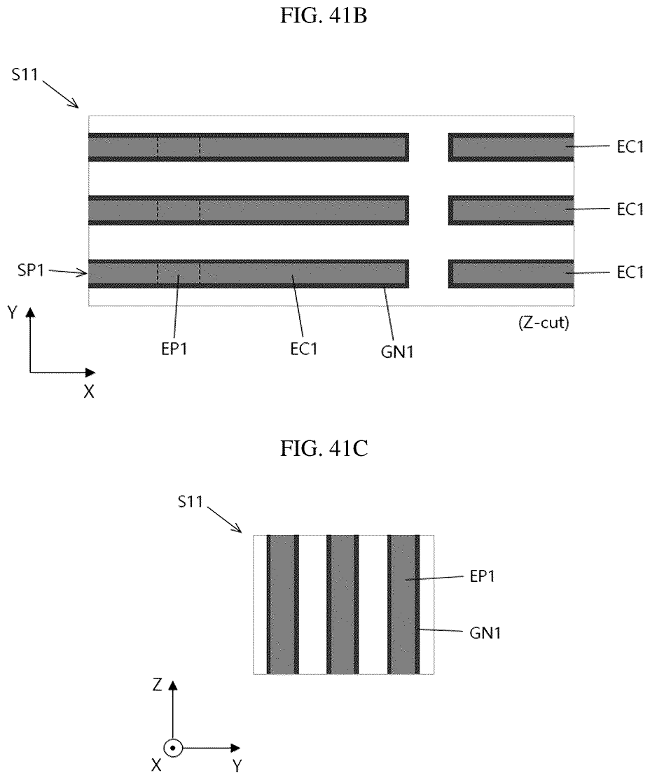

Referring to FIG. 41A to FIG. 41C, a gate insulating material layer GN1 may be formed on surface portions of the epitaxial plug pattern EP1 and the epitaxial channel pattern EC1. According to one embodiment, the gate insulating material layer GN1 may be formed by using a thermal oxidation process on the surface portions of the epitaxial plug pattern EP1 and the epitaxial channel pattern EC1. In this case, the gate insulating material layer GN1 may be an oxide layer. For example, the gate insulating material layer GN1 may be a silicon oxide layer.

However, the formation method and constituent material of the gate insulating material layer GN1 are not limited to the above and may vary in various ways. For example, the gate insulating material layer GN1 may be formed using an atomic layer deposition (ALD) process. In this case, the gate insulating material layer GN1 may be formed to include at least any one selected from silicon oxide, silicon nitride, silicon oxynitride, and a high-k material. Here, the high-k material may be a material with a higher dielectric constant than that of silicon nitride.

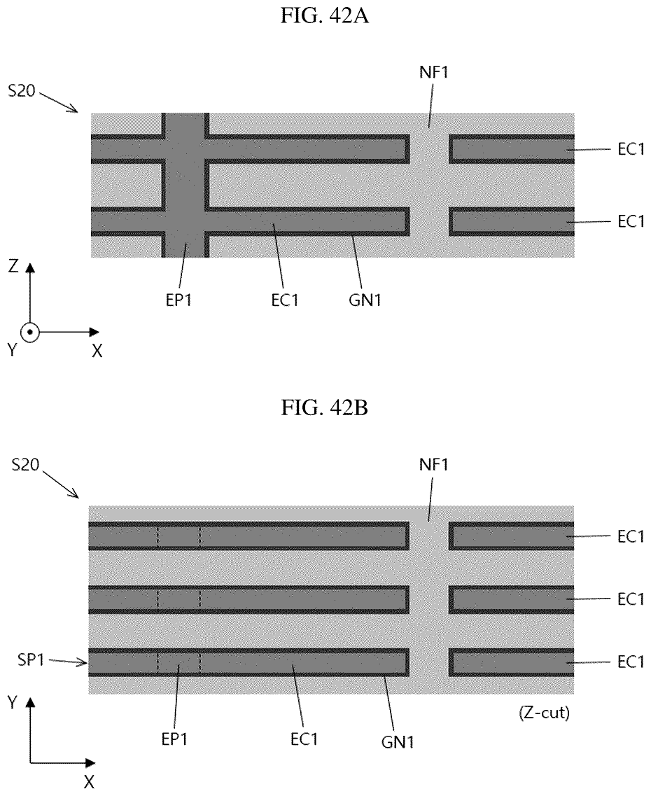

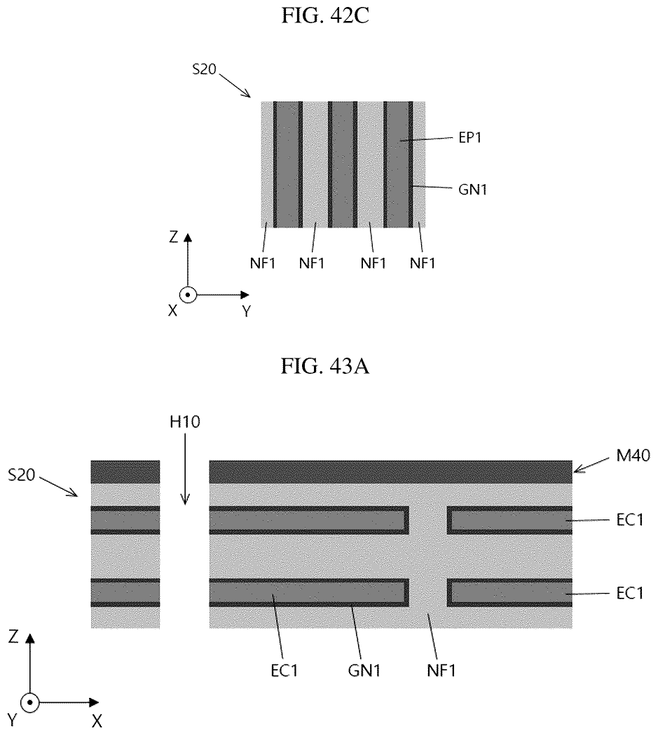

Referring to FIG. 42A to FIG. 42C, a structure S20 including the epitaxial plug pattern EP1, the epitaxial channel pattern EC1, the gate insulating material layer GN1, and a filling insulating layer NF1 may be formed by forming the filling insulating layer fills a space (i.e., the empty region) surrounding the epitaxial plug pattern EP1 and the epitaxial channel pattern EC1 on the gate insulating material layer GN1. As a non-limiting example, the filling insulating layer NF1 may include a silicon nitride (e.g., SiNx) or may be formed of silicon nitride (e.g., SiNx). The filling insulating layer NF1 may be formed of a material other than silicon nitride. When forming the filling insulating layer NF1, after depositing an insulator for the filling insulating layer NF1, a planarization process may be further performed on its upper surface and surrounding area.

In this step, the structure S20 may include the epitaxial plug pattern EP1 extending in the vertical direction on the substrate (not shown), and the epitaxial channel pattern EC1 extending in the horizontal direction from a side surface of the epitaxial plug pattern EP1, the gate insulating material layer GN1 formed on at least a surface portion of the epitaxial channel pattern EC1, and the filling insulating layer NF1 formed on the gate insulating material layer GN1 and filling the space surrounding the epitaxial plug pattern EP1 and the epitaxial channel pattern EC1. Here, the gate insulating material layer GN1 may be formed on the surface portions of the epitaxial plug pattern EP1 and the epitaxial channel pattern EC1. In the structure S20, the epitaxial plug pattern EP1 and the epitaxial channel pattern EC1 may have the same width.

The method of preparing the structure S20 as shown in FIG. 42A to FIG. 42C may vary in various ways. In other words, the process described with reference to FIG. 33A to FIG. 42C may be modified in various ways.

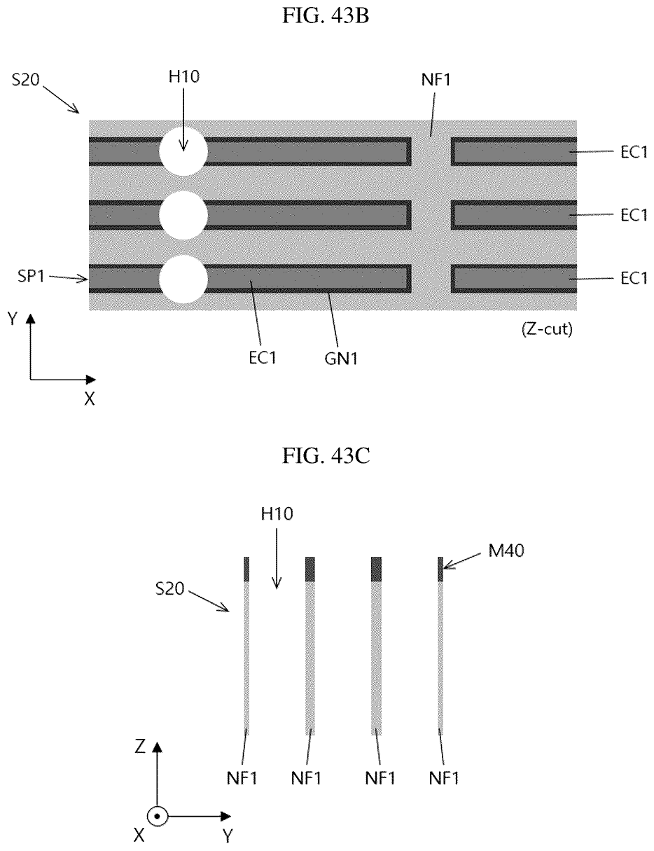

Referring to FIG. 43A to FIG. 43C, a first vertical hole H10 exposing the epitaxial channel pattern EC1 may be formed in a region of the structure S20 corresponding to the bit line formation planned region. In other words, the first vertical hole H10 exposing the epitaxial channel pattern EC1 may be formed by removing the epitaxial plug pattern EP1 by etching the bit line formation planned region in the structure S20. The first vertical hole H10 may be formed to penetrate the structure S20 in the vertical direction. The first vertical hole H10 may correspond to a region where a bit line will be formed later. The first vertical hole H10 may be formed in an area of the structure S20 where a transistor will be formed, that is, a transistor formation region (transistor formation planned region). A plurality of first vertical holes H10 may be formed to be spaced apart from each other in the Y-axis direction. For reference, the expression ‘corresponding’ in this specification may mean the same thing, but may be a concept which broadly encompasses substantially the same or similar things. This may be applied equally throughout this specification.

A fourth mask pattern M40 may be used to form the first vertical hole H10. The fourth mask pattern M40 may have a predetermined opening pattern. The fourth mask pattern M40 may be, for example, a photoresist pattern. After forming the first vertical hole H10, the fourth mask pattern M40 may be removed.

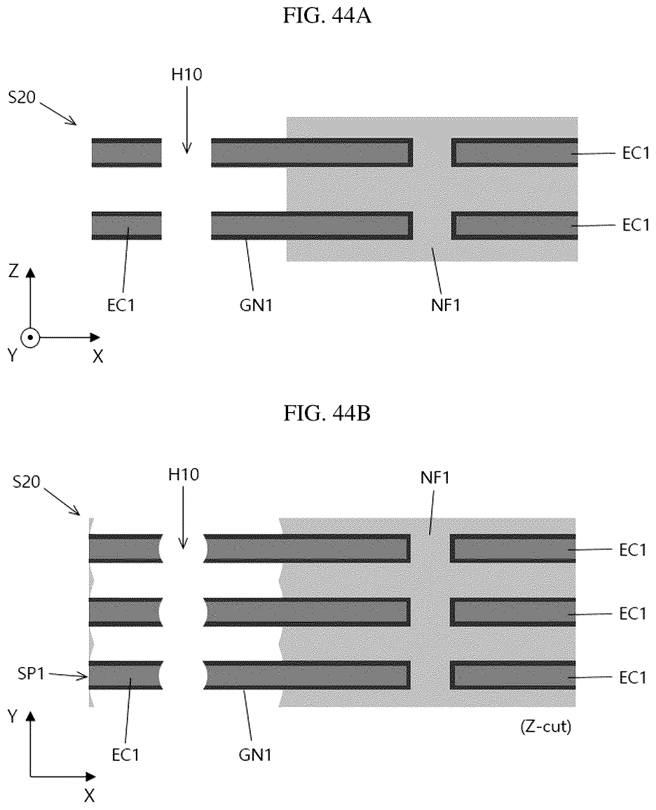

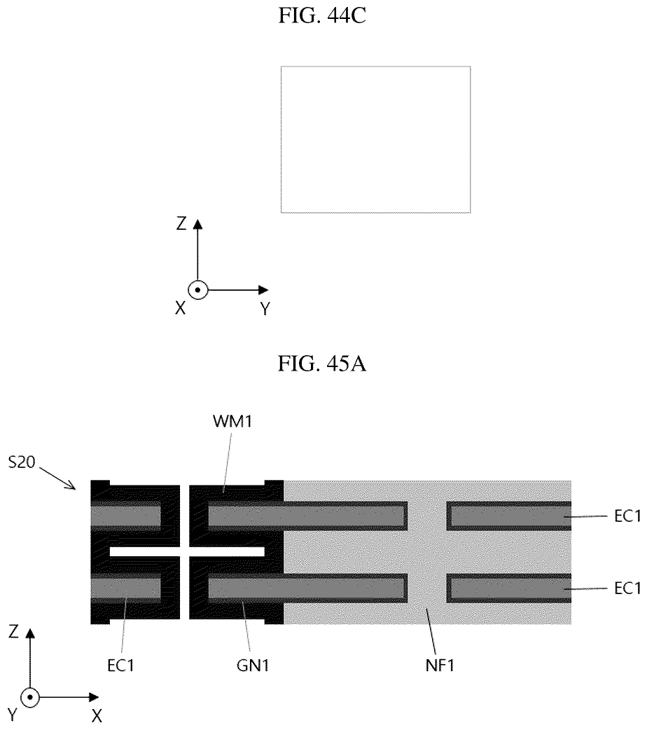

Referring to FIG. 44A to FIG. 44C, the gate insulating material layer GN1 may be exposed by removing the filling insulating layer NF1 from the transistor formation region (transistor formation planned region) around the first vertical hole H10 of the structure S20. At this time, a mask pattern (not shown) exposing the transistor formation region may be disposed on the structure S20, and the filling insulating layer NF1 may be etched and removed in the transistor formation region by using the mask pattern as an etch mask. Afterwards, the mask pattern may be removed. Here, the mask pattern may be a remaining portion of the fourth mask pattern M40 of FIG. 43A or maybe a newly deposited hard mask pattern.

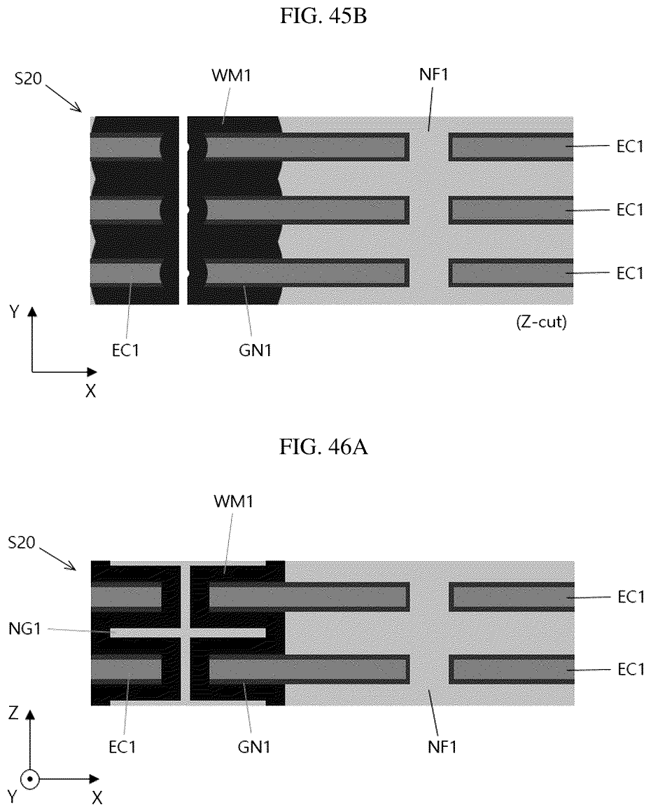

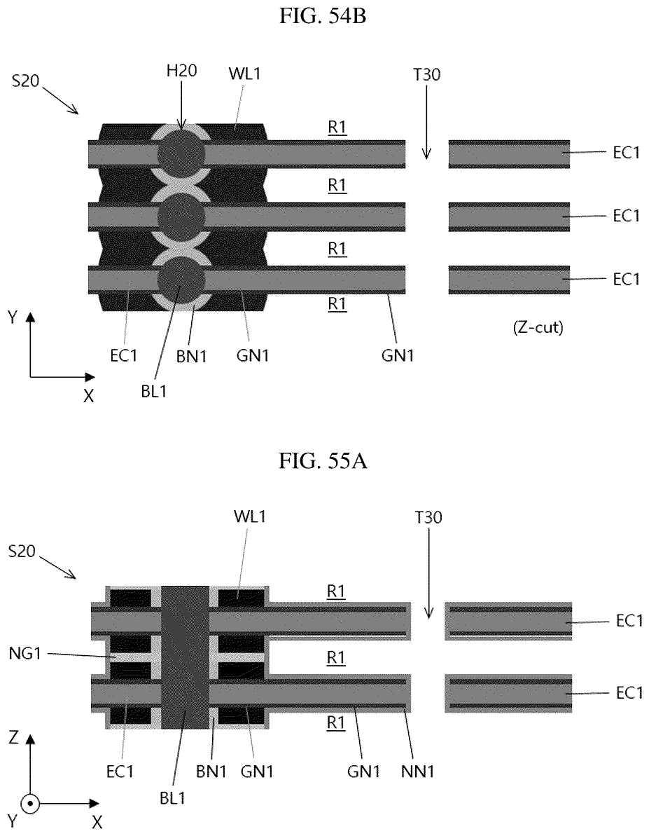

Then, a word line (WL1 in FIG. 54A) surrounding an exposed portion of the gate insulating material layer GN1 in the transistor formation region may be formed by using the method as illustrated in FIGS. 45A to 54B. Thus, a transistor including it may be defined.

Referring to FIG. 45A and FIG. 45B, a word line material layer WM1 surrounding the exposed portion of the gate insulating material layer GN1 may be formed in the transistor formation region. The word line material layer WM1 may be formed substantially conformally according to the shape of surface regions exposed in the transistor formation region. The word line material layer WM1 may be formed through, for example, an ALD process. At this time, as shown in FIG. 45A, the gap in the Z-axis direction between the lower and upper epitaxial channel patterns EC1 may be larger than approximately twice the thickness of the word line material layer WM1. Furthermore, the gap in the Z-axis direction between the lower and upper gate insulating material layers GN1 may be larger than about twice the thickness of the word line material layer WM1. Meanwhile, as shown in FIG. 45B, the gap in the Y-axis direction between two epitaxial channel patterns EC1 spaced apart in the Y-axis direction may be less than about twice the thickness of the word line material layer WM1. Furthermore, the gap in the Y-axis direction between the two gate insulating material layers GN1 spaced apart in the Y-axis direction may be less than about twice the thickness of the word line material layer WM1.

The word line material layer WM1 may be formed to surround each epitaxial channel pattern EC1 in the transistor formation region. Furthermore, the word line material layer WM1 may have a line shape extending in the Y-axis direction.

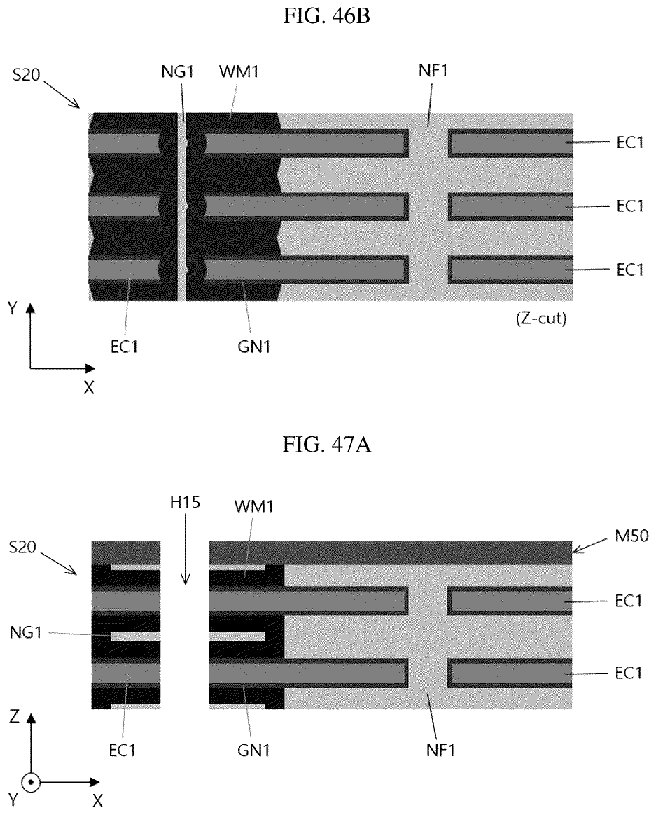

Referring to FIG. 46A and FIG. 46B, a gap filling insulating layer NG1 filling an empty space of the curved portion (bent portion) of the word line material layer WM1 may be formed. The gap filling insulating layer NG1 may be formed of an insulating oxide or another insulating material.

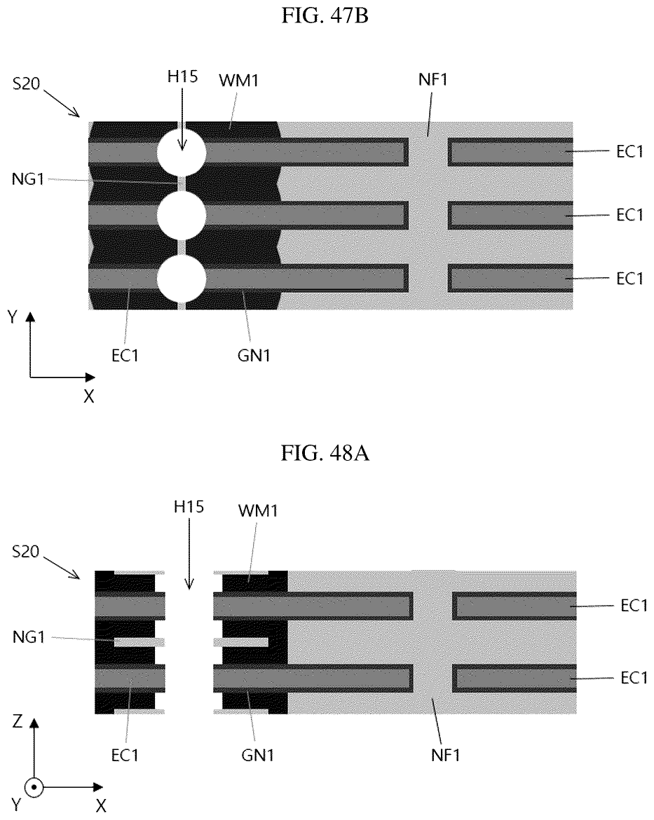

Referring to FIG. 47A and FIG. 47B, a through hole H15 may be formed by etching a region corresponding to the first vertical hole (H10 in FIG. 43A) in the word line material layer WM1. The through hole H15 may be a vertical hole. A fifth mask pattern M50 may be used to form the through hole H15. The fifth mask pattern M50 may have a predetermined opening pattern. The fifth mask pattern M50 may be, for example, a photoresist pattern. After forming the through hole H15, the fifth mask pattern M50 may be removed.

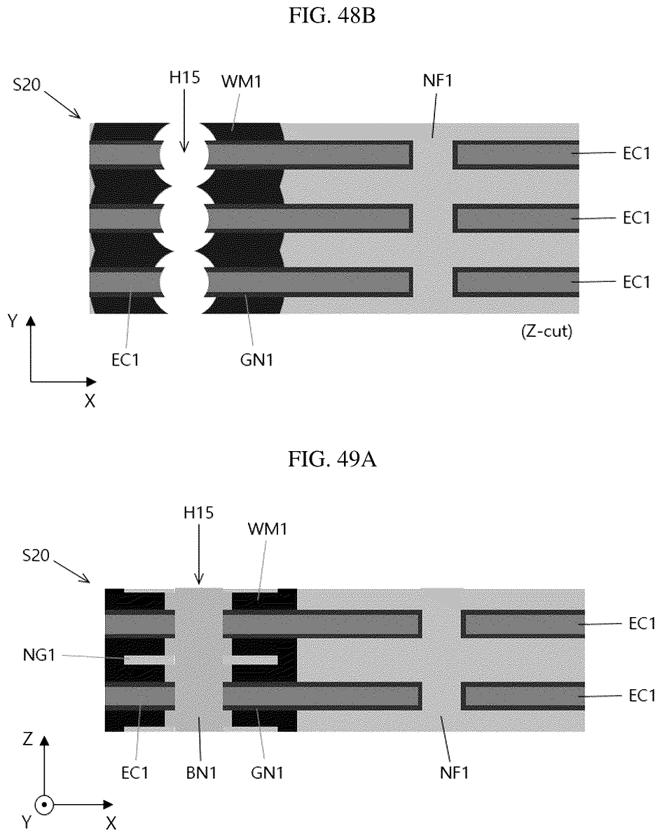

Referring to FIG. 48A and FIG. 48B, a portion of the word line material layer WM1 exposed through the through hole H15 may be recessed so that one end of the epitaxial channel pattern EC1 may protrude toward the through hole H15 rather than the word line material layer WM1. Accordingly, a portion of the word line material layer WM1 may be etched around the through hole H15, and the etched regions (recess regions) may be connected in the Y-axis direction.

Referring to FIG. 49A and FIG. 49B, a body insulating layer BN1 may be formed to fill the through hole H15 and the etched regions (recess regions) surrounding the through hole H15. The body insulating layer BN1 may be formed of an insulating oxide or another insulating material. The body insulating layer BN1 may be formed of the same material as the gap filling insulating layer NG1 or may be formed of a different material.

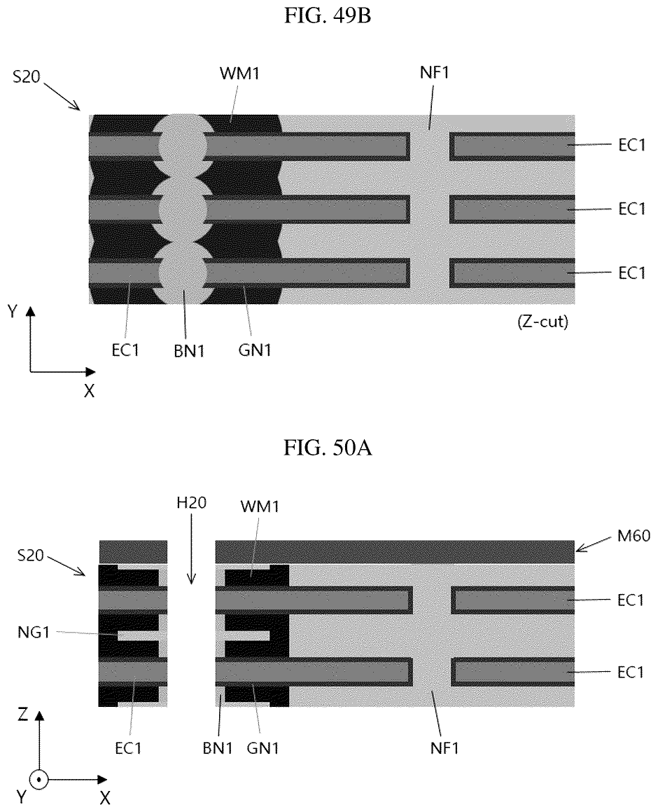

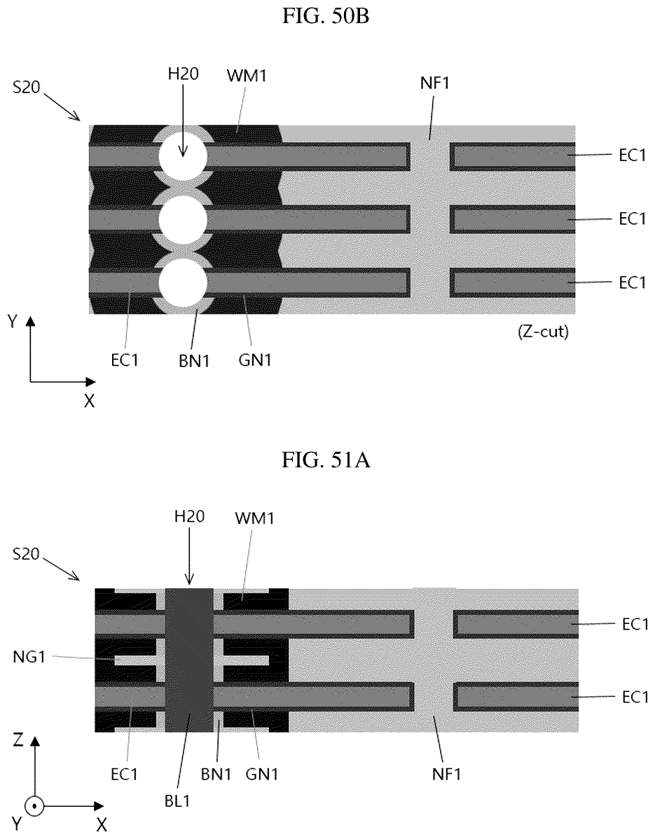

Referring to FIGS. 50A and 50B, a second vertical hole H20 may be formed in a region corresponding to the first vertical hole (H10 in FIG. 43A) of the body insulating layer BN1. A sixth mask pattern M60 may be used to form the second vertical hole H20. The sixth mask pattern M60 may have a predetermined opening pattern. The sixth mask pattern M60 may be, for example, a photoresist pattern. After forming the second vertical hole H20, the sixth mask pattern M60 may be removed.

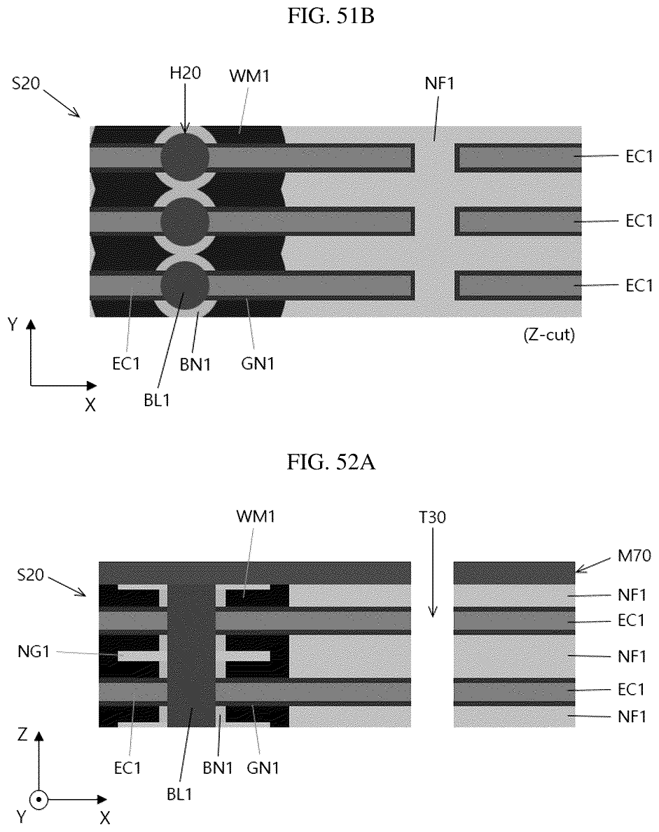

Referring to FIG. 51A and FIG. 51B, a bit line BL1 may be formed in the second vertical hole H20. The bit line BL1 may be connected (contacted) to one end of the epitaxial channel pattern EC1. Accordingly, the bit line BL1 may be formed to be connected to (contact) one end of the epitaxial channel pattern EC1 in a region corresponding to the first vertical hole (H10 in FIG. 43A) in the transistor formation region. The bit line BL1 may have a pillar shape penetrating through the structure S20 in the vertical direction. The bit line BL1 may be electrically connected to one end of the epitaxial channel pattern EC1 in a lateral direction. A plurality of bit lines BL1 connected to a plurality of epitaxial channel patterns EC1 may be formed.

Although not shown, if there is a conductive material of the bit line BL1 deposited above the second vertical hole H20, it may be removed through, for example, an etchback process.

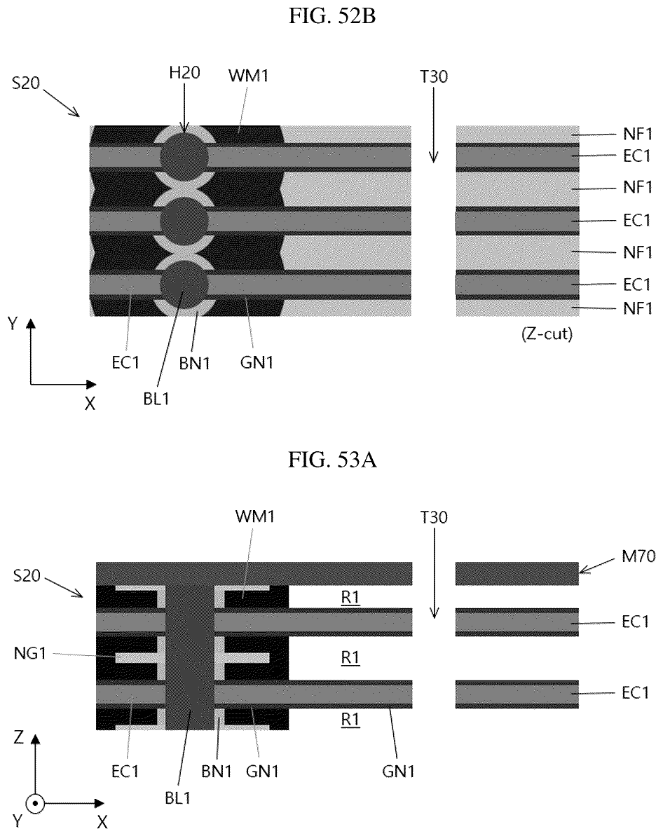

Referring to FIG. 52A and FIG. 52B, a third etched portion T30 spaced apart from the bit line BL1 may be formed in the capacitor formation region of the structure S20. The third etched portion T30 may have a trench shape. Accordingly, the third etched portion T30 may be referred to as a third trench. The third etched portion T30 may be formed to penetrate through the filling insulating layer NF1 and may have a shape extending in the Y-axis direction. The third etched portion T30 may have a line pattern shape. The third etched portion T30 may be formed in a region corresponding to the second etched portion (T20 in FIG. 36A).

According to one embodiment, the third etched portion T30 may be formed by etching a portion of the filling insulating layer NF1 and a portion of the gate insulating material layer GN1. An end of the gate insulating material layer GN1 and an end of the epitaxial channel pattern EC1 may be exposed toward the third etched portion T30.

A seventh mask pattern M70 may be used to form the third etched portion T30. The seventh mask pattern M70 may have a predetermined opening area. The seventh mask pattern M70 may be, for example, a photoresist pattern.

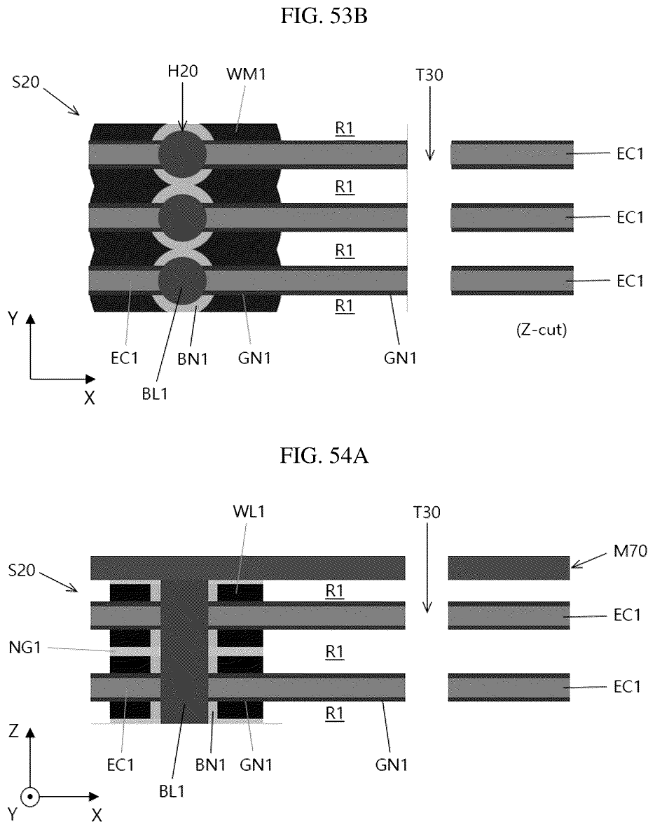

Referring to FIG. 53A and FIG. 53B, a first recess (first recess portion) R1 exposing the gate insulating material layer GN1 and the word line material layer WM1 may be formed by removing (etching) the filling insulating layer (NF1 in FIG. 52A) exposed by the third etched portion T30 in the capacitor formation region.

Referring to FIG. 54A and FIG. 54B, a portion of the material layer (WM1 in FIG. 53A) exposed by the first recess R1 may be recessed after forming the first recess R1 in the capacitor formation region. In other words, a portion of the word line material layer (WM1 in FIG. 53A) exposed toward the capacitor formation region may be recessed. As a result, the word line material layer portion surrounding the lower epitaxial channel pattern EC1 and the word line material layer portion surrounding the upper epitaxial channel pattern EC1 may be separated from each other. Here, the separated portions of the word line material layer may be referred to as the word line WL1. Afterwards, the seventh mask pattern M70 may be removed. However, the removal timing of the seventh mask pattern M70 may vary.

The word line WL1 may have a structure surrounding the gate insulating material layer GN1. Accordingly, the transistor including the word line WL1 may have a gate-all-around (GAA) structure. In this regard, the transistor may have excellent gate controllability and high on-current characteristics.

Although the method for forming the word line WL1 has been described in detail with reference to FIG. 45A to FIG. 54B, this is merely an example, and the method for forming the word line WL1 may vary depending on the case.

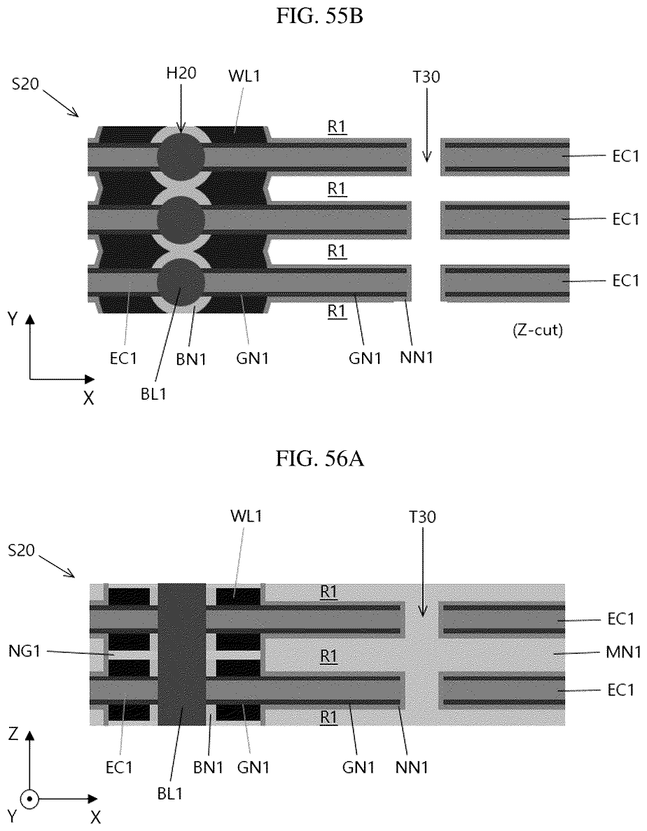

Referring to FIG. 55A and FIG. 55B, an insertion insulating layer NN1 surrounding an exposed portion of the gate insulating material layer GN1 may be formed in the capacitor formation region after forming the first recess R1 in the capacitor formation region. The insertion insulating layer NN1 may be conformally formed on the surface region exposed to the first recess R1. The insertion insulating layer NN1 may be formed to cover surfaces of the gate insulating material layer GN1, the epitaxial channel pattern EC1, and the word line WL1 exposed in the capacitor formation region. The insertion insulating layer NN1 may be formed through, for example, an ALD process. The thickness of the insertion insulating layer NN1 may be as thin as several tens of nm or less. The insertion insulating layer NN1 may be formed of an insulating oxide or another insulating material.

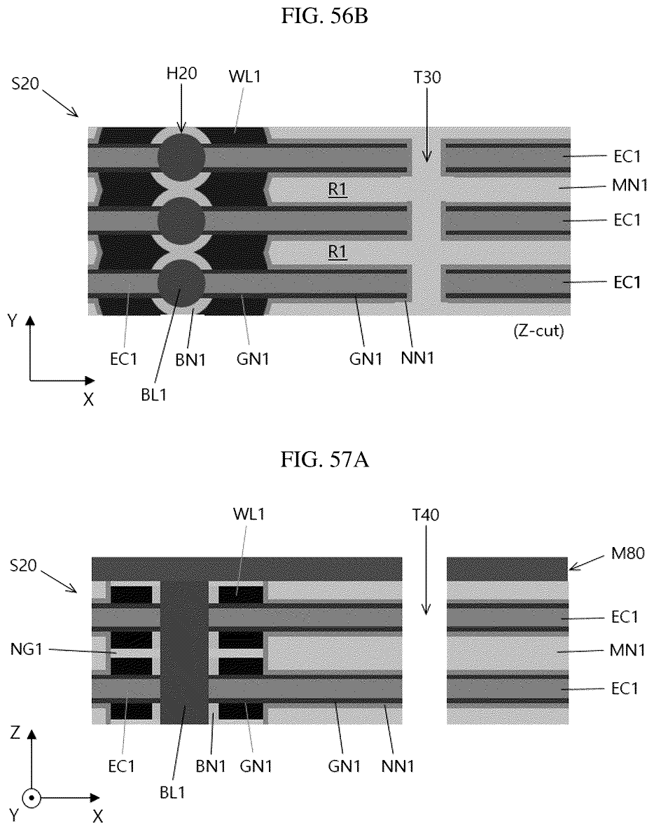

Referring to FIG. 56A and FIG. 56B, a mold insulating layer MN1 filling the first recess R1 may be formed. The mold insulating layer MN1 may be formed to fill the first recess R1 and the third etched portion T30 on the insertion insulating layer NN1. The mold insulating layer MN1 may include, for example, a silicon nitride (e.g., SiNₓ) or may be formed of a silicon nitride (e.g., SiNₓ). When forming the mold insulating layer MN1, after depositing an insulator for the mold insulating layer MN1, a planarization process may be further performed on its upper surface and surrounding area.

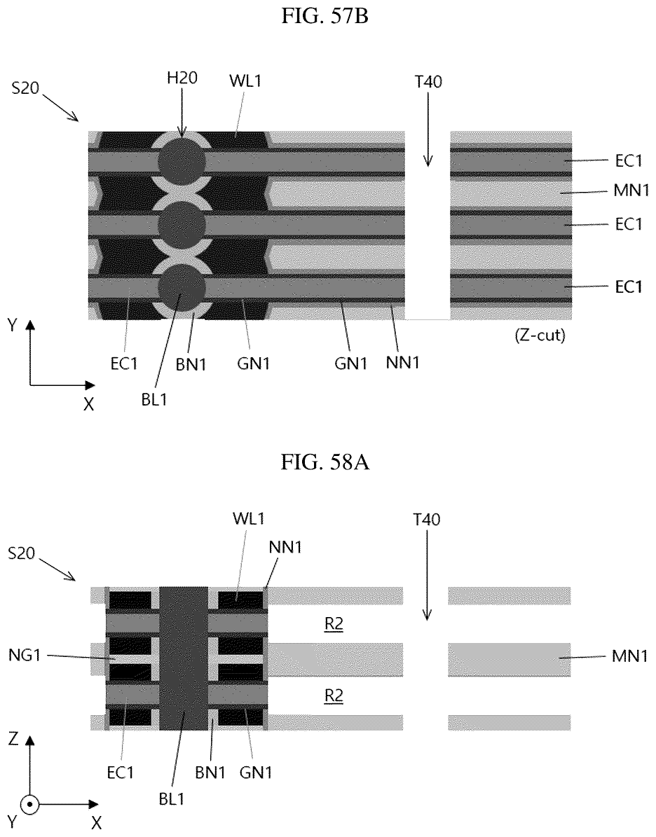

Referring to FIG. 57A and FIG. 57B, a fourth etched portion T40 may be formed in a region of the mold insulating layer MN1 corresponding to the third etched portion (T30 in FIG. 52A). The fourth etched portion T40 may be formed by etching a portion of the mold insulating layer MN1 and a portion of the insertion insulating layer NN1. Accordingly, the end of the gate insulating material layer GN1 and the end of the epitaxial channel pattern EC1 may be exposed toward the fourth etched portion T40. The fourth etched portion T40 may have a line shape extending in the Y-axis direction. The fourth etched portion T40 may be referred to as a fourth trench.

An eighth mask pattern M80 may be used to form the fourth etched portion T40. The eighth mask pattern M80 may have a predetermined opening area. The eighth mask pattern M80 may be, for example, a photoresist pattern. After forming the fourth etched portion T40, the eighth mask pattern M80 may be removed.

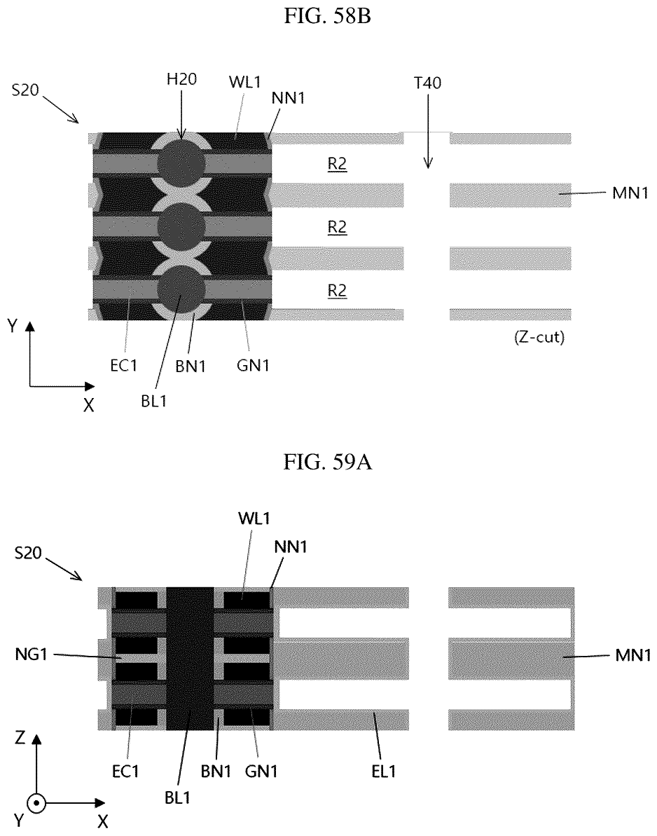

Referring to FIG. 58A and FIG. 58B, a second recess (second recess portion) R2 may be formed by etching the epitaxial channel pattern EC1, the gate insulating material layer GN1, and the insertion insulating layer NN1 exposed by the fourth etched portion T40. The epitaxial channel pattern EC1, the gate insulating material layer GN1, and the insertion insulating layer NN1 may be etched by injecting a predetermined wet etchant, that is, a wet etching solution through the fourth etched portion T40. At this time, one or more wet etchants may be used. The second recess R2 may be formed to a region somewhat spaced apart from the word line WL1. The etching range of the epitaxial channel pattern EC1, the gate insulating material layer GN1, and the insertion insulating layer NN1 may be controlled by adjusting the conditions of the etching process.

When the insertion insulating layer NN1 is removed in the step of FIG. 58A after forming the insertion insulating layer NN1 in the previous step of FIG. 55A, the second recess R2 may be formed to have a larger width than that of the remaining gate insulating material layer. Accordingly, a width of the second recess R2 in the Z-axis direction may be larger than a width of the remaining gate insulating material layer GN1 in the Z-axis direction. Furthermore, a width of the second recess R2 in the Y-axis direction may be larger than a width of the remaining gate insulating material layer GN1 in the Y-axis direction. As a result, the process margin for forming a capacitor in a subsequent process may be increased. In order to secure a process margin, and the like, it may be desirable to form the insertion insulating layer NN1. However, the formation of the above-described insertion insulating layer NN1 may be optional and may be omitted in some cases.

Meanwhile, in the step of FIG. 58A, since the epitaxial channel pattern EC1 may be removed by an etching process using a wet etching process in the capacitor formation region, this wet etching may not cause almost any etching damage to the epitaxial channel pattern EC1.

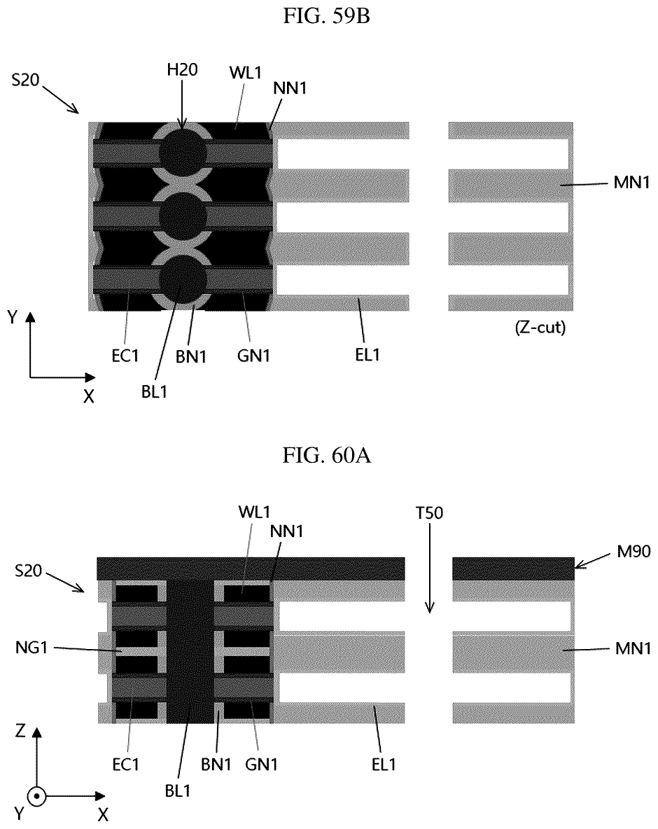

Referring to FIG. 59A and FIG. 59B, an electrode member EL1 connected to the other end of the epitaxial channel pattern EC1 may be formed on an inner surface of the second recess (R2 in FIG. 58A). The electrode member EL1 may be connected to the other end of the epitaxial channel pattern EC1 of the transistor. The electrode member EL1 may be an electrode layer (first electrode layer) for a capacitor. The electrode member EL1 may be conformally formed along the surface shape of the mold insulating layer MN1. The electrode member EL1 may be formed, for example, through an ALD process.

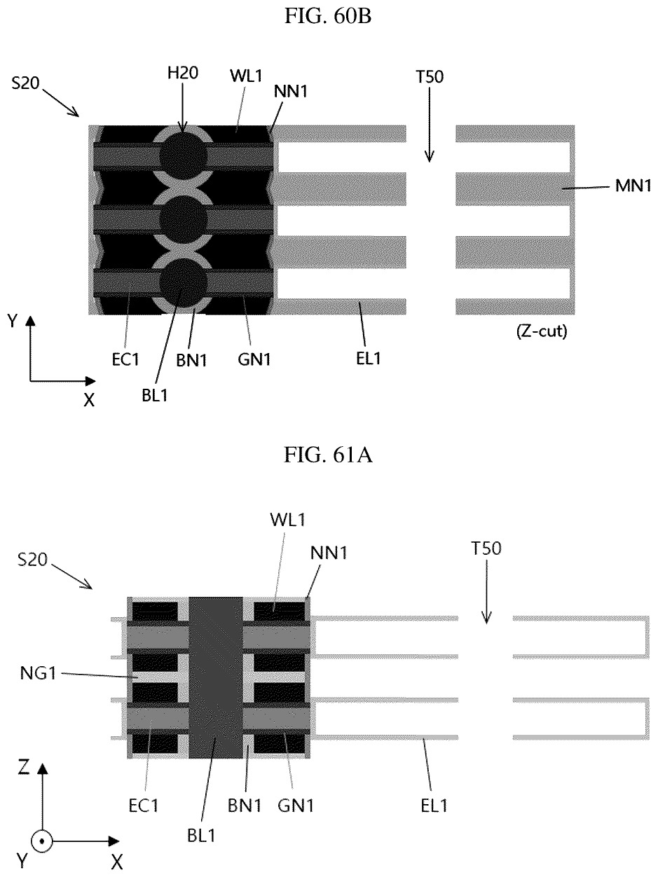

Referring to FIG. 60A and FIG. 60B, a fifth etched portion T50 may be formed in a region corresponding to the fourth etched portion (T40 in FIG. 57A) in the capacitor formation region. The fifth etched portion T50 may be formed by etching a portion of the electrode member EL1. The fifth etched portion T50 may have a line shape extending in the Y-axis direction. The fifth etched portion T50 may be referred to as a fifth trench. The electrode member EL1 may be separated into an individual capacitor region through this process. In other words, the electrode member EL1 may be separated into a unit cell region.

A ninth mask pattern M90 may be used to form the fifth etched portion T50. The ninth mask pattern M90 may have a predetermined opening area. The ninth mask pattern M90 may be, for example, a photoresist pattern. After forming the fifth etched portion T50, the ninth mask pattern M90 may be removed.

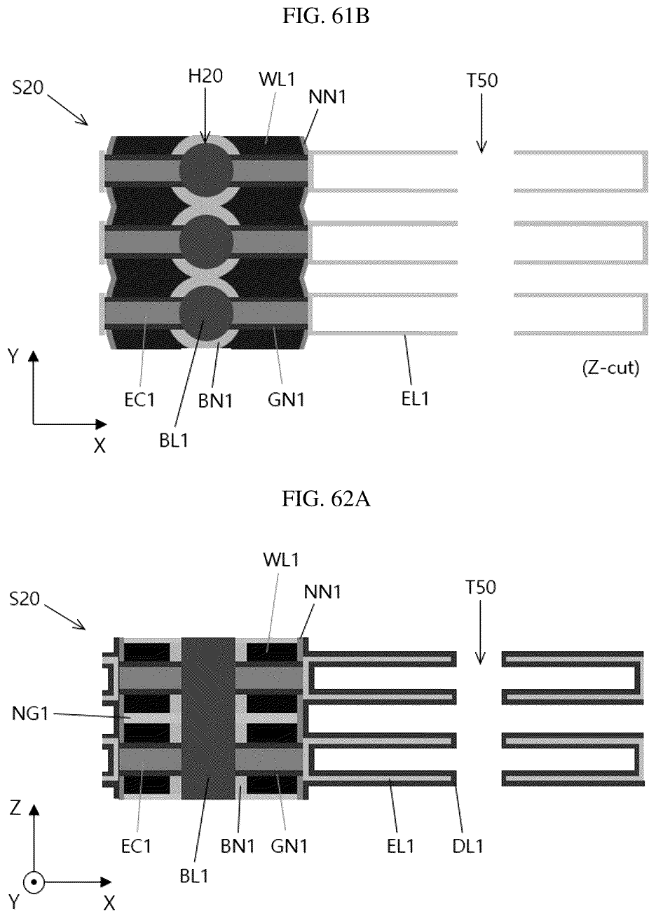

Referring to FIG. 61A and FIG. 61B, an outer surface of the electrode member EL1 may be exposed by etching the mold insulating layer (MN1 in FIG. 60A) after forming the electrode member EL1. In this step, the insertion insulating layer NN1 may be exposed by removing the entire mold insulating layer (MN1 in FIG. 60A). However, if necessary, the etching range of the mold insulating layer (MN1 in FIG. 60A) may be adjusted appropriately. As a method of adjusting the etching range, at least a portion of the ninth mask pattern (M90 in FIG. 60A) may be temporarily maintained, or a separate hard mask (not shown) may be used. If necessary, a portion of the mold insulating layer (MN1 in FIG. 60A) adjacent to the insertion insulating layer NN1 may be remained without being etched.

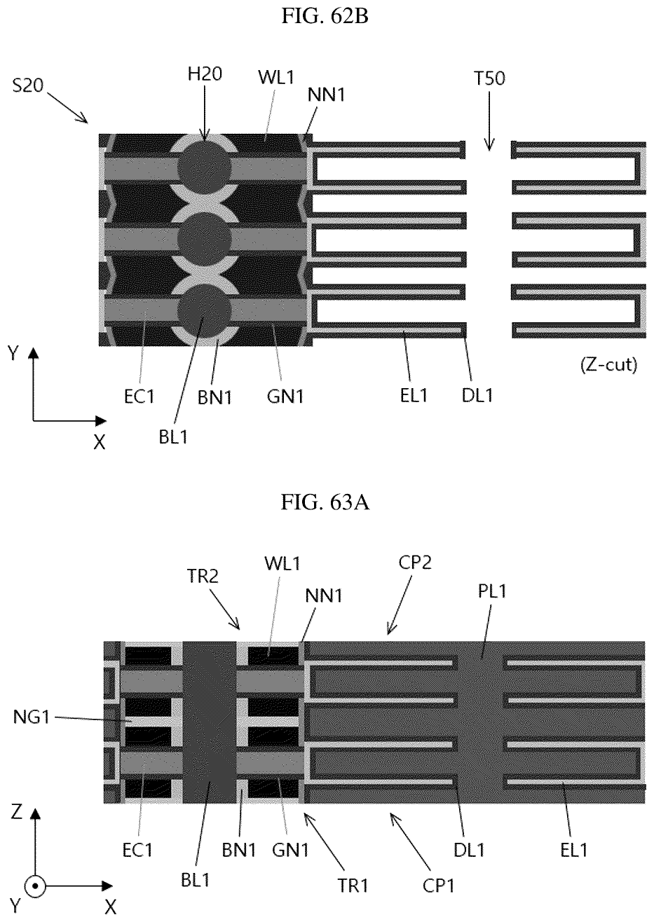

Referring to FIG. 62A and FIG. 62B, a dielectric layer DL1 may be formed on the electrode member EL1 in the capacitor formation region. The dielectric layer DL1 may be a dielectric layer for a capacitor. The dielectric layer DL1 may be formed conformally according to the surface shape of the electrode member EL1. The dielectric layer DL1 may be formed (deposited) through, for example, an ALD process. The dielectric layer DL1 may be formed to include at least any one selected from various dielectric materials. For example, the dielectric layer DL1 may include a high-k material with a higher dielectric constant than that of a silicon nitride. The specific material of the dielectric layer DL1 may vary.

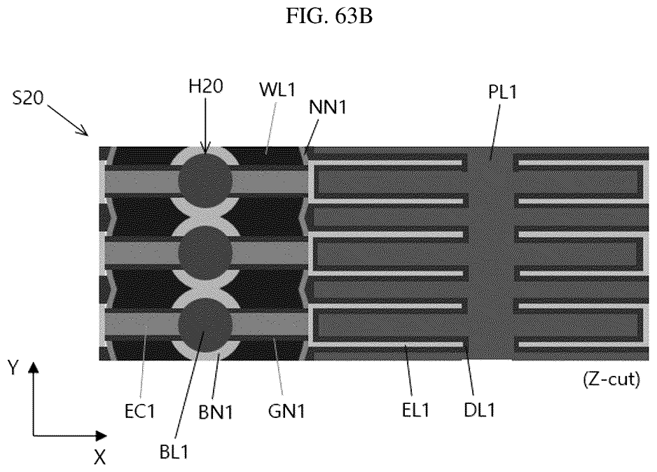

Referring to FIG. 63A and FIG. 63B, a plate electrode PL1 may be formed on the dielectric layer DL1 in the capacitor formation region. The plate electrode PL1 may be an electrode layer (second electrode layer) for a capacitor. The plate electrode PL1 may be formed to fill the fifth etched portion (T50 in FIG. 60A), the inside of the electrode member EL1, and the space between the electrode member EL1. The plate electrode PL1 may be formed to include one or more of various electrode materials used in semiconductor device processing. The plate electrode PL1 may have a type of line shape. Therefore, the plate electrode PL1 may be a plate electrode line. The electrode member EL1, the dielectric layer DL1, and the plate electrode PL1 may form a capacitor.

FIG. 59A to FIG. 63B illustrate and describe the method of forming the capacitor as an example, but the method for forming the capacitor and the specific structure of the capacitor may vary depending on the case.

In the device structure of FIG. 63A, the lower epitaxial channel pattern EC1, the word line WL1 surrounding it, and the gate insulating material layer GN1 between them may constitute a first transistor TR1. In addition, the lower electrode member EL1 electrically connected to the first transistor TR1 on the lateral side of the first transistor TR1, the dielectric layer DL1 in contact with the lower electrode member EL1, and the plate electrode PL1 may constitute a first capacitor CP1. Furthermore, the first transistor TR1 and the first capacitor CP1 constitute one memory cell (lower memory cell). The first transistor TR1 and the first capacitor CP1 may be arranged in a horizontal direction.

In addition, the upper epitaxial channel pattern EC1, the word line WL1 surrounding it, and the gate insulating material layer GN1 between them may constitute a second transistor TR2. In addition, the upper electrode member EL1 electrically connected to the second transistor TR2 on the lateral side of the second transistor TR2, the dielectric layer DL1 in contact with the upper electrode member EL1, and the plate electrode PL1 may constitute a second capacitor CP2. Furthermore, the second transistor TR2 and the second capacitor CP2 constitute one memory cell (upper memory cell). The second transistor TR2 and the second capacitor CP2 may be arranged in a horizontal direction. The second transistor TR2 may be disposed on the first transistor TR1, and the second capacitor CP2 may be disposed on the first capacitor CP1.

Although not shown, device structures such as those in FIG. 63A and FIG. 63B may be repeatedly arranged in the Z-axis direction, may be repeatedly arranged in the X-axis direction, and may be repeatedly arranged in the Y-axis direction. According to these embodiments of the present invention, it is possible to implement a memory device which may remarkably improve integration degree and have excellent performance and operation characteristics. The memory device may be a gate-all-around (GAA) type stacked memory device having a horizontal arrangement and a stacked structure. Furthermore, the memory device according to an embodiment of the present invention may be a vertical DRAM device or a three-dimensional DRAM device.

Hereinafter, a memory device according to an embodiment of the present invention will be additionally described with reference to FIG. 63A and FIG. 63B.

Referring to FIG. 63A and FIG. 63B, a memory device according to an embodiment of the present invention may include a plurality of memory cells stacked in a vertical direction. Each of the plurality of memory cells may include a transistor and a capacitor electrically connected to the transistor in a lateral direction. The transistor may correspond to TR1 and TR2, and the capacitor may correspond to CP1 and CP2. The transistor may include an epitaxial channel pattern EC1, a word line WL1 surrounding the epitaxial channel pattern EC1, and a gate insulating layer GN1 disposed between them. The capacitor may include an electrode member EL1 electrically connected to the transistor, a dielectric layer DL1 disposed on a surface of the electrode member EL1, and a plate electrode PL1 disposed on a surface of the dielectric layer DL1.

Furthermore, the memory device may include a bit line BL1 connected to a plurality of transistors of the plurality of memory cells. The bit line BL1 may extend in the vertical direction. A body insulating layer BN1 surrounding at least a portion of an outer surface of the bit line BL1 may be disposed between the bit line BL1 and the word line WL1. A gap filling insulating layer NG1 which is a separate material layer from the body insulating layer BN1 may be disposed between two adjacent word lines WL1 of the plurality of transistors.

The epitaxial channel pattern EC1 may include a single crystal semiconductor. For example, the epitaxial channel pattern EC1 may include any one of single crystal Si, single crystal Ge, and single crystal SiGe. The transistor may have excellent performance by including the epitaxial channel pattern EC1. The epitaxial channel pattern EC1 may also be referred to as an epitaxial channel material layer.

When observed from above, the body insulating layer BN1 may have a structure in which a plurality of annular-shaped units are connected in series (see FIG. 63B, etc.). The bit line BL1 may be disposed inside each of the plurality of ring-shaped units. Each of the plurality of annular-shaped units may have a ring-shaped cross-sectional structure. For example, each of the plurality of annular-shaped units may have a cross-sectional structure of a circular ring shape or an approximately circular ring shape. Furthermore, the body insulating layer BN1 may have a shape extending in the same direction as the word line WL1 when observed from above. Within the body insulating layer BN1, a plurality of bit lines BL1 may be arranged to be spaced apart from each other in the horizontal direction, that is, the horizontal direction in which the word line WL1 extends.

In an embodiment of the present invention, the transistor may have a gate-all-around (GAA) structure. In this regard, the transistor and the memory device including it may have excellent characteristics.

In addition, the memory device may further include an insertion insulating layer NN1 extending to cover a side surface of the word line WL1 while surrounding a portion (an end portion) of the gate insulating layer GN1 adjacent to the electrode member EL1. The insertion insulating layer NN1 may be a separate material layer from the body insulating layer BN1 and the gap filling insulating layer NG1. The insertion insulating layer NN1 may be, for example, an atomic layer deposition (ALD) material layer.

According to one embodiment, the body insulating layer BN1 may be in contact with a first side surface (first end) of the gap filling insulating layer NG1, and the insertion insulating layer NN1 may be in contact with a second side surface (second end) of the gap filling insulating layer NG1. A portion of the insertion insulating layer NN1 may be in contact with the electrode member EL1.

Furthermore, according to one embodiment, a side surface of the insertion insulating layer NN1 may contact a side surface of the dielectric layer DL1. The word line WL1 may contact a first side surface of the insertion insulating layer NN1, and the dielectric layer DL1 may contact a second side surface of the insertion insulating layer NN1. However, it is not limited to this structure and may be modified.

A memory device according to an embodiment of the present invention may have structural features as shown in FIGS. 63A and FIG. 63B. For example, the memory device has a stacked structure and includes the epitaxial channel pattern EC1, and may have characteristics in the structure of the body insulating layer BN1, the gap filling insulating layer NG1, the insertion insulating layer NN1 and their peripheral portions, and the transistor and the capacitor.

According to the embodiments of the present invention described above, it is possible to implement a memory device (stack-type memory device) and a manufacturing method thereof which may increase the degree of integration and secure excellent performance, while also facilitating casy processing and reducing manufacturing costs. In addition, according to the embodiments of the present invention, it is possible to implement a memory device (stack-type memory device) and a manufacturing method thereof which may improve performance such as mobility by using a single crystal channel material, may improve channel thickness uniformity, and may improve on-current characteristics. In particular, according to one embodiment of the present invention, an epitaxial channel layer is formed by using a selective epitaxial growth (SEG) method using a stack of an insulating layer and a sacrificial layer. Thus, as compared to the existing method using a Si/SiGe stacked structure, it is possible to manufacture a memory device in which process difficulties may be reduced, manufacturing costs may be reduced, and performances are improved. Since the embodiment of the present invention uses a selective epitaxial process for a single material, the process may be greatly facilitated compared to the existing method in which the epitaxial process for multiple materials (e.g., Si and SiGe) is repeatedly performed.

According to one embodiment, in manufacturing a memory device, after forming a stack in which an insulating layer and a sacrificial layer are stacked, an epitaxial material plug may be formed by using a selective epitaxial growth (SEG) method, for example, through a trench-shaped etched portion, an epitaxial channel material layer may be formed by using a SEG method from the epitaxial material plug in a space where the sacrificial layer was removed, a cell patterning may be performed and a process for forming a word line and a capacitor may be performed. In this case, it may be advantageous in manufacturing a stack-type memory device which reduces process difficulties and provides an excellent performance. In particular, when forming an epitaxial material plug by using the SEG method through a trench-shaped etched portion, the difficulty of the epitaxial process may be reduced as compared to a case that when epitaxial growth is performed through a narrow hole.

According to one example, a memory device according to an embodiment of the present invention may be configured to include a horizontal stack-type DRAM device. However, at least some of the device structures and the manufacturing methods according to the embodiments of the present invention may be applied not only for DRAM devices, but also for other memory devices (e.g., PRAM, RRAM, SRAM, flash memory, MRAM, FRAM, etc.) or a field of technology which implements logic devices with integrated logic circuits, and the like.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with memory devices and manufacturing methods thereof according to embodiments described with reference to FIG. 1A to FIG. 32B and FIG. 33A to FIG. 63B, various substitutions, changes, and modifications may be made without departing from the technological spirit of the present invention. Therefore, the scope of the invention should not be determined by the described embodiments, but should be determined by the technological concepts described in the claims.

### INDUSTRIAL APPLICARILITY

The embodiments of the present invention may be applied to semiconductor/electronic devices and manufacturing methods thereof. For example, the embodiments of the present invention may be applied to memory devices and manufacturing methods thereof.

1. A manufacturing method of a memory device comprising:
forming a stack including a first insulating layer, a first sacrificial layer, and a second insulating layer sequentially stacked on a substrate;
forming a patterned stack having at least one pattern portion having a first sacrificial layer pattern obtained from the first sacrificial layer by pattering the stack, wherein the pattern portion has a shape extending in a first direction, and empty spaces are provided on both sides of the pattern portion along a second direction perpendicular to the first direction;
forming a structure including the patterned stack and an insulating material by filling the empty spaces on both sides of the at least one pattern portion with the insulating material;
forming a first vertical hole penetrating through the first sacrificial layer pattern of the pattern portion in the structure;
forming an epitaxial material plug filling the first vertical hole from the substrate by using an epitaxial growth method;
forming a first etched portion spaced apart from the epitaxial material plug in the structure;
forming a horizontal hole extending in the first direction by removing the first sacrificial layer pattern exposed by the first etched portion;
forming an epitaxial channel material layer filling the horizontal hole from a side surface of the epitaxial material plug by using an epitaxial growth method;
forming an empty region around the epitaxial material plug and the epitaxial channel material layer by removing the first and second insulating layers and the insulating material from the structure;
forming a gate insulating material layer on surface portions of the epitaxial material plug and the epitaxial channel material layer;
forming a filling insulating layer filling the empty region on the gate insulating material layer;
forming a second vertical hole in a region corresponding to the first vertical hole in the structure where the gate insulating material layer and the filling insulating layer are formed;
exposing the gate insulating material layer by removing the filling insulating layer from a transistor formation region around the second vertical hole of the structure;
defining a transistor including a word line by forming the word line surrounding an exposed portion of the gate insulating material layer in the transistor formation region;
forming a bit line connected to one end of the epitaxial channel material layer in a region corresponding to the second vertical hole in the transistor formation region; and
removing the epitaxial channel material layer and the gate insulating material layer from a capacitor formation region adjacent to the transistor formation region of the structure, and forming a capacitor connected to the other end of the epitaxial channel material layer of the transistor.

2. The manufacturing method of a memory device of claim 1, wherein the first insulating layer, the second insulating layer, and the insulating material include a silicon nitride, and the first sacrificial layer includes a silicon oxide.

3. The manufacturing method of a memory device of claim 1, wherein the epitaxial material plug and the epitaxial channel material layer include a single crystal semiconductor.

4. The manufacturing method of a memory device of claim 3, wherein the epitaxial material plug and the epitaxial channel material layer include any one selected from a single crystal Si, a single crystal Ge, and a single crystal SiGe.

5. The manufacturing method of a memory device of claim 1, wherein the defining the transistor by forming the word line includes:
forming a word line material layer surrounding the exposed portion of the gate insulating material layer in the transistor formation region;
forming a through hole by etching a region corresponding to the second vertical hole in the word line material layer;
recessing a portion of the word line material layer exposed through the through hole so that the one end of the epitaxial channel material layer protrudes toward the through hole rather than the word line material layer; and
forming a body insulating layer filling the through hole.

6. The manufacturing method of a memory device of claim 5, further comprising:
forming a first recess exposing the word line material layer by removing the filling insulating layer from the capacitor formation region; and
recessing a portion of the word line material layer exposed by the first recess.

7. The manufacturing method of a memory device of claim 5, wherein the forming the bit line includes:
forming a third vertical hole in a region of the body insulating layer corresponding to the second vertical hole; and
forming the bit line in the third vertical hole.

8. The manufacturing method of a memory device of claim 1, after the forming the bit line, further comprising:
forming a second etched portion spaced apart from the bit line in the capacitor formation region; and
forming a first recess exposing the gate insulating material layer by removing the filling insulating layer exposed by the second etched portion in the capacitor formation region.

9. The manufacturing method of a memory device of claim 8, after the forming the first recess in the capacitor formation region, further comprising:
forming an insertion insulating layer surrounding an exposed portion of the gate insulating material layer in the capacitor formation region;
forming a mold insulating layer on the insertion insulating layer filling the first recess and the second etched portion;
forming a third etched portion in a region of the mold insulating layer corresponding to the second etched portion; and
forming a second recess by etching the epitaxial channel material layer, the gate insulating material layer, and the insertion insulating layer exposed by the third etched portion.

10. The manufacturing method of a memory device of claim 9, wherein the forming the capacitor includes:
forming an electrode member connected to the other end of the epitaxial channel material layer on an inner surface of the second recess;
forming a dielectric layer on the electrode member; and
forming a plate electrode on the dielectric layer.

11. The manufacturing method of a memory device of claim 10, further comprising exposing an outer surface of the electrode member by etching the mold insulating layer after forming the electrode member, and wherein the dielectric layer and the plate electrode are sequentially formed after etching the mold insulating layer.

12. The manufacturing method of a memory device of claim 1,
wherein the stack further includes a second sacrificial layer and a third insulating layer sequentially stacked on the second insulating layer,
wherein the stack has a vertically symmetrical structure with respect to the second insulating layer.

13. The manufacturing method of a memory device of claim 12, wherein the second insulating layer has a thickness larger than that of each of the first insulating layer, the third insulating layer, the first sacrificial layer, and the second sacrificial layer.

14. The manufacturing method of a memory device of claim 12,
wherein the transistor is a first transistor,
wherein the capacitor is a first capacitor,
wherein the memory device is formed to further include a second transistor disposed on the first transistor and a second capacitor disposed on the first capacitor.

15. A manufacturing method of a memory device comprising:
forming a structure including an epitaxial material plug extending in a vertical direction on a substrate, an epitaxial channel material layer extending in a horizontal direction from a side surface of the epitaxial material plug, a gate insulating material layer formed on at least a surface portion of the epitaxial channel material layer, and a filling insulating layer formed on the gate insulating material layer and filling a space surrounding the epitaxial material plug and the epitaxial channel material layer;
forming a vertical hole (hereinafter, referred to as a second vertical hole) by removing the epitaxial material plug from the structure;
exposing the gate insulating material layer by removing the filling insulating layer from a transistor formation region around the second vertical hole of the structure;
forming a word line surrounding an exposed portion of the gate insulating material layer in the transistor formation region to define a transistor including the word line;
forming a bit line connected to one end of the epitaxial channel material layer in a region corresponding to the second vertical hole in the transistor formation region; and
removing the epitaxial channel material layer and the gate insulating material layer from a capacitor formation region adjacent to the transistor formation region of the structure, and forming a capacitor connected to the other end of the epitaxial channel material layer of the transistor.

16. A manufacturing method of a memory device comprising:
forming a stack including a first insulating layer, a first sacrificial layer, and a second insulating layer sequentially stacked on a substrate;
forming a first etched portion penetrating through a region including at least one bit line formation planned region in the stack;
forming an epitaxial material plug filling the first etched portion from the substrate by using an epitaxial growth method;
forming a second etched portion spaced apart from the epitaxial material plug in the stack;
forming a horizontal space by removing the first sacrificial layer exposed by the second etched portion;
forming an epitaxial channel material layer filling the horizontal space from a side surface of the epitaxial material plug by using an epitaxial growth method;
forming a patterned stack including at least one pattern portion having an epitaxial channel pattern obtained from the epitaxial channel material layer and an epitaxial plug pattern obtained from the epitaxial material plug by patterning the stack on which the epitaxial channel material layer is formed,;
removing the first and second insulating layers from the patterned stack;
forming a gate insulating material layer on surface portions of the epitaxial plug pattern and the epitaxial channel pattern;
forming a structure including the epitaxial plug pattern, the epitaxial channel pattern, the gate insulating material layer, and an filling insulating layer by forming the filling insulating layer filling a space surrounding the epitaxial plug pattern and the epitaxial channel pattern on the gate insulating material layer;
forming a first vertical hole exposing the epitaxial channel pattern in a region corresponding to the bit line formation planned region;
exposing the gate insulating material layer by removing the filling insulating layer from a transistor formation region around the first vertical hole of the structure;
defining a transistor including a word line by forming the word line surrounding an exposed portion of the gate insulating material layer in the transistor formation region;
forming a bit line connected to one end of the epitaxial channel pattern in a region corresponding to the first vertical hole in the transistor formation region; and
removing the epitaxial channel pattern and the gate insulating material layer from a capacitor formation region adjacent to the transistor formation region of the structure, and forming a capacitor connected to the other end of the epitaxial channel pattern of the transistor.

17. The manufacturing method of a memory device of claim 16, wherein the first insulating layer and the second insulating layer include a silicon nitride, and the first sacrificial layer includes a silicon oxide.

18. The manufacturing method of a memory device of claim 16, wherein the first etched portion has a trench shape which commonly penetrates through a plurality of the bit line formation planned regions.

19. The manufacturing method of a memory device of claim 16, wherein the epitaxial material plug and the epitaxial channel material layer include a single crystal semiconductor.

20. The manufacturing method of a memory device of claim 19, wherein the epitaxial material plug and the epitaxial channel material layer include any one selected from a single crystal Si, a single crystal Ge, and a single crystal SiGe.

21. The manufacturing method of a memory device of claim 16, wherein the defining the transistor by forming the word line includes:
forming a word line material layer surrounding the exposed portion of the gate insulating material layer in the transistor formation region;
forming a through hole by etching a region corresponding to the first vertical hole in the word line material layer;
recessing a portion of the word line material layer exposed through the through hole so that the one end of the epitaxial channel pattern protrudes toward the through hole rather than the word line material layer; and
forming a body insulating layer filling the through hole.

22. The manufacturing method of a memory device of claim 21, further comprising:
forming a first recess exposing the word line material layer by removing the filling insulating layer from the capacitor formation region; and
recessing a portion of the word line material layer exposed by the first recess.

23. The manufacturing method of a memory device of claim 21, wherein the forming the bit line includes:
forming a second vertical hole in a region of the body insulating layer corresponding to the first vertical hole; and
forming the bit line in the second vertical hole.

24. The manufacturing method of a memory device of claim 16, after forming the bit line, further comprising:
forming a third etched portion spaced apart from the bit line in the capacitor formation region; and
forming a first recess exposing the gate insulating material layer by removing the filling insulating layer exposed by the third etched portion in the capacitor formation region.

25. The manufacturing method of a memory device of claim 24, after forming the first recess in the capacitor formation region, further comprising:
forming an insertion insulating layer surrounding an exposed portion of the gate insulating material layer in the capacitor formation region;
forming a mold insulating layer filling the first recess and the third etched portion on the insertion insulating layer;
forming a fourth etched portion in a region of the mold insulating layer corresponding to the third etched portion; and
forming a second recess by etching the epitaxial channel pattern, the gate insulating material layer, and the insertion insulating layer exposed by the fourth etched portion.

26. The manufacturing method of a memory device of claim 25, wherein the forming the capacitor includes:
forming an electrode member connected to the other end of the epitaxial channel pattern on an inner surface of the second recess;
forming a dielectric layer on the electrode member; and
forming a plate electrode on the dielectric layer.

27. The manufacturing method of a memory device of claim 26, further comprising:
exposing an outer surface of the electrode member by etching the mold insulating layer after forming the electrode member, and wherein the dielectric layer and the plate electrode are sequentially formed after etching the mold insulating layer.

28. The manufacturing method of a memory device of claim 16,
wherein the stack further includes a second sacrificial layer and a third insulating layer sequentially stacked on the second insulating layer,
wherein the stack has a vertically symmetrical structure with respect to the second insulating layer.

29. The manufacturing method of a memory device of claim 28, wherein the second insulating layer has a thickness larger than that of each of the first insulating layer, the third insulating layer, the first sacrificial layer, and the second sacrificial layer.

30. The manufacturing method of a memory device of claim 28,
wherein the transistor is a first transistor,
wherein the capacitor is a first capacitor,
wherein the memory device is formed to further include a second transistor disposed on the first transistor and a second capacitor disposed on the first capacitor.

31. A manufacturing method of a memory device comprising:
forming a structure including an epitaxial plug pattern extending in a vertical direction on a substrate, an epitaxial channel pattern extending in a horizontal direction from a side surface of the epitaxial plug pattern, a gate insulating material layer formed on at least a surface portion of the epitaxial channel pattern, and a filling insulating layer formed on the gate insulating material layer to fill a space surrounding the epitaxial plug pattern and the epitaxial channel pattern;
removing the epitaxial plug pattern and forming a first vertical hole exposing the epitaxial channel pattern by etching a bit line formation planned region in the structure;
exposing the gate insulating material layer by removing the filling insulating layer from a transistor formation region around the first vertical hole of the structure;
forming a word line surrounding an exposed portion of the gate insulating material layer in the transistor formation region to define a transistor including the word line;
forming a bit line connected to one end of the epitaxial channel pattern in a region corresponding to the first vertical hole in the transistor formation region; and
removing the epitaxial channel pattern and the gate insulating material layer from a capacitor formation region adjacent to the transistor formation region of the structure, and forming a capacitor connected to the other end of the epitaxial channel pattern of the transistor.

32. The manufacturing method of a memory device of claim 31, wherein the epitaxial plug pattern and the epitaxial channel pattern have the same width in the structure.

33. A memory device comprising a plurality of memory cells stacked in a vertical direction,
wherein each of the plurality of memory cells includes a transistor and a capacitor electrically connected to the transistor in a lateral direction,
wherein the transistor includes an epitaxial channel material layer, a word line surrounding the epitaxial channel material layer, and a gate insulating layer disposed therebetween,
wherein the capacitor includes an electrode member electrically connected to the transistor, a dielectric layer disposed on a surface of the electrode member, and a plate electrode disposed on a surface of the dielectric layer,
wherein a bit line connected to a plurality of transistors of the plurality of memory cells and extending in a vertical direction is provided,
wherein the transistor has a GAA (gate-all-around) structure.

34. The memory device of claim 33, wherein the epitaxial channel pattern includes any one selected from the group consisting of a single crystal Si, a single crystal Ge, and a single crystal SiGe.

35. The memory device of claim 33, wherein a body insulating layer is provided between the bit line and the word line to surround at least a portion of an outer surface of the bit line, and a gap filling insulating layer which is a separate material layer from the body insulating layer is provided between two mutually adjacent word lines of the plurality of transistors.

36. The memory device of claim 35,
wherein the body insulating layer has a structure in which a plurality of annular-shaped units are connected in series when observed from above,
wherein the bit line is disposed inside each of the plurality of annular-shaped units.

37. The memory device of claim 35, further comprising an insertion insulating layer surrounding a portion of the gate insulating layer adjacent to the electrode member and extending to cover a side surface of the word line,
wherein the insertion insulating layer is a separate material layer from the body insulating layer and the gap filling insulating layer.

38. The memory device of claim 37, wherein the body insulating layer is in contact with a first side surface of the gap filling insulating layer, and the insertion insulating layer is in contact with a second side surface of the gap filling insulating layer.
